(19) United States
(12) Patent Application Publication
(10) Pub. No.: US 2011/0044121 A1
(43) Pub. Date: Feb. 24, 2011

(54) SEMICONDUCTOR MEMORY DEVICE HAVING DEVICE FOR CONTROLLING BIT LINE LOADING AND IMPROVING SENSING EFFICIENCY OF BIT LINE SENSE AMPLIFIER

(76) Inventors: Joung-Yeal Kim, Yongin-si (KR); Soo-Bong Chang, Incheon (KR); Seong-Jin Jang, Seongnam-si (KR); Jin-Seok Kwak, Hwaseong-si (KR); Dong-Hak Shin, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/860,484

(22) Filed: Aug. 20, 2010

(30) Foreign Application Priority Data
Aug. 20, 2009 (KR) 10-2009-0077160
Mar. 3, 2010 (KR) 10-2010-0019035

(51) Int. Cl. G11C 7/06

(52) U.S. Cl. 365/207; 365/230.03

(57) ABSTRACT

A semiconductor memory device includes a memory cell array block including a plurality of memory cells each connected to one of a plurality of bit lines and one of a plurality of word lines, a sense amplifier connected to a half of the plurality of bit lines, the sense amplifier for sensing and amplifying a voltage between each of the half of the bit lines and a corresponding complementary bit line; and a dummy block connected to the half of the plurality of bit lines of the memory cell array block, the dummy block for controlling a load on the memory cell array block to be different from a load on the dummy block according to a dummy load signal.

### BACKGROUND

1. Field

Aspects of the inventive concept relate to semiconductor memory devices, and more particularly, to a semiconductor memory device capable of improving the sensing efficiency of a bit line sense amplifier by using a device for controlling bit line loading.

2. Description of the Related Art

A recent trend in the field of semiconductor memory devices is toward having increased storage capacity and operating speeds while consuming less power. However, as semiconductor manufacturing processes become more and more miniaturized to increase the storage capacity of semiconductor memory devices, loading mismatch between a bit line and a complementary bit line connected to a bit line sense amplifier, and threshold voltage mismatch between a plurality of transistors included in the bit line sense amplifier, are more likely to occur, thereby degrading the sensing margin and speed of the bit line sense amplifier.

### SUMMARY

Embodiments are therefore directed to semiconductor devices, which substantially overcome one or more of the problems due to the limitations and disadvantages of the related art.

It is therefore a feature of an embodiment to provide a semiconductor memory device capable of improving the sensing efficiency of a bit line sense amplifier by using a device for controlling bit line loading.

It is therefore another feature of an embodiment to provide a semiconductor memory device capable of increasing the sensing speed and performance of a bit line sense amplifier by reducing effects caused by bit line loading mismatch between a plurality of transistors included in the bit line sense amplifier.

It is yet another feature of an embodiment to provide a semiconductor memory device capable of increasing the sensing speed and performance of a bit line sense amplifier by reducing effects caused by threshold voltage mismatch between a plurality of transistors included in the bit line sense amplifier.

According to an aspect of the inventive concept, there is provided a semiconductor memory device including a bit line connected to a plurality of memory cells included in a memory cell array block; an isolation transistor having, a first end connected to the bit line; and a sense amplifier including a first node connected to a second end of the isolation transistor and a second node that is not connected to any bit line arranged on the memory cell array block, wherein a word line supply voltage, a ground voltage, or an intermediate voltage between the word line supply voltage and the ground voltage is selectively applied to a gate of the isolation transistor, wherein the word line supply voltage is applied to a word line connected to at least one of the plurality of memory cells.

The semiconductor memory device may further include an isolation control circuit for selectively applying the word line supply voltage, the ground voltage, or the intermediate voltage to the gate of the isolation transistor.

The isolation control circuit may apply the word line supply voltage to the gate of the isolation transistor when the word line is activated, apply the intermediate voltage to the gate of the isolation transistor for a predetermined amount of time before and after a sensing operation of the sense amplifier begins, and apply the word line supply voltage again to the gate of the isolation transistor after the predetermined amount of time. The isolation control circuit may apply the word line supply voltage to the gate of the isolation transistor while the word line is deactivated.

According to another aspect of the inventive concept, there is provided a semiconductor memory device including a plurality of unit blocks each having a bit line connected to a plurality of memory cells in a memory cell array block, a sense amplifier having a first node and a second node, and an isolation transistor connected between the bit line and the first node of the sense amplifier, wherein the second nodes of the sense amplifiers are not connected to any bit line arranged on the same memory cell array block, and gates of the isolation transistors in the unit blocks are commonly connected to an isolation line, wherein one transistor is connected to the isolation line for each of the plurality of unit blocks.

The semiconductor memory device may further include an isolation control circuit for selectively applying the word line supply voltage, the ground voltage, or the intermediate voltage to the isolation line.

According to another aspect of the inventive concept, there is provided a semiconductor memory device including a memory cell array block including a plurality of memory cells each connected to one of a plurality of bit lines and one of a plurality of word lines; a sense amplifier connected to a half of the plurality of bit lines, the sense amplifier for sensing and amplifying a voltage between each of the half of the bit lines and a corresponding complementary bit line; and a dummy block connected to the half of the plurality of bit lines of the memory cell array block, the dummy block for controlling a load on the memory cell array block to be different from a load on the dummy block according to a dummy load signal.

The dummy block may include a dummy capacitor; and a dummy transistor for connecting the dummy capacitor to the half of the plurality of bit lines of the memory cell array according to the dummy load signal.

The dummy block may be connected commonly to the half of the plurality of bit lines of the memory cell array.

According to another aspect of the inventive concept, there is provided a semiconductor memory device including a first memory cell array block including at least one first memory cell connected to at least one first bit line and at least one first word line; a second memory cell array block including at least one second memory cell connected to at least one second bit line and at least one second word line; a first isolation control unit for connecting the at least one first bit line of the first memory cell array block to a first node according to a first isolation control signal; a second isolation control unit for connecting the at least one second bit line of the second memory cell array block to a second node according to a second isolation control signal; an equalization unit for equalizing voltages of the first node and the second node with a ground voltage according to an equalizing signal; a sense amplifier for sensing and amplifying a voltage between the first node and the second node; and a balancing control unit for controlling the voltages of the first node and the second node.

The first and second isolation control signals may control a load on the at least one first bit line to be delivered to the first node to be different from a load on the at least one second bit line to be delivered to the second node.

In the semiconductor memory device, voltages of the first and second isolation control signals may be set in such a manner that mismatch occurring between transistors that are expected to have symmetric characteristics with one another in the sense amplifier may be compensated for.

The balancing control unit may include a current balancing control unit for controlling the amount of current to be supplied to the first node and the second node according to a first balancing signal and a second balancing signal. The current balancing control unit may include a first NMOS transistor connected between a ground voltage source and the first node, and having a gate to which the first balancing signal is supplied; and a second NMOS transistor connected between the ground voltage source and the second node and having a gate to which the second balancing signal is supplied. If the voltage of the second isolation control signal is lower than the voltage of the first isolation control signal and load on the second node is thus lower than load on the first node, then the second balancing signal may be maintained at a logic ‘high’ level until the beginning of a sensing operation so that current, which is to be supplied to the second node by the sense amplifier, is diverted to a path of current flowing through the second NMOS transistor.

The balancing control unit may include a voltage balancing control unit for controlling the voltages of the first node and the second node according to a first balancing signal and a second balancing signal. The voltage balancing control unit may include a first NMOS transistor connected between a balancing voltage source and the first node and having a gate to which the first balancing signal is supplied; and a second NMOS transistor connected between the balancing voltage source and the second node and having a gate to which the second balancing signal is supplied. The balancing voltage may be half a charge-sharing voltage between the first node and the second node. The first or second balancing signal may be activated depending on whether the at least one first memory cell of the first memory cell array block or the at least one second memory cell of the second memory cell array block is selected. The difference between the voltages of the first node and the second node may be half the charge-sharing voltage.

The balancing control unit may include a current balancing control unit for controlling the amount of current to be supplied to the first node and the second node according to a balancing control signal, a first balancing signal, and a second balancing signal. The current balancing control unit may include an NMOS transistor having a source to which a sensing driving voltage is applied and a gate to which the balancing control signal is supplied; a first NMOS transistor connected between a drain of the NMOS transistor and the first node and having a gate to which the first balancing signal is supplied; and a second NMOS transistor connected between the drain of the NMOS transistor and the second node and having a gate to which the second balancing signal is supplied. The balancing control signal may have an external voltage that is logic high during a sensing operation. The first or second balancing signal may be activated depending on whether the at least one first memory cell of the first memory cell array block or the at least one second memory cell of the second memory cell array block is selected. The difference between the voltages of the first and second nodes may be increased by additionally supplying current to the first or second node connected to the first or second memory cell that is not selected during the sensing operation.

According to another aspect of the inventive concept, there is provided a semiconductor memory device including a memory cell array block including a plurality of memory cells each connected to one of a plurality of bit lines and one of a plurality of word lines; an isolation control unit for connecting a half of the plurality of bit lines to a first node according to an isolation control signal, respectively; a sense amplifier for sensing and amplifying a voltage between the first node and a second node; and a balancing control unit for controlling voltages of the first and second nodes.

The isolation control unit may include an NMOS transistor connected between the plurality of bit lines and the first node and having a gate to which the isolation control signal is supplied.

The balancing control unit may control the voltages of the first node and the second node according to an equalizing signal. The balancing control unit may include a first NMOS transistor connected between a ground voltage source and the first node and having a gate to which the equalizing signal is supplied; and a second NMOS transistor connected between a balancing voltage source and the second node and having a gate to which the equalizing signal is supplied. The balancing voltage may be half a charge-sharing voltage between the first node and the second node. The difference between the voltages of the first and second nodes may be half the charge-sharing voltage between the first and second nodes during precharge and charge-sharing operations.

The balancing control unit may control the voltages of the first node and the second node according to first and second equalizing signals. The balancing control unit may include an NMOS transistor connected between a ground voltage source and the first node and having a gate to which the first equalizing signal is supplied; and a PMOS transistor connected between the ground voltage source and the second node and having a gate to which the second equalizing signal is supplied. The first equalizing signal may have an equalizing voltage before a precharge operation is performed and may have a ground voltage during precharge, active, and sensing operations. The second equalizing signal may have a negative back-bias voltage before the precharge operation is performed and may have the equalizing voltage during the precharge, active, and sensing operations. The difference between the voltages of the first and second nodes may be less than or equal to the charge-sharing voltage, influenced by the coupling using the voltages of the first and second equalizing signals supplied during the precharge operation.

According to another aspect of the inventive concept, there is provided a semiconductor memory device including a memory cell array block including a plurality of memory cells each connected to one of a plurality of bit lines and one of a plurality of word lines; a sense amplifier for sensing and amplifying a voltage between each of a half of the plurality of bit lines and a corresponding complementary bit line; a first balancing control unit for controlling the voltage between each of the half of the plurality of bit lines and the corresponding complementary bit line according to an equalizing signal; and a second balancing control unit for controlling the amount of current to be supplied to the corresponding complementary bit lines according to a balancing signal.

The first balancing control unit may include a first NMOS transistor connected between a ground voltage source and the half of the plurality of bit lines and having a gate to which the equalizing signal is supplied; and a second NMOS transistor connected between a balancing voltage source and the corresponding complementary bit lines and having a gate to which the equalizing signal is supplied. During precharge and charge-sharing operations, the difference between voltages of the first and second node is half a charge-sharing voltage. The second balancing control unit may include an NMOS transistor connected between a balancing voltage source and the corresponding complementary bit lines and having a gate to which the balancing signal is supplied. Until the beginning of a sensing operation starting from when a precharge operation begins, current that is to be supplied to the corresponding complementary bit line may be diverted to a path of current flowing through the balancing voltage source when the sense amplifier operates.

According to another aspect of the inventive concept, there is provided a semiconductor memory device including a first memory cell array block including at least one first memory cell connected to at least one first bit line and at least one first word line; a second memory cell array block including at least one second memory cell connected to at least one second bit line and at least one second word line; a first isolation control unit for connecting the at least one first bit line of the first memory cell array block to a first node according to a first isolation control signal; a second isolation control unit for connecting the at least one second bit line of the second memory cell array block to a second node according to a second isolation control signal; an equalization unit for equalizing voltages of the first node and the second node with a ground voltage according to an equalizing signal; a sense amplifier for sensing and amplifying a voltage between the first node and the second node; and a coupling control unit for controlling the voltages of the first node and the second node by performing coupling.

The coupling control unit may control the voltages of the first node and the second node according to a coupling signal. The coupling control unit may include a first NMOS transistor having a gate to which the coupling signal is supplied and a source and drain connected to the first node; and a second NMOS transistor having a gate to which the coupling signal is supplied and a source and drain connected to the second node. A coupling voltage may be applied to the coupling signal, where the coupling voltage is determined in such a manner that the result of multiplying the sum of the coupling capacitance of the first or second NMOS transistor and the capacitance of the second node by a voltage that is half the voltage of the first node may be equal to the product of the coupling capacitance and the coupling voltage. The difference between the voltages of the first node and the second node may be half a charge-sharing voltage by performing coupling using the coupling voltage applied to the coupling signal during an active operation. The coupling control unit may be located in a conjunction region which is a common region of the semiconductor memory device to be connected to the first and second nodes of the sense amplifier.

The coupling control unit may include a first coupling control unit for controlling the voltage of the first node according to a first coupling signal; and a second coupling control unit for controlling the voltage of the second node according to a second coupling signal. The first coupling control unit may include an NMOS transistor having a gate to which the first coupling signal is supplied and a source and drain connected to the first node. The second coupling control unit may include an NMOS transistor having a gate to which the second coupling signal is supplied and a source and drain connected to the second node. The first or second coupling signal may be activated depending on whether the at least one first memory cell of the first memory cell array block or the at least one second memory cell of the second memory cell array block is selected. If the at least one first memory cell is selected during an active operation, the voltage of the second node may increase up to a voltage that is half a charge-sharing voltage, influenced by the coupling.

The coupling control unit may include an equalizing and coupling control unit for controlling the voltages of the first node and the second node according to an equalizing selection signal, first and second equalizing signals, and first and second coupling signals. The equalizing and coupling control unit may include a first NMOS transistor having a gate to which the first equalizing signal is supplied and a drain connected to the first node; a second NMOS transistor having a gate to which the first coupling signal is supplied and a source and drain connected to a source of the first NMOS transistor; a third NMOS transistor having a gate to which the equalizing selection signal is supplied, a drain connected to the source of the first NMOS transistor, and a source to which a ground voltage is applied; a fourth NMOS transistor having a gate to which the second equalizing signal is supplied and a drain connected to the second node; a fifth NMOS transistor having a gate to which the second coupling signal is supplied and a source and drain connected to a source of the fifth NMOS transistor; and a sixth NMOS transistor having a gate to which the equalizing selection signal is supplied, a drain connected to a source of the fourth NMOS transistor, and a source to which the ground voltage is applied. The first or second coupling signal may be activated depending on whether the at least one first memory cell of the first memory cell array block or the at least one second memory cell of the second memory cell array block is selected. The first or second equalizing signal may be activated depending on whether the at least one first memory cell of the first memory cell array block or the at least one second memory cell of the second memory cell array block is selected. If the at least one first memory cell is selected during the active operation, then the voltage of the second node may increase up to a voltage that is half the charge-sharing voltage, influenced by the coupling.

According to another aspect of the inventive concept, there is provided a semiconductor memory device including a first memory cell array block including at least one first memory cell connected to at least one first bit line and at least one first word line; a second memory cell array block including at least one second memory cell connected to at least one second bit line and at least one second word line; a first isolation control unit for connecting the at least one first bit line of the first memory cell array block to a first node according to a first isolation control signal; a second isolation control unit for connecting the at least one second bit line of the second memory cell array block to a second node according to a second isolation control signal; an equalization unit for equalizing voltages of the first node and the second node with a ground voltage according to an equalizing signal; a sense amplifier for sensing and amplifying a voltage between the first node and the second node according to a free sensing enable signal and first and second sensing enable signals; and a coupling control unit for controlling the voltages of the first node and the second node according to a coupling signal.

The sense amplifier may include a first type sense amplifier being driven by a first sensing driving voltage, the first type sense amplifier for sensing and amplifying a voltage between the first node and the second node; a second type sense amplifier being driven by a second sensing driving voltage, the second type sense amplifier for sensing and amplifying the voltage between the first node and the second node; a main sensing control unit for applying the first sensing driving voltage as a first internal supply voltage according to the first sensing enable signal, and applying the second sensing driving voltage as a ground voltage according to the second sensing enable signal; and a free sensing control unit for applying the second sensing driving voltage as a second internal supply voltage according to the free sensing enable signal.

The free sensing enable signal may be activated during an active operation and is deactivated before a sensing operation is performed. During the active operation, the difference between the voltages of the first node and the second node may be less than or equal to a second internal supply voltage. The second internal supply voltage may range from a ground voltage to a negative transistor threshold voltage.

The first type sense amplifier may include a first PMOS transistor connected between a first sensing driving voltage source and the first node and having a gate connected to the second node, and a second PMOS transistor connected between the first sensing driving voltage source and the second node and having a gate connected to the first node. The second type sense amplifier may include a first NMOS transistor connected between a second sensing driving voltage source and the first node and having a gate connected to the second node, and a second NMOS transistor connected between the second sensing driving voltage source and the second node and having a gate connected to the first node.

The main sensing control unit may include a PMOS transistor connected between a first sensing driving voltage source and a first internal supply voltage source and having a gate to which the first sensing enable signal is supplied; and an NMOS transistor connected between a second sensing driving voltage source and a ground voltage source and having a gate to which the second sensing enable signal is supplied. The free sensing control unit may include an NMOS transistor connected between a second sensing driving voltage source and a second internal supply voltage source and having a gate to which the free sensing enable signal is supplied.

According to another aspect of the inventive concept, there is provided a semiconductor memory device including a memory cell array block including a plurality of memory cells each connected to one of a plurality of bit lines and one of a plurality of word lines; a sense amplifier connected to a half of the plurality of bit lines, the sense amplifier for sensing and amplifying a voltage between each of the half of the plurality of bit lines and a corresponding complementary bit line according to a free sensing enable signal and first and second sensing enable signals; a dummy block connected to the corresponding complementary bit lines, the dummy block for controlling a load on the memory cell array block to be different from a load on the dummy block according to a dummy load signal; an equalization unit for equalizing voltages of the half of the plurality of bit lines and the corresponding complementary bit lines with a ground voltage according to an equalizing signal; and a coupling control unit for controlling the voltages of the half of the plurality of bit lines according to a coupling signal.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a circuit diagram of a semiconductor memory device according to an embodiment of the inventive concept;

FIG. 2 illustrates a circuit diagram of a semiconductor memory device according to another embodiment of the inventive concept;

FIG. 3 illustrates a circuit diagram of a first isolation control circuit and a second isolation control circuit in FIG. 1 or 2, according to an embodiment of the inventive concept;

FIGS. 4 to 9 illustrate timing diagrams of a first gate voltage and a second gate voltage that are output from the first isolation control circuit and the second isolation control circuit via a first isolation line and a second isolation line in FIG. 1 or 2, respectively, according to an embodiment of the inventive concept;

FIGS. 10 to 30 illustrate timing diagrams of memory core parts of the semiconductor memory devices in FIGS. 1 and 2 according to embodiments of the inventive concept;

FIG. 31 illustrates a circuit diagram of a semiconductor memory device according to another embodiment of the inventive concept;

FIG. 32 illustrates a circuit diagram of a semiconductor memory device according to another embodiment of the inventive concept;

FIG. 33 illustrates a timing diagram of a first isolation control circuit and a second isolation control circuit in FIG. 31 or 32. according to an embodiment of the inventive concept;

FIG. 34 illustrates arrangement of a plurality of unit blocks that may be included in the semiconductor memory device of FIG. 1, according to an embodiment of the inventive concept;

FIG. 35 illustrates arrangement of a plurality of unit blocks that may be included in the semiconductor memory device of FIG. 2, according to another embodiment of the inventive concept;

FIG. 36 illustrates a circuit diagram of a semiconductor memory device according to another embodiment of the inventive concept;

FIG. 37 illustrates a circuit diagram of a semiconductor memory device according to another embodiment of the inventive concept;

FIG. 38 illustrates a circuit diagram of a semiconductor memory device according to another embodiment of the inventive concept;

FIGS. 39 and 40 illustrate timing diagrams of operations of the semiconductor memory device of FIG. 38 according to embodiments of the inventive concept;

FIG. 41 illustrates a circuit diagram of a semiconductor memory device according to another embodiment of the inventive concept;

FIGS. 42 and 43 illustrate timing diagrams of operations of the semiconductor memory device of FIG. 41 according to embodiments of the inventive concept;

FIG. 44 illustrates a circuit diagram of a semiconductor memory device according to another embodiment of the inventive concept;

FIGS. 45 and 46 illustrate timing diagrams of operations of the semiconductor memory device of FIG. 44 according to embodiments of the inventive concept;

FIG. 47 illustrates a circuit diagram of a semiconductor memory device according to another embodiment of the inventive concept;

FIGS. 48 and 49 illustrate timing diagrams of operations of the semiconductor memory device of FIG. 47 according to embodiments of the inventive concept;

FIG. 50 illustrates a circuit diagram of a semiconductor memory device according to another embodiment of the inventive concept;

FIGS. 51 and 52 illustrate timing diagrams of operations of the semiconductor memory device of FIG. 50 according to embodiments of the inventive concept;

FIG. 53 illustrates a circuit diagram of a semiconductor memory device according to another embodiment of the inventive concept;

FIGS. 54 and 55 illustrate timing diagrams of operations of the semiconductor memory device of FIG. 53 according to embodiments of the inventive concept;

FIG. 56 illustrates a circuit diagram of a semiconductor memory device according to another embodiment of the inventive concept;

FIGS. 57 and 58 illustrate timing diagrams of operations of the semiconductor memory device of FIG. 56 according to embodiments of the inventive concept;

FIG. 59 illustrates a circuit diagram of a semiconductor memory device according to another embodiment of the inventive concept;

FIGS. 60 and 61 illustrate timing diagrams of operations of the semiconductor memory device of FIG. 59 according to embodiments of the inventive concept;

FIG. 62 illustrates a circuit diagram of a semiconductor memory device according to another embodiment of the inventive concept;

FIGS. 63 and 64 illustrate timing diagrams of operations of the semiconductor memory device of FIG. 62 according to embodiments of the inventive concept;

FIG. 65 illustrates a circuit diagram of a semiconductor memory device according to another embodiment of the inventive concept;

FIGS. 66 and 67 illustrate timing diagrams of operations of the semiconductor memory device of FIG. 65 according to embodiments of the inventive concept;

FIG. 68 illustrates a circuit diagram of a semiconductor memory device according to another embodiment of the inventive concept;

FIGS. 69 and 70 illustrate timing diagrams of operations of the semiconductor memory device of FIG. 68 according to embodiments of the inventive concept;

FIG. 71 illustrates a circuit diagram of a semiconductor memory device according to another embodiment of the inventive concept;

FIGS. 72 and 73 illustrate timing diagrams of operations of the semiconductor memory device of FIG. 41 according to embodiments of the inventive concept;

FIG. 74 illustrates a diagram of a memory module having a plurality of memory chips each including a semiconductor memory device according to an embodiment of the inventive concept; and

FIG. 75 illustrates a block diagram of a processor-based system employing random access memory (RAM) that is embodied as a semiconductor memory device according to an embodiment of the inventive concept.

### DETAILED DESCRIPTION

Korean Patent Application No. 10-2009-0077160, filed on Aug. 20, 2009, and Korean Patent Application No. 10-2010-0019035, filed on Mar. 3, 2010, in the Korean Intellectual Property Office, entitled, “Semiconductor Memory Device Having Device for Controlling Bit Line Loading and Improving Sensing Efficiency of Bit Line,” and, “Sense Amplifier,” are incorporated by reference herein in their entirety.

Hereinafter, exemplary embodiments of the inventive concept will be described in detail with reference to the accompanying drawings. Like reference numerals denote like elements.

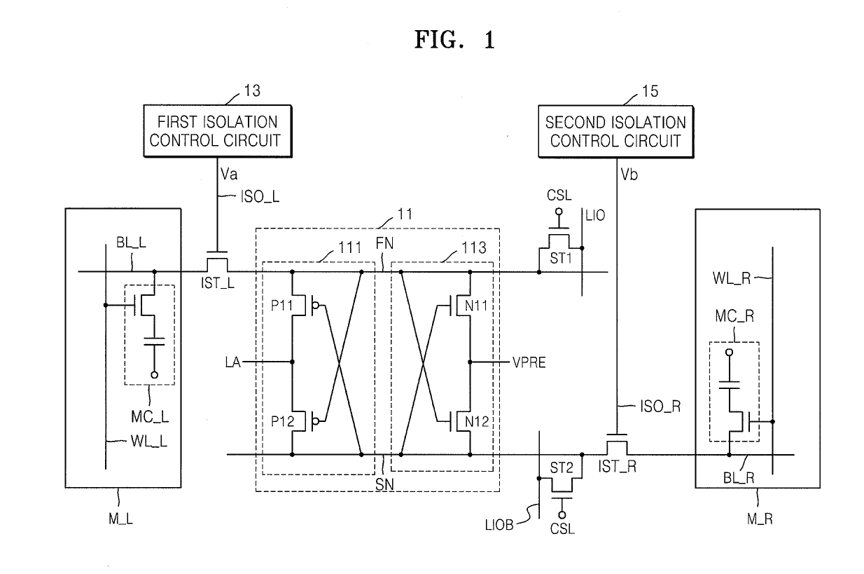

FIG. 1 illustrates a circuit diagram of a semiconductor memory device according to an embodiment of the inventive concept. Referring to FIG. 1, the semiconductor memory device includes a first memory cell array block M_L, a second memory cell array block M_R, a sense amplifier 11, a first isolation transistor IST_L, a second isolation transistor IST_R, a first isolation control circuit 13, and a second isolation control circuit 15. Referring to FIG. 1, the semiconductor memory device has an open bit line configuration, in which a pair of a first bit line BL_L and a second bit line BL_R that are connected to the sense amplifier 11 via the first and second isolation transistors IST_L and IST_R, respectively, are arranged in different memory cell array blocks. The semiconductor memory device illustrated in FIG. 1 employs a ground voltage GND precharge method.

The first memory cell array block M_L includes a plurality of memory cells each connected to a respective bit line and a respective word line. Similarly, the second memory cell array block M_R includes a plurality of memory cells each connected to a respective bit line and a respective word line. For convenience of explanation, FIG. 1 illustrates only a memory cell MC_L connected to the first bit line BL_L and a first word line WL_L in the first memory cell array block M_L and a memory cell MC_R connected to the second bit line BL_R and a second word line WL_R in the second memory cell array block M_R.

The sense amplifier 11 is disposed between the first memory cell array block M_L and the second memory cell array block M_R. The sense amplifier 11 includes a first node FN, a second node SN, a P type sense amplifier 111, and an N type sense amplifier 113. The P type sense amplifier 111 includes a first PMOS transistor P11 and a second PMOS transistor P12 connected in series between the first node FN and the second node SN, and receives a sensing voltage via a sensing enable signal input terminal LA. The first PMOS transistor P11 and the second PMOS transistor P12 may be different or the same in size. The N type sense amplifier 113 includes a first NMOS transistor N11 and a second NMOS transistor N12 connected in series between the first node FN and the second node SN, and receives a precharge voltage via a precharge voltage terminal VPRE. The first NMOS transistor N11 and the second NMOS transistor N12 may be different or the same in size. The sensing voltage may be either a supply voltage to be applied to the semiconductor memory device or an internal voltage generated from a supply voltage in the semiconductor memory device. The precharge voltage may be a ground voltage.

The first isolation transistor IST_L is connected between the first bit line BL_L and the first node FN of the sense amplifier 11. The second isolation transistor IST_R is connected between the second bit line BL_R and the second node SN of the sense amplifier 11. A first gate voltage Va is applied to a gate of the first isolation transistor IST_L from the first isolation control circuit 13 via a first isolation line ISO_L. A second gate voltage Vb is applied to a gate of the second isolation transistor ISTR from the second isolation control circuit 15 via a second isolation line ISO_R. In the current embodiment, the first isolation transistor IST_L and the second isolation transistor IST_R are NMOS transistors.

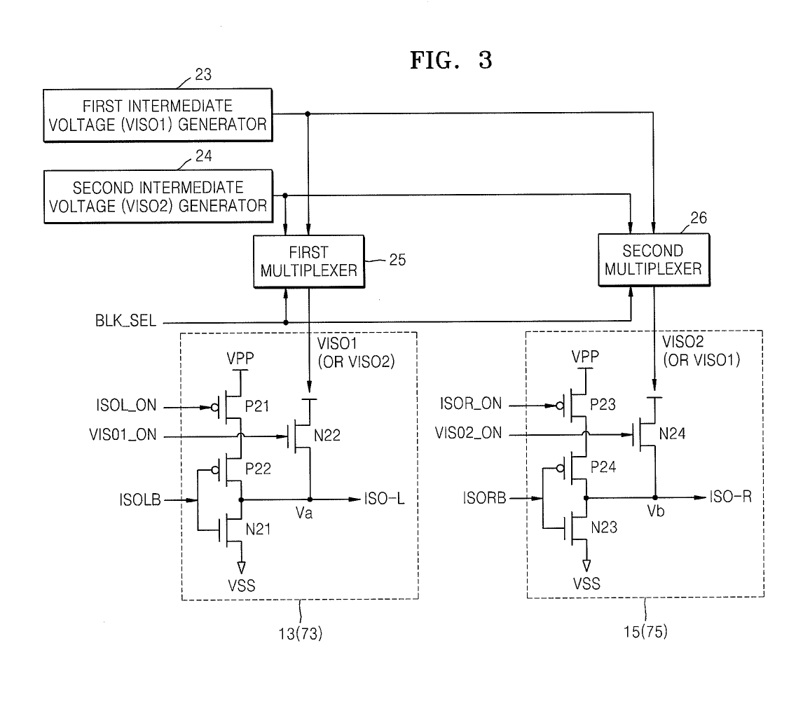

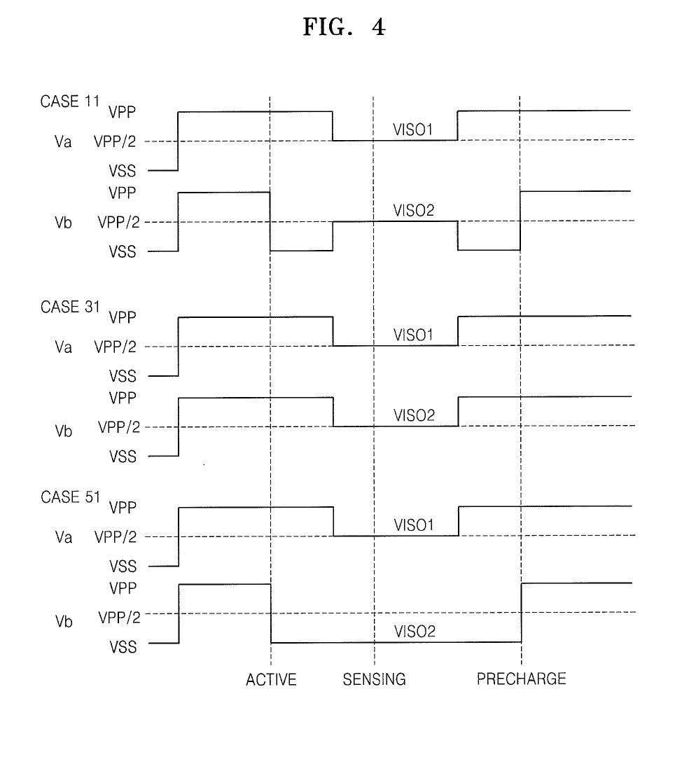

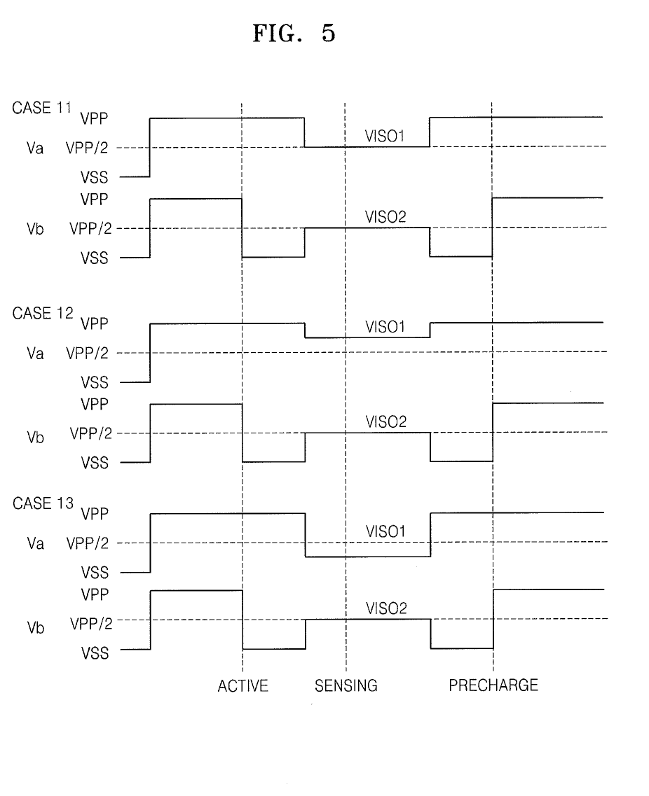

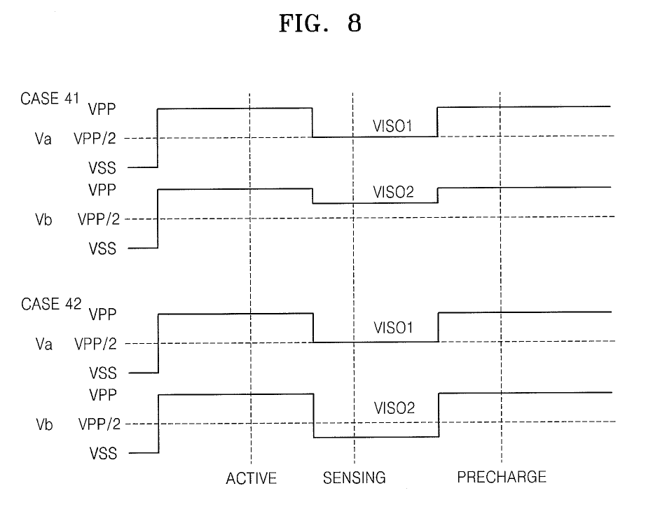

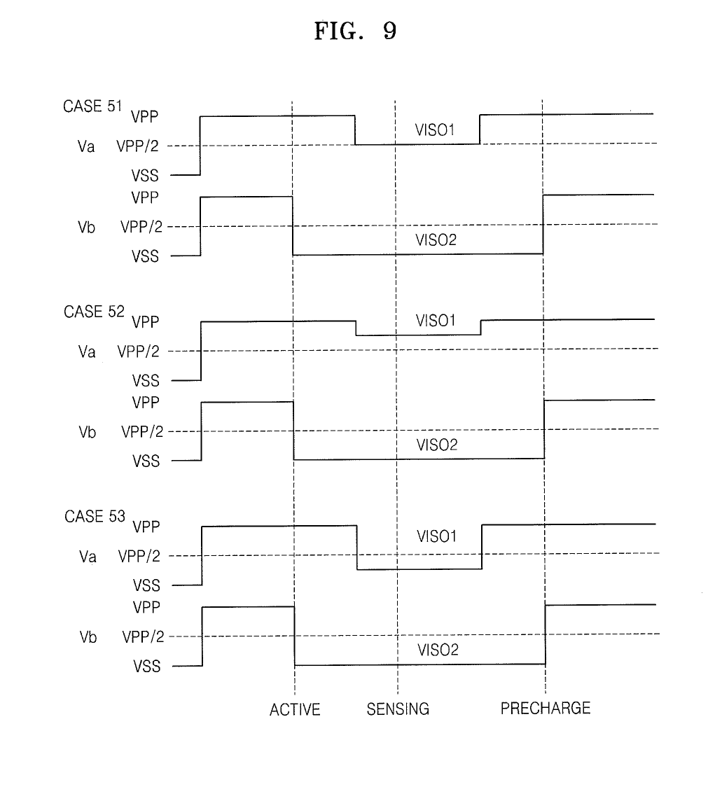

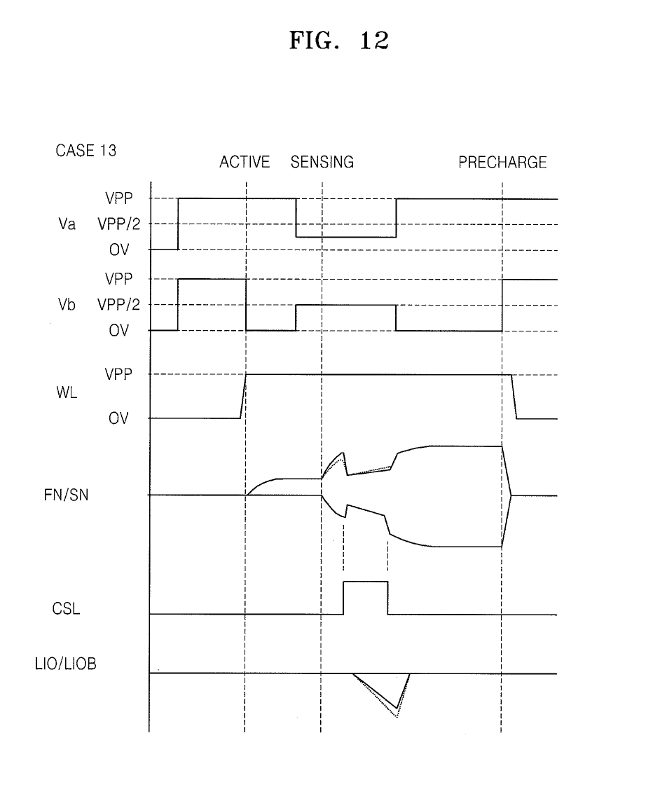

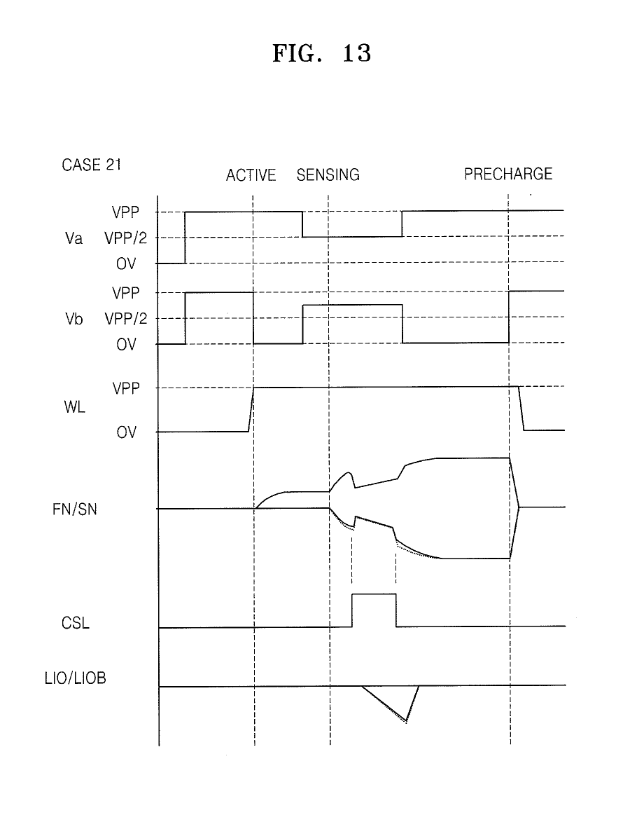

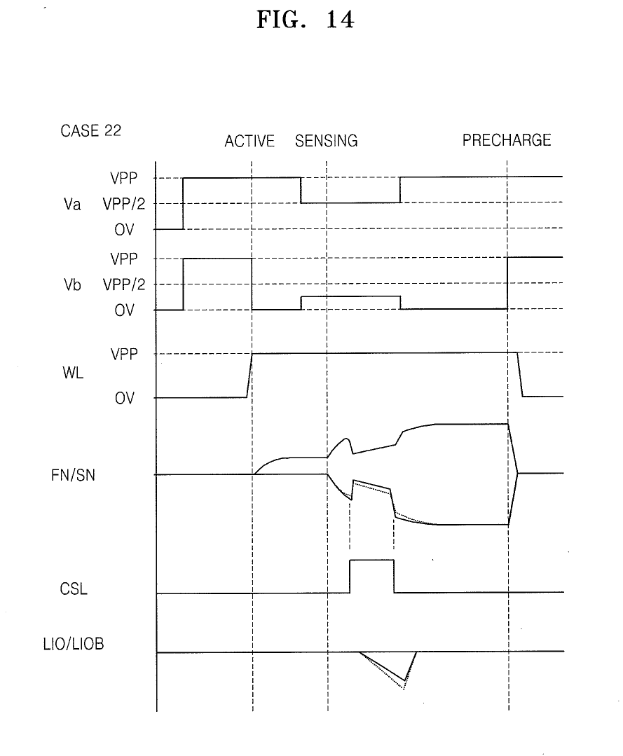

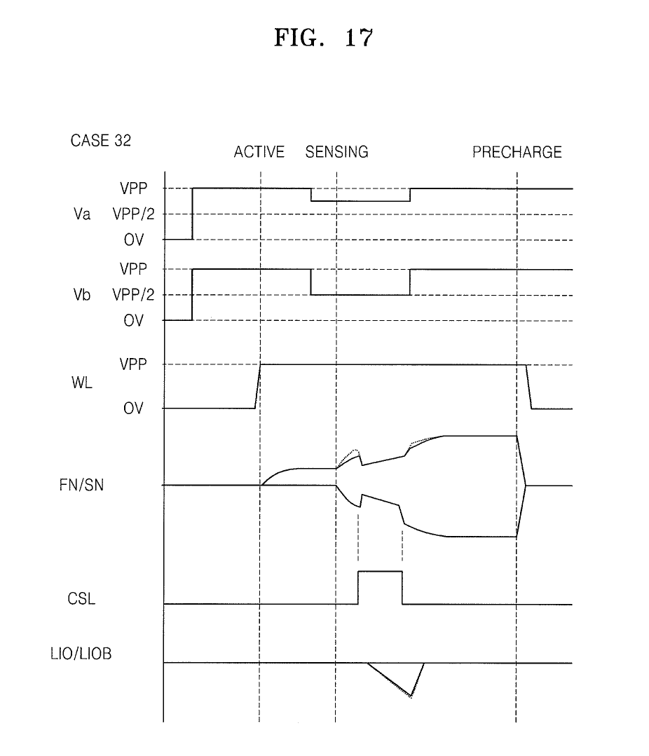

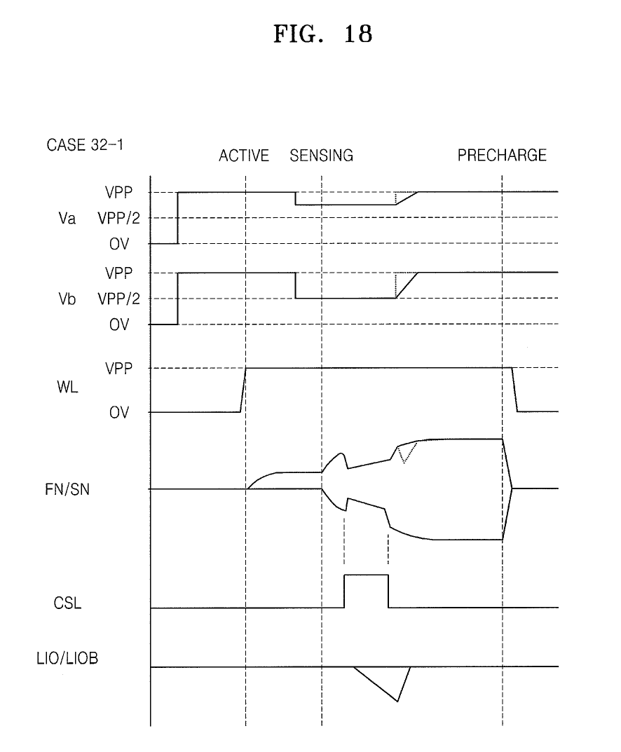

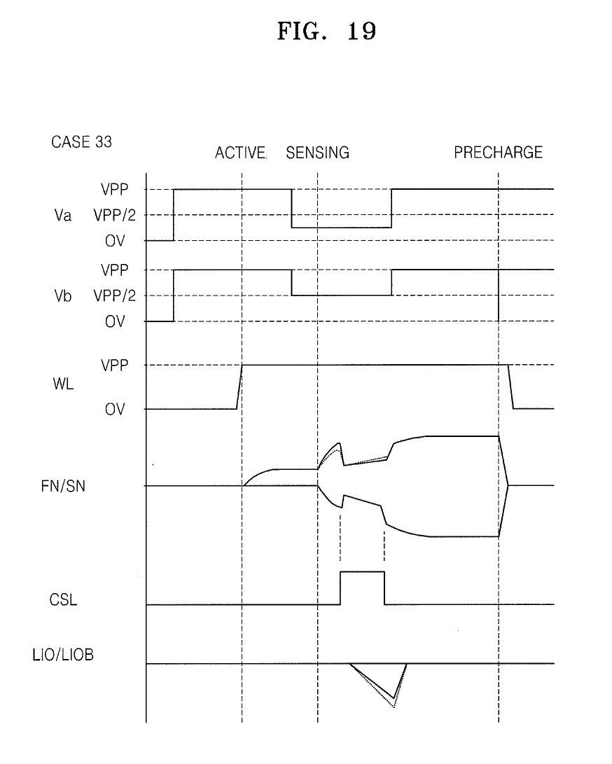

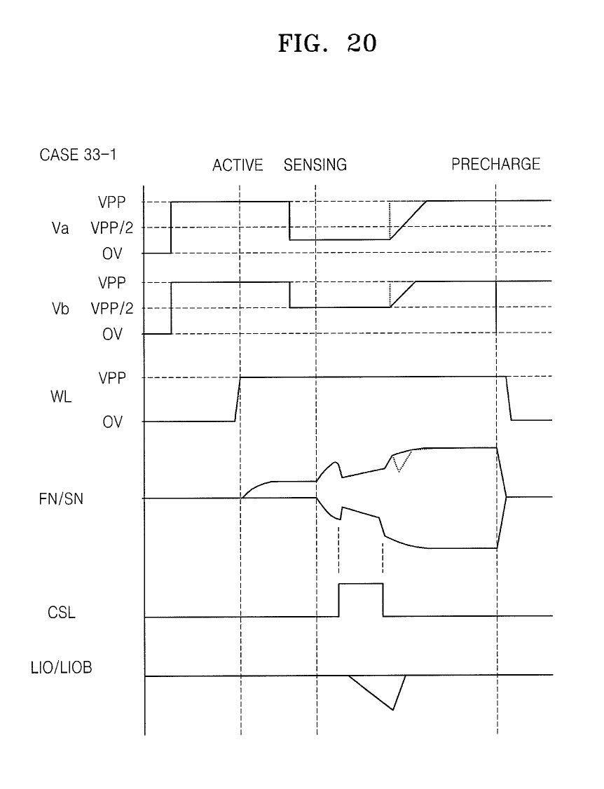

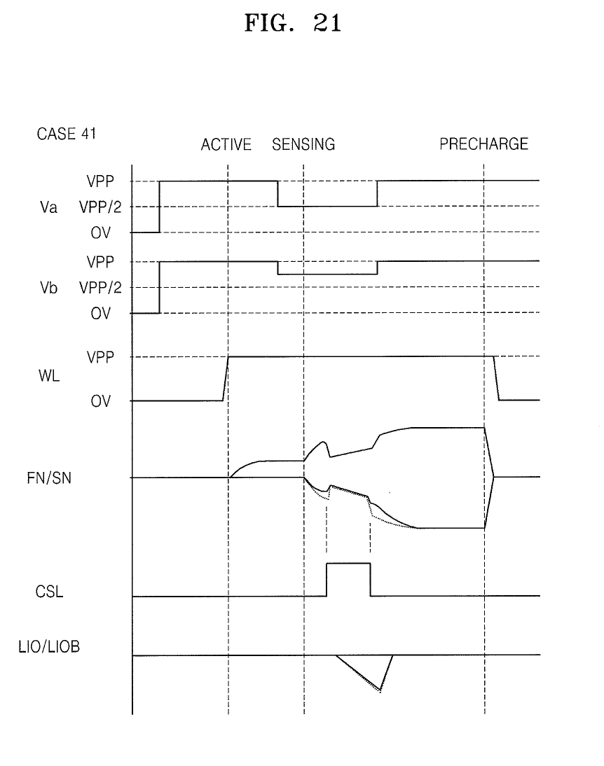

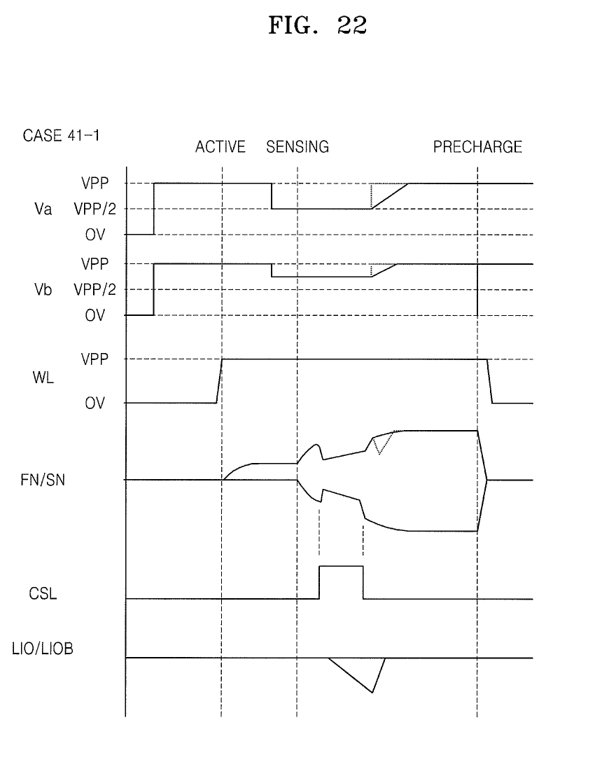

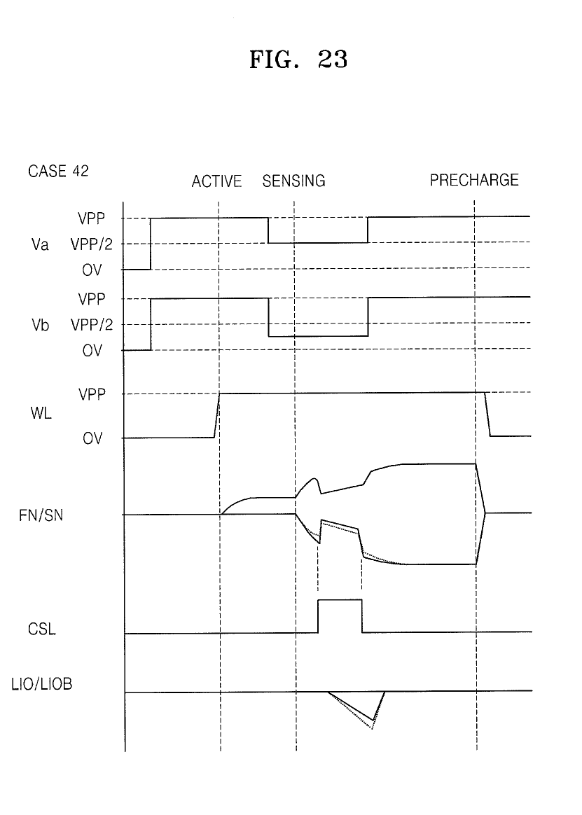

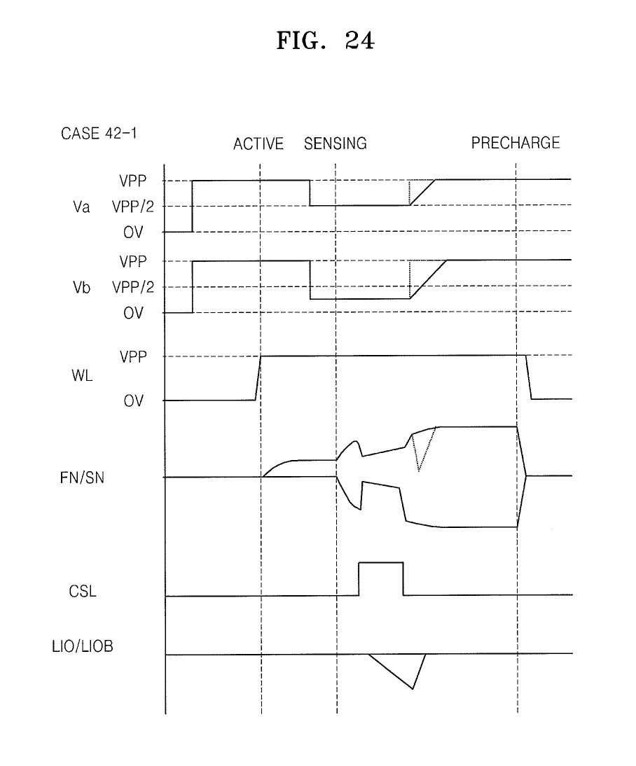

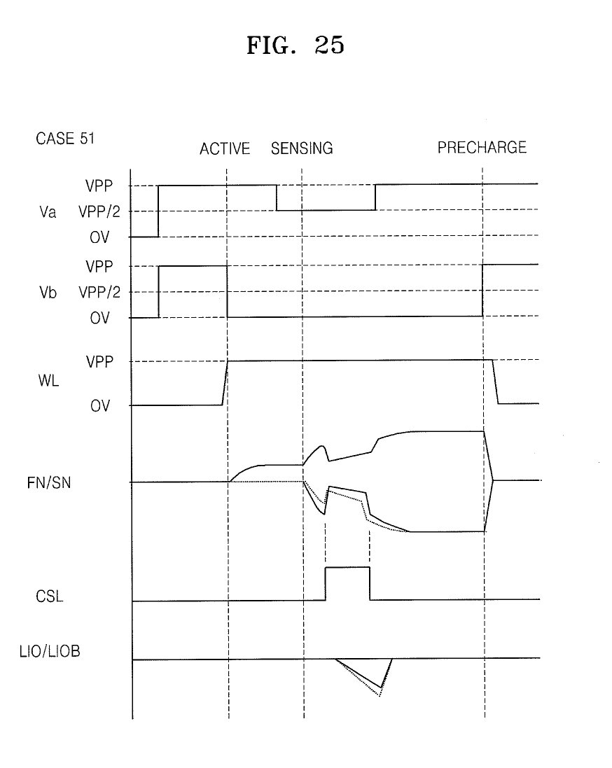

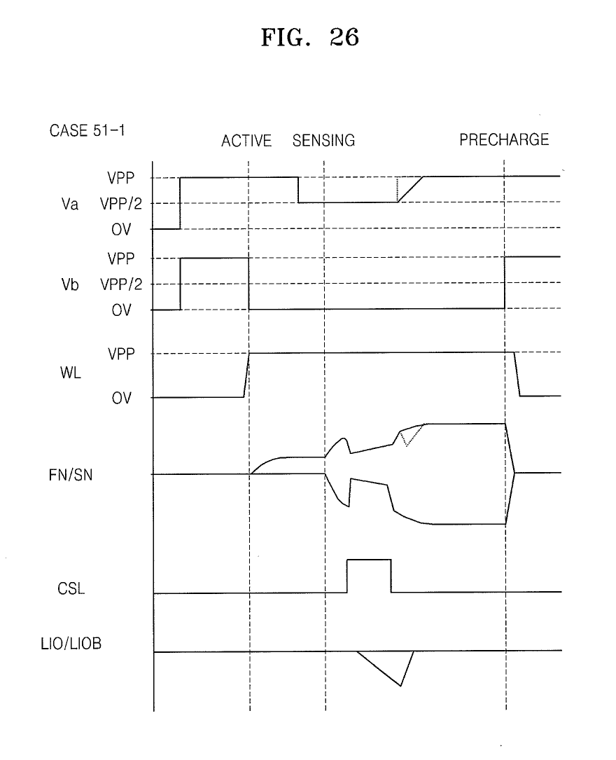

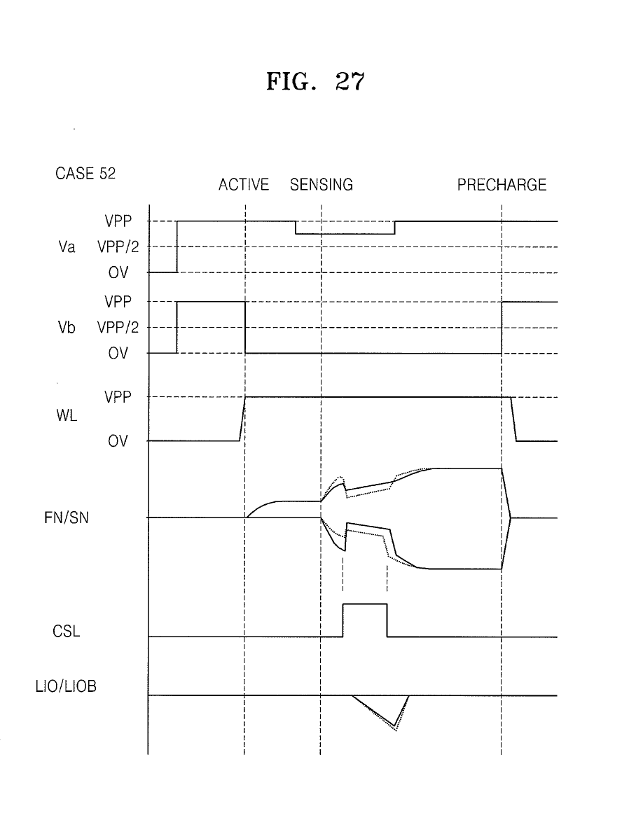

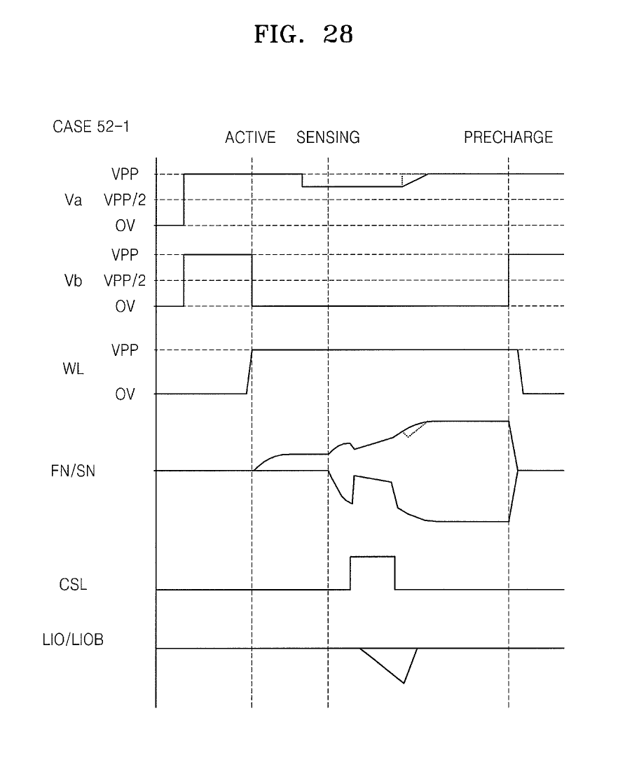

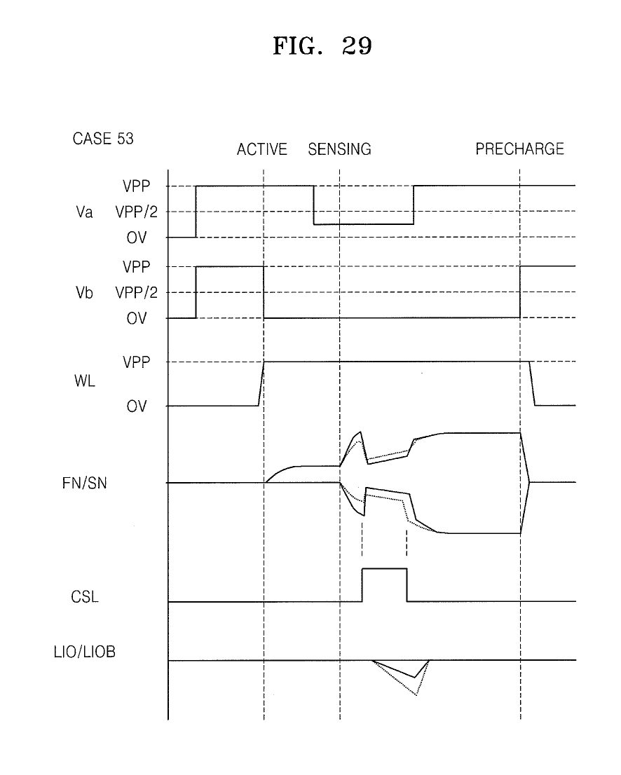

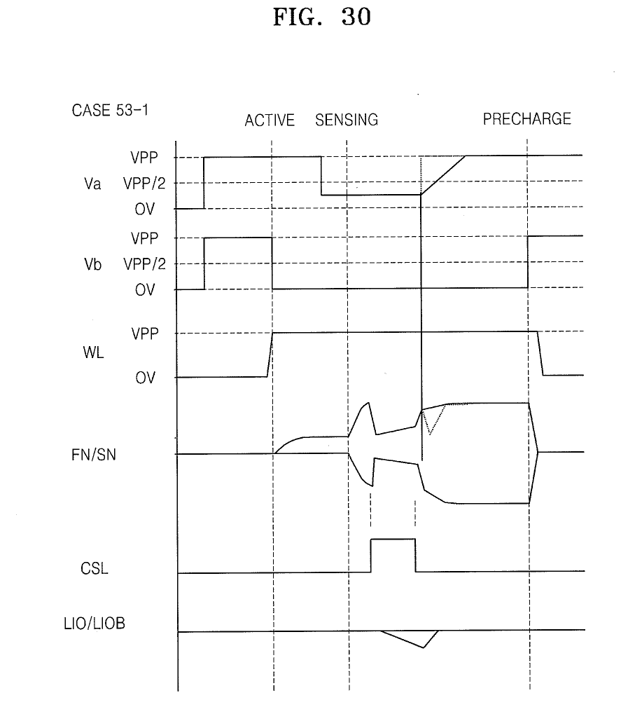

In particular, the first isolation control circuit 13 selectively applies a word line supply voltage VPP illustrated in FIGS. 4 to 30, a ground voltage VSS illustrated in FIGS. 4 to 30, or a first intermediate voltage VISO1 illustrated in FIGS. 4 to 30 between the word line supply voltage VPP and the ground voltage VSS as the first gate voltage Va to the gate of the first isolation transistor IST_L via the first isolation line ISO_L. Also, the second isolation control circuit 15 selectively applies the word line supply voltage VPP, the ground voltage VSS, or a second intermediate voltage VISO2 illustrated in FIGS. 4 to 30 between the word line supply voltage VPP and the ground voltage VSS as the second gate voltage Vb to the gate of the second isolation transistor IST_R via the second isolation line ISO_R. The structures and operations of the first isolation control circuit 13 and the second isolation control circuit 15 will be described later in detail with reference to FIG. 3.

The word line supply voltage VPP is applied to the first or second word lines WL_L or WL_R in order to respectively select the first or second memory cells MC_L or MC_R.

Referring to FIG. 1, the semiconductor memory device further includes a first selection transistor ST1, a second selection transistor ST2, and an equalization circuit (not shown). The equalization circuit equalizes the voltages of the first node FN and the second node SN of the sense amplifier 11 with each other, before the sense amplifier 11 is activated, in response to an equalizing signal. The first selection transistor ST1 applies a voltage of the first node FN of the sense amplifier 11 to an input/output (IO) line LIO, in response to a column selection signal CSL, and may be located, in contrast to the embodiment illustrated in FIG. 1, between the first isolation transistor IST_L and the P type sense amplifier 111. The second selection transistor ST2 applies a voltage of the second node SN of the sense amplifier 11 to an IO line LIOB, complementary to the IO line LIO, in response to the column selection signal CSL. The first selection transistor ST1 and the second selection transistor ST2 are NMOS transistors.

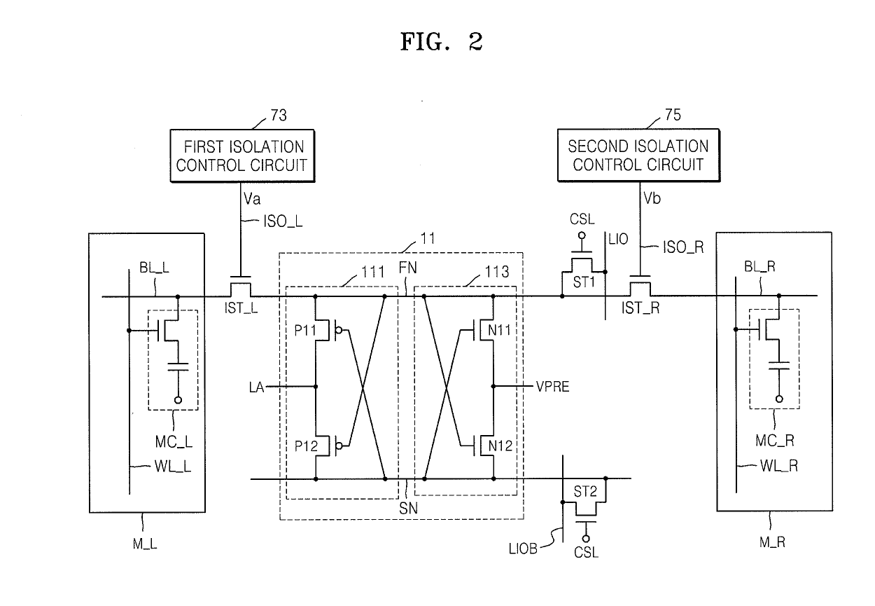

FIG. 2 illustrates a circuit diagram of a semiconductor memory device according to another embodiment of the inventive concept. Referring to FIG. 2, the semiconductor memory device includes the first memory cell array block M_L, the second memory cell array block M_R, the sense amplifier 11, the first isolation transistor IST_L, the second isolation transistor IST_R, a first isolation control circuit 73, a second isolation control circuit 75, the first selection transistor ST1, the second selection transistor ST2, and an equalization circuit (not shown). The first isolation transistor IST_L and the second isolation transistor IST_R are NMOS transistors.

The structures and operations of the first memory cell array block M_L, the second memory cell array block M_R, the sense amplifier 11, the first isolation transistor IST_L, the second isolation transistor IST_R, the first selection transistor ST1, the second selection transistor ST2, and the equalization circuit are the same as described above with reference to FIG. 1. The first isolation transistor IST_L is connected between the first bit line BL_L and the first node FN of the sense amplifier 11. The second isolation transistor IST_R is connected between the second bit line BL_R and the first node FN of the sense amplifier 11. The second node SN of the sense amplifier 11 is not connected to any bit line. Thus, a load applied to the second node SN is much lower than that applied to the first node FN.

In the current embodiment, the semiconductor memory device has an Only Bitline On Cell (OBOC) configuration, in which the first node FN of the sense amplifier 11 is connected to the bit line BL_L or BL_R respectively via the isolation transistor IST_L or IST_R and the second node SN of the sense amplifier 11 is not connected to any bit line. That is, in the OBOC configuration, only the bit lines BL_L and BL_R are present in the memory cell array blocks M_L and M_R, respectively, and no complementary bit line is present therein, unlike the open bit line configuration illustrated in FIG. 1.

The first isolation control circuit 73 selectively applies the word line supply voltage VPP, the ground voltage VSS, or the first intermediate voltage VISO1 illustrated in FIGS. 3 to 40 between the word line supply voltage VPP and the ground voltage VSS as the first gate voltage Va to a gate of the first isolation transistor IST_L via the first isolation line ISO_L. The second isolation control circuit 75 selectively applies the word line supply voltage VPP, the ground voltage VSS, or the second intermediate voltage VISO2 illustrated in FIGS. 3 to 40 between the word line supply voltage VPP and the ground voltage VSS as the second gate voltage Vb to the gate of the second isolation transistor IST_R via the second isolation line ISO_R.

The first selection transistor ST1 applies a voltage of the first node FN of the sense amplifier 11 to an IO line LIO, in response to a column selection signal CSL. As an alternative to the particular configuration illustrated in FIG. 2, the first selection transistor ST1 may be located between the first isolation transistor IST_L and the P type sense amplifier 111.

FIG. 3 illustrates a detailed circuit diagram of the first isolation control circuit 13 or 73 and the second isolation control circuit 15 or 75 in FIG. 1 or 2, according to an embodiment of the inventive concept. For convenience of explanation, FIG. 3 also illustrates a first intermediate voltage generator 23, a second intermediate voltage generator 24, a first multiplexer 25, and a second multiplexer 26. The first intermediate voltage generator 23, the second intermediate voltage generator 24, the first multiplexer 25, and the second multiplexer 26 may also be included in the semiconductor memory devices illustrated in FIGS. 1 and 2.

The first intermediate voltage generator 23 generates the first intermediate voltage VISO1 and the second intermediate voltage generator 24 generates the second intermediate voltage VISO2. The first multiplexer 25 selects the first intermediate voltage VISO1 or the second intermediate voltage VISO2 and applies the selected intermediate voltage to the first isolation control circuit 13, according to a block selection signal BLK_SEL. That is, the first multiplexer 25 may select the first intermediate voltage VISO1 and apply it to the first isolation control circuit 13 when the block selection signal BLK_SEL is at a first logic level, and may select the second intermediate voltage VISO2 and apply it to the first isolation control circuit 13 when the block selection signal BLK_SEL is at a second logic level.

The second multiplexer 26 selects the first intermediate voltage VISO1 or the second inteimmediate voltage VISO2 and applies it to the second isolation control circuit 15 according to the block selection signal BLK_SEL. That is, the second multiplexer 26 may select the second intermediate voltage VISO2 and apply it to the second isolation control circuit 15 when the block selection signal BLK_SEL is at the first logic level, and may select the first intermediate voltage VISO1 and apply it to the second isolation control circuit 15 when the block selection signal BLK_SEL is at the second logic level.

In other words, if the block selection signal BLK_SEL is at the first logic level, then the first intermediate voltage VISO1 is applied to the first isolation control circuit 13 and the second intermediate voltage VISO2 is applied to the second isolation control circuit 15. If the block selection signal BLK_SEL is at the second logic level, then the second intermediate voltage VISO2 is applied to the first isolation control circuit 13 and the first intermediate voltage VISO1 is applied to the second isolation control circuit 15. If the second intermediate voltage VISO2 is applied to the first isolation control circuit 13 and the first intermediate voltage VISO1 is applied to the second isolation control circuit 15, then the NMOS transistor N22 is turned on in the first isolation control circuit 13 and the second intermediate voltage VISO2 is applied as the first gate voltage Va to the gate of the first isolation transistor IST_L via the turned on NMOS transistor N22 and the first isolation line ISO_L. In addition, if the NMOS transistor N24 is turned on in the second isolation control circuit 15, the first intermediate voltage VISO1 is applied as the second gate voltage Vb to the gate of the second isolation transistor IST_R via the turned on NMOS transistor N24 and the second isolation line ISO_R.

The first isolation control circuit 13 or 73 includes a PMOS transistor P21 controlled by a signal ISOL_ON, a PMOS transistor P22 controlled by a signal ISOLB, an NMOS transistor N21 controlled by the signal ISOLB, and an NMOS transistor N22 controlled by a signal VISO1_ON. The first isolation control circuit 13 or 73 selectively applies the word line supply voltage VPP, the ground voltage VSS, or the first intermediate voltage VISO1 (in accordance with example timing diagrams illustrated in FIGS. 4 to 30) between the word line supply voltage VPP and the ground voltage VSS as a first gate voltage Va to a gate of a first isolation transistor IST_L via a first isolation line ISO_L.

The second isolation control circuit 15 or 75 includes a PMOS transistor P23 controlled by a signal ISOR_ON, a PMOS transistor P24 controlled by a signal ISORB, an NMOS transistor N23 controlled by the signal ISORB, and an NMOS transistor N24 controlled by a signal VISO2_ON. The second isolation control circuit 15 or 75 selectively applies the word line supply voltage VPP, the ground voltage VSS, or a second intermediate voltage VISO2 (in accordance with example timing diagrams illustrated in FIGS. 4 to 30) between the word line supply voltage VPP and the ground voltage VSS as a second gate voltage Vb to a gate of a second isolation transistor IST_R via a second isolation line ISO_R.

FIGS. 4 to 9 illustrate timing diagrams of the first gate voltage Va and the second gate voltage Vb output respectively from the first isolation control circuit 13 or 73 and the second isolation control circuit 15 or 75 respectively via the first isolation line ISO_L and the second isolation line ISO_R illustrated in FIG. 1 or 2, according to an embodiment of the inventive concept. The first gate voltage Va and the second gate voltage Vb, which are output from the first isolation control circuit 13 and the second isolation control circuit 15, respectively, will now be described with reference to FIGS. 4 to 9. The first gate voltage Va, i.e., a voltage applied to the gate of the first isolation transistor IST_L, and the second gate voltage Vb, i.e., a voltage applied to the gate of the second isolation transistor IST_R, may be set according to one of CASES 11 to 53.

Thus, the first intermediate voltage VISO1 and the second intermediate voltage VISO2 may be equal to a word line supply voltage VPP, a ground voltage VSS, a voltage VPP/2, i.e., half the word line supply voltage VPP, a voltage that is lower than the word line supply voltage VPP and greater than the voltage VPP/2, and a voltage that is lower than the voltage VPP/2 and greater than the ground voltage VSS. The first intermediate voltage VISO1 and the second intermediate voltage VISO2 are equal to the first gate voltage Va and the second gate voltage Vb, respectively, for a predetermined time period before and after sensing begins.

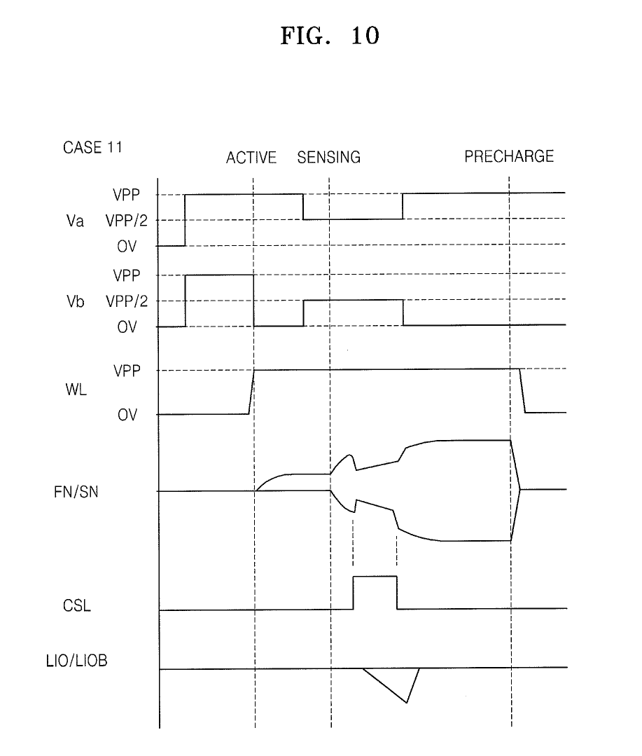

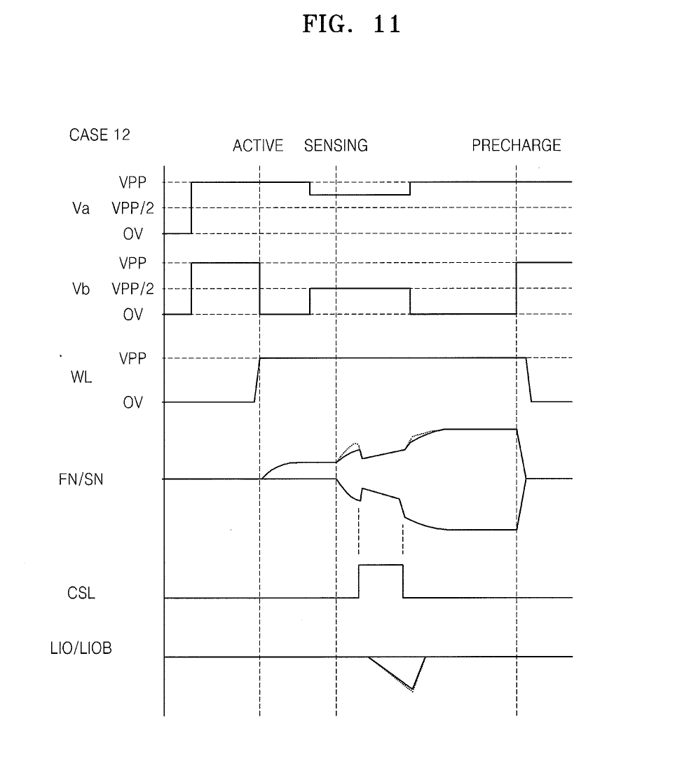

FIGS. 10 to 30 are timing diagrams of memory core parts of the semiconductor memory devices illustrated in FIGS. 1 and 2 according to embodiments of the inventive concept. Referring to FIGS. 11 to 30, in CASES 12, 13, 21, 22, 31, 32, 33, 41, 42, 51, 52, and 53, dotted lines marked on graphs corresponding to the first node/second node FN/SN and the JO line/complementary IO line LIO/LIOB denote operating values of the first node/second node FN/SN and the JO line/complementary IO line LIO/LIOB illustrated in CASE 11 of FIG. 10, respectively. Also, in CASES 31-1, 32-1, 33-1, 41-1, 42-1, 51-1, 52-1, and 53-1, dotted lines marked on graphs corresponding to the first node/second node FN/SN denote a variation in the operating value of the first node/second node FN/SN when the first gate voltage Va and the second gate voltage Vb are changed as marked by dotted lines on graphs corresponding to the first and second gate voltages Va and Vb.

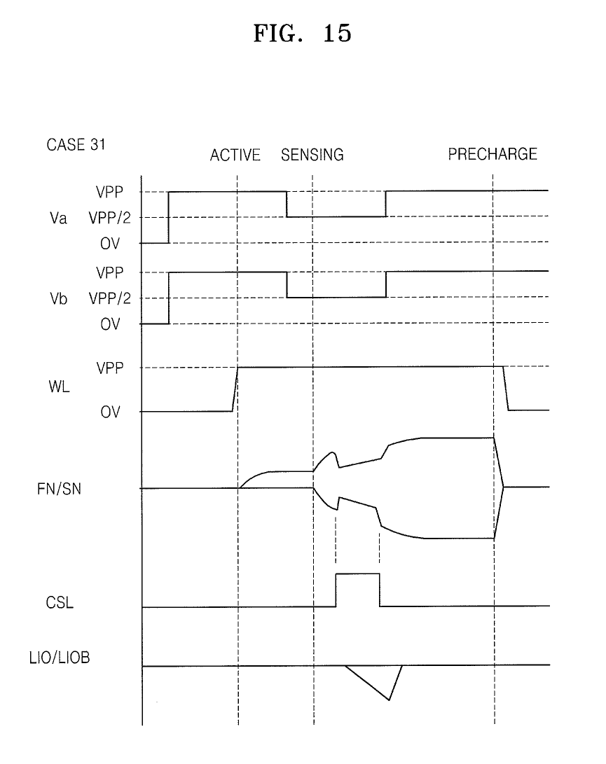

In CASE 11 of FIG. 4, 5, or 10, the first gate voltage Va changes in a way similar to the way the first gate voltage Va changes in CASE 31 of FIG. 15, but the second gate voltage Vb is equal to the second intermediate voltage VISO2, which is half the word line supply voltage VPP when the word line WL_L is activated, in a predetermined time period. After the predetermined time period, the second gate voltage Vb becomes equal to the ground voltage VSS again. Thus, referring to FIG. 1 or 2, during a sensing operation of the sense amplifier 11, the first isolation transistor IST_L is turned on, but is turned off in a section where the ground voltage VSS is applied to the gate of the second isolation transistor IST_R, and is turned on only in a section where the second intermediate voltage VISO2 is applied to the gate of the second isolation transistor IST_R.

Referring to CASE 31 of FIG. 4, 7, or 15, in the semiconductor memory device having the open bit line configuration illustrated in FIG. 1, if the first memory cell MC_L of the first memory cell array block M_L is selected, i.e., if the first word line WL_L connected to the memory cell MC_L is activated and is equal to the word line supply voltage VPP (an active section ACTIVE illustrated in FIG. 4, 7, or 15), then the first isolation control circuit 13 applies the word line supply voltage VPP to the gate of the first isolation transistor ISTL via the first isolation line IST_L and the second isolation control circuit 15 applies the word line supply voltage VPP to the gate of the second isolation transistor IST_R via the second isolation line ISO_R.

Accordingly, the first isolation transistor IST_L and the second isolation transistor IST_R are fully turned on and charges in the selected first memory cell MC_L are delivered to the first node FN of the sense amplifier 11 via the first bit line BL_L and the first isolation transistor IST_L. It is noted from the graph corresponding to the first node/second node FN/SN of FIG. 15 that the charges are delivered to the first node FN. Thus, the voltage of the first node FN gradually increases after the active section ACTIVE. Thus, charge sharing is performed. When charge sharing is completed, the sensing operation of the sense amplifier 11 starts. That is, the sense amplifier 11 starts amplifying the difference between the voltages of the first node FN and the second node SN. As shown in the graph corresponding to the first node/second node FN/SN of FIG. 15, the difference between the voltages of the first node/second node FN/SN becomes larger when the amplification starts.

For a predetermined time period before and after the sensing operation of the sense amplifier 11 starts (a sensing section SENSING of FIG. 4, 7, or 15), the first isolation control circuit 13 applies the first intermediate voltage VISO1, which is half the word line supply voltage VPP, as the first gate voltage Va to the gate of the first isolation transistor IST_L via the first isolation line ISO_L, and the second isolation control circuit 15 applies the second intermediate voltage VISO2, which is also half the word line supply voltage VPP, as the second gate voltage Vb to the gate of the second isolation transistor IST_R via the second isolation line ISO_R. At the beginning of the sensing operation of the sense amplifier 11, the first and second gate voltages Va and Vb, respectively from the first isolation transistor IST_L and the second isolation transistor IST_R, are each half the word line supply voltage VPP. Thus, the first and second isolation transistors IST_L and IST_R are not fully turned on, i.e., are only weakly turned on, at the beginning of the sensing operation of the sense amplifier 11. Thus, a load applied to the sense amplifier 11, which is influenced by the capacitances of the first and second bit lines BL_L and BL_R, may be reduced. Accordingly, loading mismatch between the first and second nodes FN and SN of the sense amplifier 11, which occurs more often as a semiconductor manufacture processes becomes more miniaturized, is minimized, enhancing the sensing speed of the sense amplifier 11.

After the predetermined time period, i.e., when the sensing operation of the sense amplifier 11 is completed, the first isolation control circuit 13 applies the word line supply voltage VPP again to the gate of the first isolation transistor IST_L via the first isolation line ISO_L and the second isolation control circuit 15 applies the word line supply voltage VPP again to the gate of the second isolation transistor IST_R via the second isolation line ISO_R.

While the first word line WL_L is deactivated, i.e., before the active section ACTIVE and after the precharge section PRECHARGE illustrated in FIG. 4, 7, or 15, the first isolation control circuit 13 and the second isolation control circuit 15 apply the word line supply voltage VPP to the gate of the first isolation transistor IST_L and the gate of the second isolation transistor IST_R, respectively.

In CASE 51 illustrated in FIG. 4, 9, or 25, the first gate voltage Va changes in a way similar to the way the first gate voltage Va changes in CASE 11. However, in CASE 51, the second isolation control circuit 15 applies the ground voltage VSS to the gate of the second isolation transistor IST_R from when the word line WL_L is activated and is equal to the word line supply voltage VPP (the active section ACTIVE illustrated in FIG. 4, 9, or 25) to when the word line WL_L is deactivated (the precharge section PRECHARGE illustrated in FIG. 4, 9, or 25). In this case, the first isolation transistor IST_L is turned on and the second isolation transistor IST_R is turned off during the sensing operation of the sense amplifier 11. Thus, the load applied to the sense amplifier 11, which is influenced by the capacitance of the second bit line BL_R, is greatly minimized, thus greatly reducing the load applied to the second node SN of the sense amplifier 11.

As described above, as illustrated in the CASES 11, 31, and 51 illustrated in FIG. 4, in a semiconductor memory device according to an embodiment of the inventive concept, resistances between the sense amplifier 11 and the first bit line BL_L and between the sense amplifier 11 and the second bit line BL_R are determined by the first and second gate voltages Va and Vb applied to the gates of the first and second isolation transistors IST_L and IST_R, respectively. That is, the first and second gate voltages Va and Vb are inversely proportional to the resistances between the sense amplifier 11 and the first bit line BL_L and between the sense amplifier 11 and the second bit line BL_R.

If the first and second gate voltages Va and Vb are large, then the resistances between the sense amplifier 11 and the first bit line BL_L and between the sense amplifier 11 and the second bit line BL_R are small, increasing the load applied to the sense amplifier 11, which includes all capacitance loadings of the first and second bit lines BL_L and BL_R, thereby lowering the sensing speed of the sense amplifier 11. However, the lower the first and second gate voltages Va and Vb, the greater the resistances between the sense amplifier 11 and the first bit line BL_L and between the sense amplifier 11 and the second bit line BL_R. Thus, the capacitances of the first bit line BL_L and the second bit line BL_R gradually decrease, lowering the total capacitance of the sense amplifier 11, and only the capacitance of the sense amplifier 11 is retained. In this case, the capacitance loading values of the first bit line BL_L and the second bit line BL_R are far greater than the loading value of the sense amplifier 11, and are less than the capacitance loading value of the sense amplifier 11. During the sensing operation of the sense amplifier 11, the loading values of the first node FN and the second node SN are small. Thus, the sensing speed of the sense amplifier 11 is better when the first gate voltage Va applied to the first isolation transistor IST_L and the second gate voltage Vb applied to the second isolation transistor IST_R are low than when the first and second gate voltages Va and Vb are high.

In other words, the first isolation transistor IST_L and the first isolation control circuit 13 control the capacitance loading of the first bit line BL_L, and the second isolation transistor ISTR and the second isolation control circuit 15 control the capacitance loading of the second bit line BL_R. At the beginning of the sensing operation of the sense amplifier 11, the intermediate voltages VISO1 and VISO2 are lower than the word line supply voltage VPP and higher than the ground voltage VSS, and the first and second isolation control circuits 13 and 15 (73 and 75) apply the intermediate voltages VISO1 and VISO2 to the gates of the first and second isolation transistors IST_L and IST_R, respectively. Thus, the first isolation transistor IST_L and the second isolation transistor IST_R are weakly turned on, reducing the capacitance loadings of the first bit line BL_L and the second bit line BL_R. Therefore, during the sensing operation of the sense amplifier 11, the loading values of the first node FN and second node SN are small. Thus, the sensing speed of the sense amplifier 11 is better when the first and second gate voltages Va and Vb applied to the first and second isolation transistors IST_L and IST_R are low than when the first and second gate voltages Va and Vb are high.

Also, as illustrated in FIGS. 4 to 30 and 33, the first intermediate voltage VISO1 applied to the first isolation transistor IST_L may be set to be different from the second intermediate voltage VISO2 applied to the second isolation transistor IST_R in order to reduce effects caused by the difference between the loading values of the first node FN and second node SN of the sense amplifier 11, i.e., bit line loading mismatch. In this case, effects caused by threshold voltage mismatch occurring between transistors included in the sense amplifier 11 may also be reduced. Accordingly, the sensing performance of the sense amplifier 11 may be enhanced.

The operations of the first isolation control circuit 13 or 73 and the second isolation control circuit 15 or 75 illustrated in FIG. 3 will now be described based on CASE 31 of FIG. 4, 7, or 15. If the first word line WL_L connected to the first memory cell MC_L of FIG. 1 is activated and is equal to the word line supply voltage VPP (the active section ACTIVE of FIG. 4, 7, or 15), then the signal ISOL_ON, the signal ISOLB, and the signal VISO1_ON are all logic low. Thus, the PMOS transistors P21 and P22 are turned on and the NMOS transistors N21 and N22 are turned off. Also, in this case, the signal ISOR_ON, the signal ISORB, and the signal VISO2_ON are all logic low. Thus, the PMOS transistors P23 and P24 are turned on and the NMOS transistors N23 and N24 are turned off. Thus, the word line supply voltage VPP is applied to the first isolation line ISO_L via the turned on PMOS transistors P21 and P22 and to the second isolation line ISO_R via the turned on PMOS transistors P23 and P24.

Next, after a predetermined time period before and after the sensing operation of the sense amplifier 11 starts (the sensing section SENSING of FIG. 4, 7, or 15), the signal VISO1_ON is logic high, and the NMOS transistor N22 is thus turned on and the PMOS transistors P21 and P22 and the NMOS transistor N21 are turned off. Also, for the predetermined time period before and after the sensing operation of the sense amplifier 11 starts, the signal VISO2_ON is also logic high, and the NMOS transistor N24 is thus turned on, and the PMOS transistors P23 and P24, and the NMOS transistor N23 are turned off. Accordingly, the first intermediate voltage VISO1 is applied as the first gate voltage Va to the first isolation line ISO_L via the turned on NMOS transistor N22, and the second intermediate voltage VISO2 is applied as the second gate voltage Vb to the second isolation line ISO_R via the turned on NMOS transistor N24.

After the predetermined time period, the signal VISO1_ON is logic low again to turn off the NMOS transistor N22 and the signals ISOL_ON and ISOLB are logic low to turn on the PMOS transistors P21 and P22. Also, in this case, the signal VISO2_ON is also logic low to turn off the NMOS transistor N24 and the signals ISOR_ON and ISORB are logic low to turn on the PMOS transistors P23 and P24. Thus, the word line supply voltage VPP is applied again as the first gate voltage Va to the first isolation line ISO_L via the turned on PMOS transistors P21 and P22 and is applied again as the second gate voltage Vb to the second isolation line ISO_R via the turned on PMOS transistors P23 and P24.

If no memory cell is selected, i.e., while the first word line WL_L is deactivated (before the active section ACTIVE and after the precharge section PRECHARGE illustrated in FIG. 4), the signal ISOL_ON, the signal ISOLB, and the signal VISO1_ON are all logic low, thus turning on the PMOS transistors P21 and P22 and turning off the NMOS transistors N21 and N22. Also, the signal ISOR_ON, the signal ISORB, and the signal VISO2_ON are all logic low, thus turning on the PMOS transistors P23 and P24 and turning off the NMOS transistors N23 and N24. Thus, while the first word line WL_L is deactivated, the word line supply voltage VPP is applied as the first gate voltage Va to the first isolation line ISO_L via the turned on PMOS transistors P21 and P22 and is applied as the second gate voltage Vb to the second isolation line ISO_R via the turned on PMOS transistors P23 and P24.

CASES 11 and 51 illustrated in FIG. 4 may be embodied by controlling the voltages of the signals ISOL_ON, ISOLB, and VISO1_ON of FIG. 3, and the voltages of the signals ISOR_ON, ISORB, and VISO2_ON. Thus, CASES 11 and 51 will not be described here.

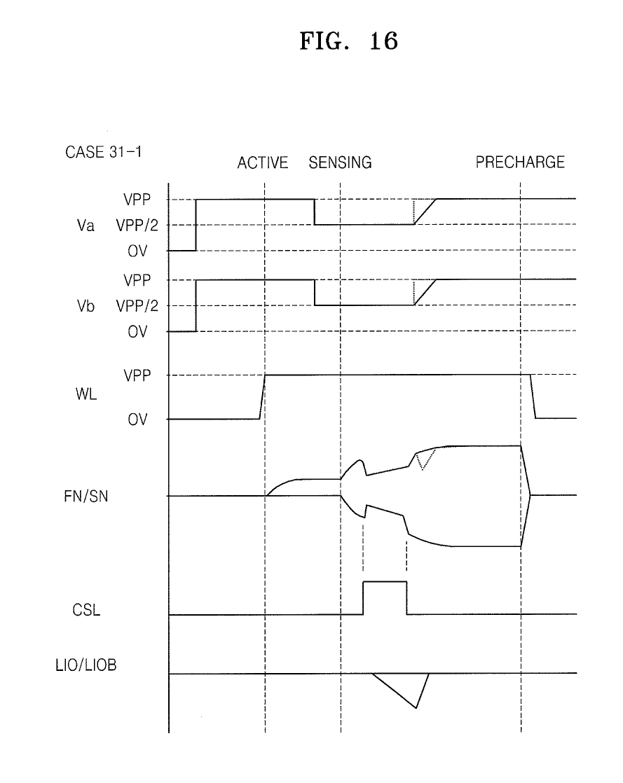

FIG. 16 illustrates a timing diagram of CASE 31-1 of a case, marked by a solid line, in which the first gate voltage Va and the second gate voltage Vb are gradually increased over time from the voltage VPP/2 to the word line supply voltage VPP as compared to the case in CASE 31 of FIG. 15, marked by a dotted line, in which the first gate voltage Va and the second gate voltage Vb are suddenly increased from the voltage VPP/2 to the word line supply voltage VPP.

With reference to FIGS. 1 and 2, if the first and second gate voltages Va and Vb are increased directly from the voltage VPP/2 to the word line supply voltage VPP as marked by the dotted line in FIG. 16, the bit line BL_L and the first node FN are connected directly to each other. If the voltage of the first bit line BL_L is low, then the difference between the voltages of the bit line BL_L and the first node FN is large and the bit line BL_L is thus connected directly to the first node FN. In this case, the voltage of the first node FN may be lowered instantaneously as marked by a dotted line in the graph corresponding to the first node/second node FN/SN of FIG. 16. In order to prevent this problem, the first and second gate voltages Va and Vb may be increased gradually so that the voltage of the first node FN may change as marked by the solid line in the graph of the first node/second node FN/SN of FIG. 16 even when the voltage of the bit line BL_L is low and the difference between the voltages of the bit line BL_L and the first node FN is large.

As described above with reference to FIG. 16, dotted lines marked in FIGS. 18, 20, 22, 24, 26, 28, and 30 denote a case where the first and second gate voltages Va and Vb are increased directly from the voltage VPP/2 to the word line supply voltage VPP. In this case, it is possible to prevent the voltage of the first node FN from being lowered by gradually increasing the first and second gate voltages Va and Vb from the voltage VPP/2 to the word line supply voltage VPP, as marked by a solid line.

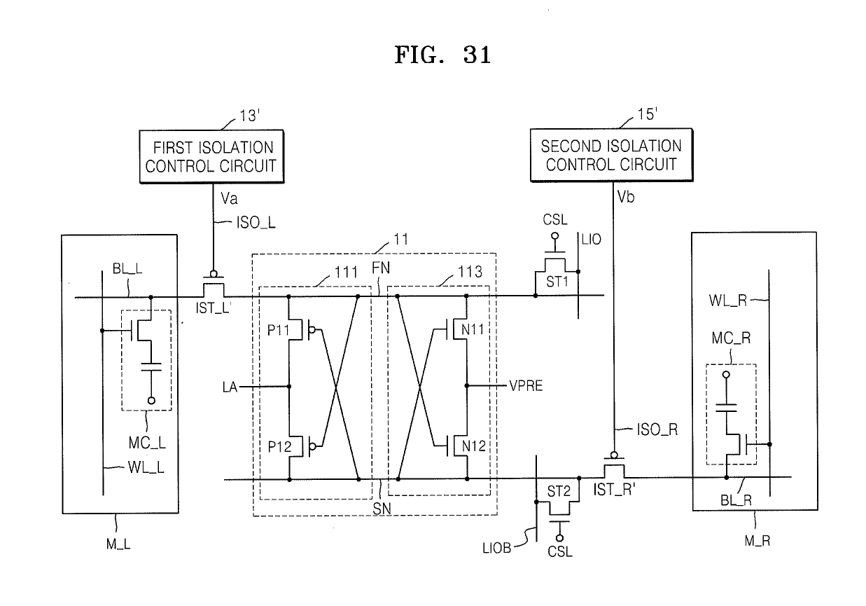

FIG. 31 illustrates a circuit diagram of a semiconductor memory device according to another embodiment of the inventive concept. Referring to FIG. 31, the semiconductor memory device is different from the semiconductor memory device of FIG. 1 in that a first isolation transistor IST_L′ and a second isolation transistor IST_R′ are PMOS transistors. Thus, the polarities of output signals of a respective first isolation control circuit 13′ and a second isolation control circuit 15′, which are output via a first isolation line ISO_L and a second isolation line ISO_R, respectively (see FIG. 4), are opposite to those of the output signals of the respective first isolation control circuit 13 and second isolation control circuit 15 of FIG. 1.

FIG. 32 illustrates a circuit diagram of a semiconductor memory device according to another embodiment of the inventive concept. Referring to FIG. 32, the semiconductor memory device is different from the semiconductor memory device of FIG. 31 in that a first isolation transistor IST_L′ and a second isolation transistor IST_R′ are PMOS transistors. Thus, the polarities of output signals of a first isolation control circuit 73′ and a second isolation control circuit 75′, which are output via a first isolation line ISO_L and a second isolation line ISO_R, respectively, are opposite to those of the first isolation control circuit 73 and the second isolation control circuit 75 of FIG. 2.

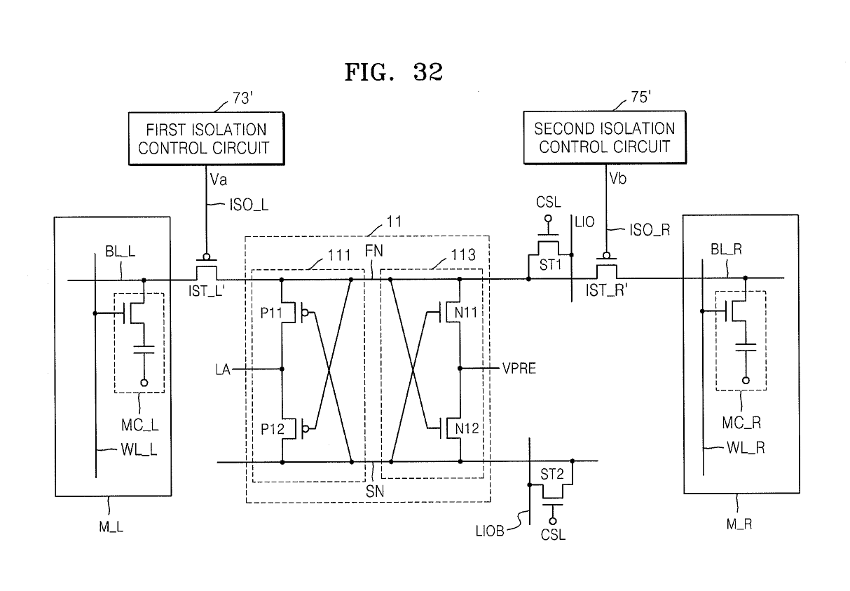

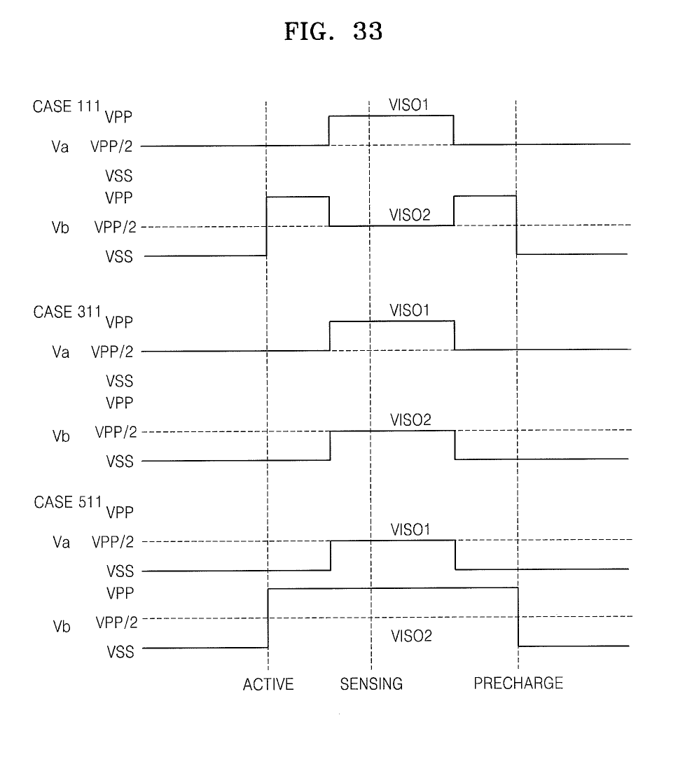

FIG. 33 illustrates a timing diagram of the first isolation control circuit 13′ or 73′ and the second isolation control circuit 15′ or 75′ illustrated in FIG. 31 or 32, according to an embodiment of the inventive concept. The first isolation control circuit 13′ or 73′ and the second isolation control circuit 15′ or 75′ may be operated according to CASE 111, CASE 311, or CASE 511 of FIG. 33. Referring to FIG. 33, the polarities of output signals of the respective first isolation control circuit 13′ or 73′ and second isolation control circuit 15′ or 75′, which are output via a first isolation line ISO_L and a second isolation line ISO_R, respectively, are opposite to those as illustrated in FIG. 4. Thus, the operations of the first isolation control circuits 13′ and 73′ and the second isolation control circuits 15′ and 75′ illustrated in FIGS. 31 and 32 are the same as those of the first isolation control circuit 13 and the second isolation control circuit 15 of FIG. 1 except for polarity thereof.

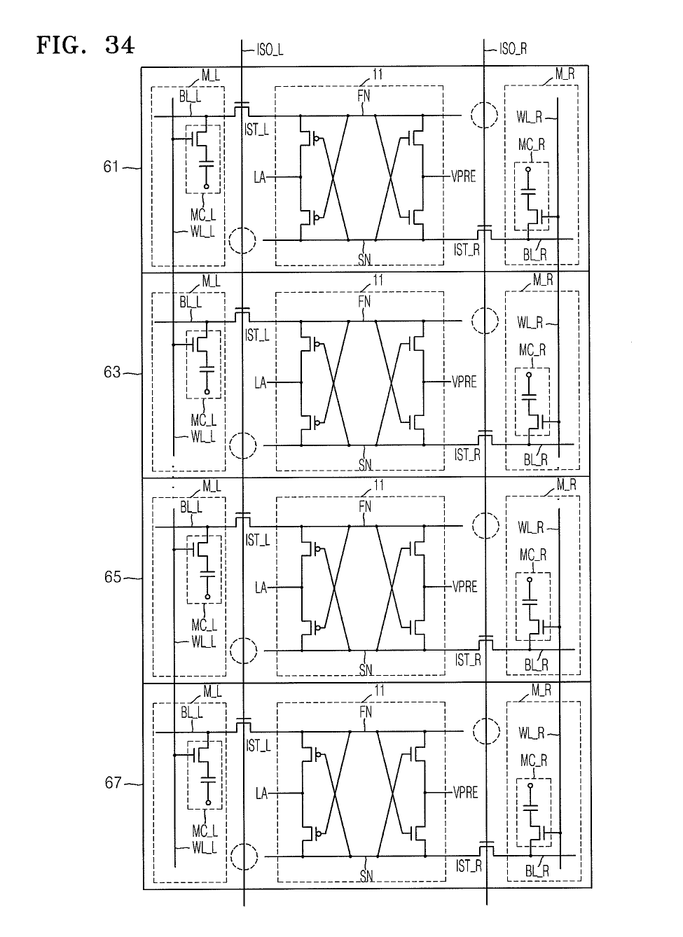

FIG. 34 illustrates arrangement of a plurality of unit blocks 61 to 67 that may be included in the semiconductor memory device of FIG. 1, according to an embodiment of the inventive concept. A degree of threshold voltage mismatch occurring among transistors included in the sense amplifier 11 may not be the same as with the plurality of unit blocks 61 to 67 illustrated in FIG. 34. Thus, the semiconductor memory device of FIG. 1 may further include the first voltage generator 23, the second intermediate voltage generator 24, the first multiplexer 25, and the second multiplexer 26, so that the first intermediate voltage VISO1 or the second intermediate voltage VISO2 may be selected according to the unit blocks 61 to 67.

As described above, in the semiconductor memory device of FIG. 1, the first intermediate voltage VISO1 or the second intermediate voltage VISO2 is selected according to the unit blocks 61 to 67 and the selected intermediate voltage is applied to the gates of the first and second isolation transistors IST_L and IST_R. Thus, in all the unit blocks 61 to 67, the threshold voltage mismatch between transistors included in the sense amplifier 11 may be efficiently controlled.

Referring to FIG. 34, each of the unit blocks 61 to 67 includes the first memory cell array block M_L, the second memory cell array block M_R, the sense amplifier 11, the first isolation transistor IST_L, and the second isolation transistor IST_R illustrated in FIG. 1.

The unit blocks 61 to 67 have the open bit line configuration, in which a pair of a bit line BL_L and a bit line BL_R connected to the sense amplifier 11 via the first and second isolation transistors IST_L and IST_R, respectively, are arranged in different memory cell array blocks. A second node SN of the sense amplifier 11 is not connected to the bit line BL_L on the memory cell array block M_L.

Gates of the first isolation transistors IST_L in the respective unit blocks 61 to 67 are commonly connected to a first isolation line ISO_L, and gates of the second isolation transistors IST_R in the respective unit blocks 61 to 67 are commonly connected to a second isolation line ISO_R. The first isolation line ISO_L is connected to an output terminal of the first isolation control circuit 13 illustrated in FIG. 1 and the second isolation line ISO_R is connected to an output terminal of the second isolation control circuit 15 illustrated in FIG. 1.

Referring to FIG. 34, one transistor is connected to the first isolation line ISO_L and one transistor is connected to the second isolation line ISO_R for each of the unit blocks 61 to 67.

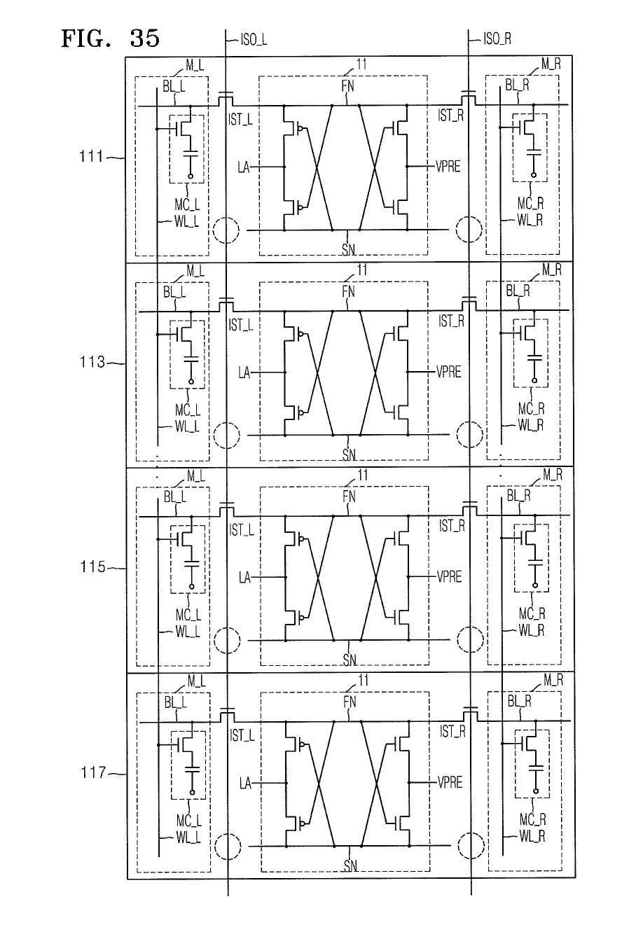

FIG. 35 illustrates arrangement of a plurality of unit blocks 111 to 117 that may be included in the semiconductor memory device of FIG. 2, according to another embodiment of the inventive concept. Referring to FIG. 35, each of the unit blocks 111 to 117 includes the first memory cell array block M_L, the second memory cell array block M_R, the sense amplifier 11, the first isolation transistor IST_L, and the second isolation transistor IST_R illustrated in FIG. 2.

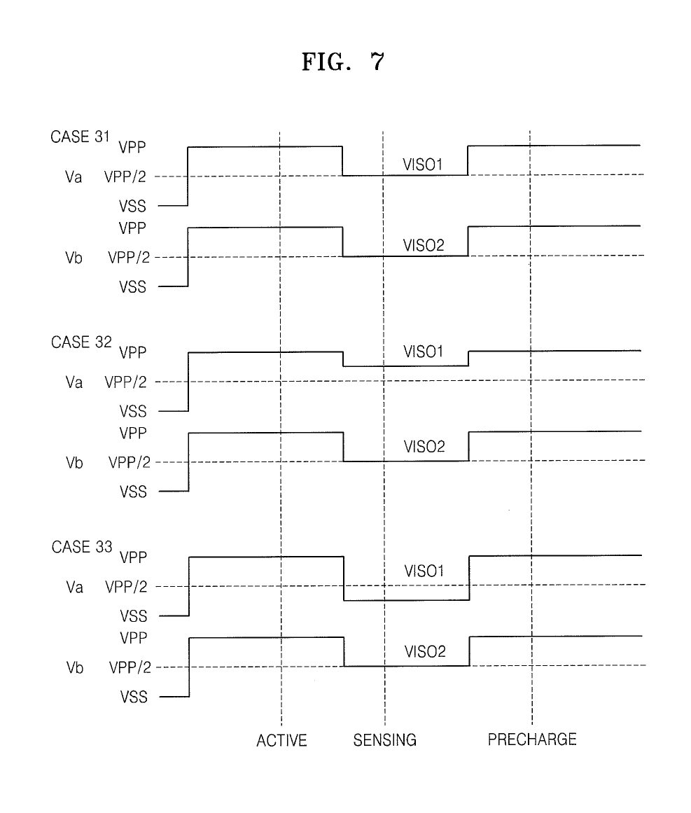

The unit blocks 111 to 117 have the OBOC configuration, in which a first node of the sense amplifier 11 is connected to a bit line BL_L or BL_R via the first or second isolation transistor IST_L or IST_R and a second node SN of the sense amplifier 11 is not connected to any bit line. Gates of the first isolation transistors IST_L in the respective unit blocks 111 to 117 are commonly connected to a first isolation line ISO_L, and gates of the second isolation transistors IST_R in the respective unit blocks 111 to 117 are commonly connected to a second isolation line ISO_R. The first isolation line ISO_L is connected to an output terminal of the first isolation control circuit 73 illustrated in FIG. 7 and the second isolation line ISO_R is connected to an output terminal of the second isolation control circuit 75 illustrated in FIG. 7.

Referring to FIG. 35, one transistor is connected to the first isolation line ISO_L and one transistor is connected to the second isolation line ISO_R for each of the unit blocks 111 to 117.

FIG. 36 illustrates a circuit diagram of a semiconductor memory device according to another embodiment of the inventive concept. The semiconductor memory device of FIG. 36 employs a supply voltage (VDD) precharge method. The semiconductor memory device of FIG. 36 is the same as the semiconductor memory device having the open bit line configuration illustrated in FIG. 1 except that an internal structure of a sense amplifier 31 is different from that of the sense amplifier 11 included in the semiconductor memory device of FIG. 1.

The sense amplifier 31 includes the first node FN, the second node SN, a P type sense amplifier 313, and an N type sense amplifier 311. The P type sense amplifier 313 includes a first PMOS transistor P31 and a second PMOS transistor P32 connected in series between the first node FN and the second node SN, and receives a precharge voltage via a precharge voltage terminal VPRE. The N type sense amplifier 311 includes a first NMOS transistor N31 and a second NMOS transistor N32 connected in series between the first node FN and the second node SN, and receives a sensing voltage via a sensing enable signal input terminal LA. The precharge voltage may be a supply voltage VDD.

FIG. 37 illustrates a circuit diagram of a semiconductor memory device according to another embodiment of the inventive concept. The semiconductor memory device of FIG. 37 employs the supply voltage (VDD) precharge method. The semiconductor memory device of FIG. 37 is the same as the semiconductor memory device having the OBOC configuration illustrated in FIG. 2, except that an internal structure of a sense amplifier 41 is different from that of the sense amplifier 11 included in the sense amplifier 11 of FIG. 2.

The sense amplifier 41 includes the first node FN, the second node SN, a P type sense amplifier 413, and an N type sense amplifier 411. The P type sense amplifier 413 includes a first PMOS transistor P41 and a second PMOS transistor P42 connected in series between a first node FN and a second node SN, and receives a precharge voltage via a precharge voltage terminal VPRE. The N type sense amplifier 411 includes a first NMOS transistor N41 and a second NMOS transistor N42 connected in series between the first node FN and the second node SN, and receives a sensing voltage via a sensing enable signal input terminal LA. The precharge voltage may be the supply voltage VDD.

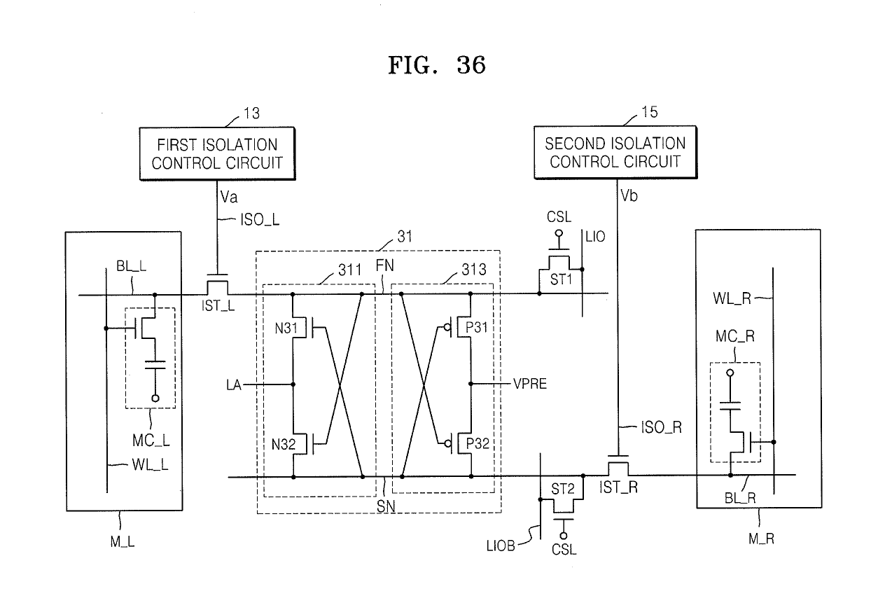

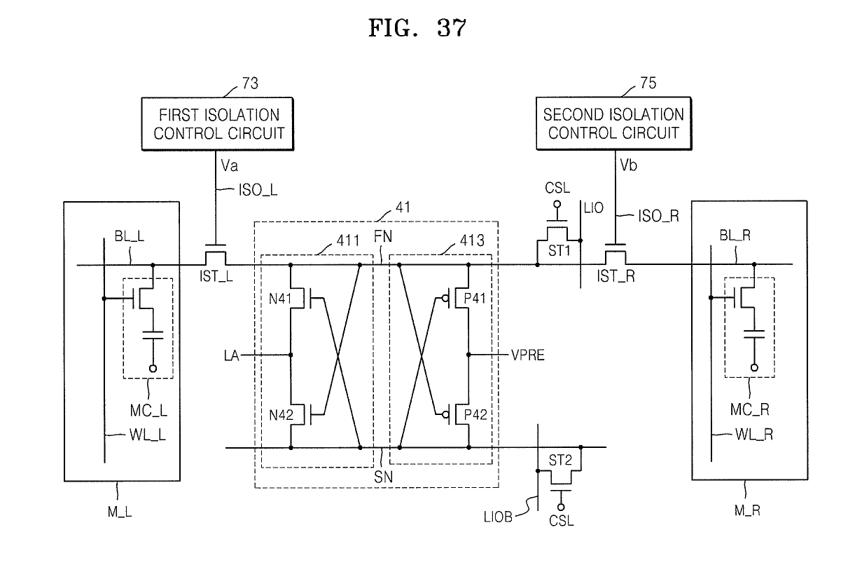

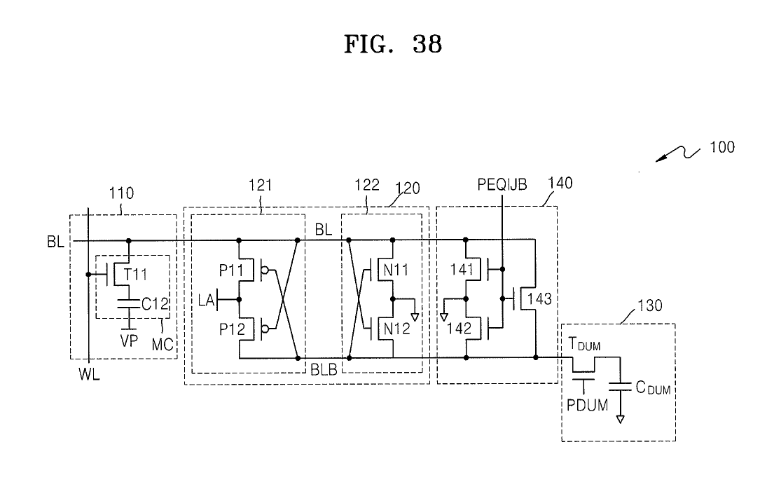

FIG. 38 illustrates a circuit diagram of a semiconductor memory device 100 according to another embodiment of the inventive concept. Referring to FIG. 38, the semiconductor memory device 100 is embodied as dynamic random access memory (DRAM) device that includes a memory cell array block 110, a sense amplifier 120, a dummy block 130, and an equalization unit 140. The memory cell array block 110 may include a plurality of memory cells each connected to a respective bit line and a respective word line. For convenience of explanation, FIG. 38 illustrates one memory cell MC arranged at an intersection of a word line WL and a bit line BL. The memory cell MC includes a cell transistor (1-transistor) T11, a gate and drain of which are connected to the word line WL and the bit line BL, respectively, and a cell capacitor (1-capacitor) C12 connected to a source of the first cell transistor T11 and a plate voltage source VP.

The sense amplifier 120 is connected to the memory cell array block 110 and the dummy block 130. The sense amplifier 120 senses and amplifies voltages of bit lines BL in the memory cell array block 110, and particularly, in the current embodiment, the sense amplifier 120 senses and amplifies the voltage of the bit line BL connected to the memory cell MC in the memory cell array block 110. The sense amplifier 120 includes a P type sense amplifier 121 and an N type sense amplifier 122 that sense and amplify a voltage between the bit line BL and a complementary bit line BLB.

The P type sense amplifier 121 includes the first PMOS transistor P11 and the second PMOS transistor P12 connected in series between the bit line BL and the complementary bit line BLB. The sensing driving voltage LA is applied to sources of the first and second PMOS transistors P11 and P12, and the complimentary bit line BLB and bit line BL are connected to the gate of the first PMOS transistor P11 and the gate of the second PMOS transistor P12, respectively. The first and second PMOS transistors P11 and P12 may be different or the same in size. The sensing driving voltage LA is applied in response to a sensing enable signal (not shown). The sensing driving voltage LA may be either a supply voltage to be applied to the semiconductor memory device 100 or an internal voltage generated from a supply voltage in the semiconductor memory device 100.

The N type sense amplifier 122 includes the first NMOS transistor N11 and the second NMOS transistor N12 connected in series between the bit line BL and the complementary bit line BLB. A ground voltage VSS is applied to sources of the first and second NMOS transistors N11 and N12, a gate of the first NMOS transistor N11 is connected to the complementary bit line BLB, and a gate of the second NMOS transistor N12 is connected to the bit line BL. The first and second NMOS transistors N11 and N12 may be different or the same in size.

The size of a memory cell, e.g., a DRAM cell, may be reduced using a miniaturization process and/or by changing a memory arrangement. Referring to FIG. 38, in the DRAM, an arrangement of the memory cell MC, which includes the cell transistor (1-transistor) T11 and the cell capacitor (1-capacitor) C12, and the sense amplifier 120, which senses and amplifies data received from the memory cell MC, is a major design factor that determines the chip size of the DRAM. Arrangement methods of the sense amplifier 120 and the memory cell array 110 connected to the sense amplifier 120 are classified largely into the open bit line configuration and the folded bit line configuration.

In the open bit line configuration, each of a plurality of memory cells is connected to a respective bit line and a respective word line. Thus, the open bit line configuration is advantageous in that a small-sized chip having high memory cell density can be fabricated. In the open bit line configuration, a sense amplifier is connected to a bit line and a complementary bit line that are disposed in different memory cell arrays and one sense amplifier is disposed in two bit line pitches. In the folded bit line configuration, one sense amplifier is disposed in four bit line pitches. Thus, the layout design of the sense amplifier is easier in the folded bit line configuration than in the open bit line configuration. However, the size of a memory cell in the folded bit line configuration is double that of a memory cell in the open bit line configuration, resulting in an increased chip size for the folded bit line configuration.

In memory cell arrays according to the open bit line configuration, every alternate bit line is connected to a sense amplifier from among a half of the bit lines of an outermost memory cell array and the other bit lines remain dummy bit lines. In the outermost memory cell array, the total area of dummy cells may be half the area of a block, and a memory capacity of memory cells disposed is thus greater than a desired memory capacity of the total (capacity) of memory cell arrays, thereby increasing chip size overhead. To solve this problem, referring to FIG. 38, in the current embodiment, one of dummy bit lines of the memory cell array block 110, i.e., an outermost memory cell array, is illustrated as the bit line BL of the memory cell MC in the memory cell array block 110, and the dummy block 130 is commonly connected to the bit line BL.

In the sense amplifier 120, the bit line BL is connected to the memory cell array block 110 but the complementary bit line BLB is not connected to any memory cell array block. That is, the memory cell array block 110 connected to the sense amplifier 120 has the OBOC which is a type of open bit line configuration. Thus, the sense amplifier 120 may be referred to as ‘an edge sense amplifier’.

The dummy block 130 includes a dummy transistor T_{DUM} and a dummy capacitor C_{DUM} connected to the complementary bit line BLB. A load applied to the dummy block 130 is determined by a load applied to the bit line BL of the memory cell array block 110, which is an outermost memory cell array. The dummy transistor T_{DUM} connects the dummy capacitor C_{DUM} to the complementary bit line BLB according to a dummy load signal PDUM. The dummy load signal. PDUM may control the load on the bit line BL of the memory cell array block 110 to be different from the load on the complementary bit line BLB of the dummy block 130. Thus, a load applied to the dummy block 130 is determined by a voltage of the dummy load signal PDUM and a capacitance of the dummy capacitor C_{DUM}. The voltage of the dummy load signal PDUM and the capacitance of the dummy capacitor C_{DUM} should satisfy the following equations:

$$\begin{matrix}{V}_{BLfar} = [ {R}_{BL} + \{ ( \frac{Time}{{C}_{BL}} ) // ( {R}_{CELL} + \frac{Time}{{C}_{CELL}} ) \} ] * {I}_{BL} + Δ {V}_{BL} & ( 1 ) \\ {V}_{BLnear} = [ {R}_{BL} + \{ ( \frac{Time}{{C}_{BL}} ) // ( {R}_{CELL} + \frac{Time}{{C}_{CELL}} ) \} ] * {I}_{BL} + Δ {V}_{BL} & ( 2 ) \\ {V}_{BLB} = [ {R}_{BLB} + ( \frac{Time}{{C}_{BLB}} ) ] * {I}_{BL} & ( 3 )\end{matrix}$$

wherein R_{BL} denotes a resistance of the bit line BL of the memory cell array block 110, C_{BL} denotes a capacitance of the bit line BL of the memory cell array block 110, R_{CELL} denotes a resistance of the memory cell transistor 111, C_{CELL} denotes a capacitance of the memory cell capacitor 112, R_{BLB} denotes a resistance of the dummy transistor T_{DUM} controlled by a voltage of the dummy load signal PDUM, C_{BLB} denotes a capacitance of the dummy capacitor C_{DUM}, and dVBL denotes the difference between the voltages of the bit line BL and the complementary bit line BLB after charge sharing is performed (hereinafter referred to as “the difference dVBL”).

The voltage of the dummy load signal PDUM and the capacitance of the dummy capacitor C_{DUM} are determined to be such that the difference dVBL may be positive or may be zero. When the difference dVBL is positive, the load on the bit line BL of the memory cell array block 110 may be greater than that on the complementary bit line BLB of the dummy block 130 when data of the memory cell MC is logic high. When the difference dVBL is 0 V, the load on the complementary bit line BLB of the dummy block 130 is greater than that on the bit line BL of the memory cell array block 110 when the data of the memory cell MC is logic low.

The equalization unit 140 equalizes voltages of the first node FN and the second node SN of the sense amplifier 120 with a ground voltage VSS according to an equalizing signal PEQIJB. The equalization unit 140 includes a first NMOS transistor 141 connected between a ground voltage VSS source and the first node FN, a second NMOS transistor 142 connected between the ground voltage VSS source and the second node SN, and a third NMOS transistor 143 connected between the first node FN and the second node SN. The equalizing signal PEQIJB is supplied to gates of the first to third NMOS transistors 141 to 143. The equalizing signal PEQIJB is logic high when supplied to the first to third NMOS transistors 141 to 143 during a precharge operation of the semiconductor memory device 100 so as to turn on the first to third NMOS transistors 141 to 143 and to precharge the first node FN and the second node SN to the ground voltage VSS. During active and sensing operations of the semiconductor memory device 100, the equalizing signal PEQIJB is logic low when supplied to the first to third NMOS transistors 141 to 143 to turn off the first to third NMOS transistors 141 to 143.

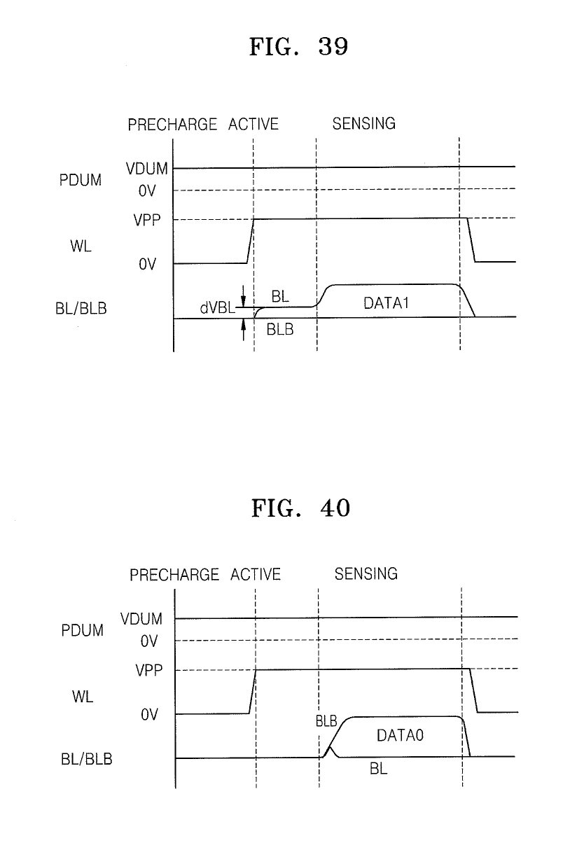

FIGS. 39 and 40 illustrate timing diagrams of operations of the semiconductor memory device 100 of FIG. 38 according to embodiments of the inventive concept. Specifically, FIG. 39 illustrates a timing diagram of an operation of the semiconductor memory device 100 of FIG. 38 when data of the memory cell MC is logic high, according to an embodiment of the inventive concept. FIG. 40 illustrates a timing diagram of an operation of the semiconductor memory device 100 of FIG. 38 when data of the memory cell MC is logic low, according to another embodiment of the inventive concept.

Referring to FIG. 39, the dummy load signal PDUM has a dummy voltage VDUM that is a constant DC voltage that satisfies Equations (1) to (3). In an active section where the word line WL is enabled having a word line supply voltage VPP, when the data of the memory cell MC is logic high, the bit line BL and the complementary bit line BLB are charge-shared, and the difference dVBL between voltages of the charge-shared bit line BL and complementary bit line BLB is positive. Then, in a sensing section where a sensing enable signal (not shown) is activated and the sensing driving voltage LA is applied, the difference between the voltages of the bit line BL and the complementary bit line BLB is sensed and amplified, and the bit line BL and the complementary bit line BLB approach the sensing driving voltage LA and the ground voltage VSS, respectively.

Referring to FIG. 40, the dummy load signal PDUM has a dummy voltage VDUM that is a constant DC voltage. In an active section, even if the word line WL is enabled having a word line supply voltage VPP, when data of the memory cell MC is logic low, the load on the bit line BL of the dummy block 130 is greater than that on the bit line BL of the memory cell array block 110, and the bit line BL and the complementary bit line BLB are not charge-shared. Then, in a sensing section where the sensing enable signal is enabled and the sensing driving voltage LA is applied, the difference between the voltages of the bit line BL and the complementary bit line BLB is sensed and amplified. Thus, the bit line BL and the complementary bit line BLB approach the ground voltage VSS and the sensing driving voltage LA, respectively.

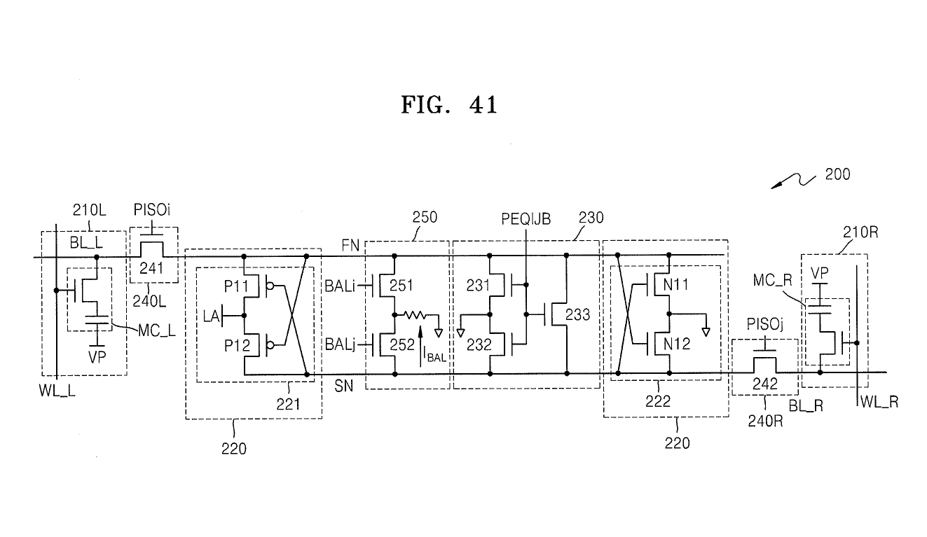

FIG. 41 illustrates a circuit diagram of a semiconductor memory device 200 according to another embodiment of the inventive concept. Referring to FIG. 41, the semiconductor memory device 200 includes a first memory cell array block 210L, a second memory cell array block 210R, a sense amplifier 220, an equalization unit 230, a first isolation control unit 240L, a second isolation control unit 240R, and a current balancing control unit 250. The semiconductor memory device 200 has an open bit line configuration, in which first and second bit line lines BL_L and BL_R connected to the sense amplifier 220 via the first and second isolation control units 240L and 240R, respectively, are disposed in different memory cell array blocks 210L and 210R, respectively.

The first memory cell array block 210L includes a plurality of memory cells each connected to a respective bit line and a respective word line. Similarly, the second memory cell array block 210R includes a plurality of memory cells each connected to a respective bit line and a respective word line. For convenience of explanation, only one memory cell MC_L is included in the first memory cell array block 210L and one memory cell MC_R is included in the second memory cell array block 210R.

The sense amplifier 220 includes a P type sense amplifier 221 and an N type sense amplifier 222, wherein each senses and amplifies a voltage between a first node FN and a second node SN. The P type sense amplifier 221 includes the first PMOS transistor P11 and the second PMOS transistor connected in series between the first node FN and the second node SN. The sensing driving voltage LA is applied to sources of the first and second PMOS transistors P11 and P12, the gate of the first PMOS transistor P11 is connected to the second node SN, and the gate of the second PMOS transistor P12 is connected to the first node FN. The first PMOS transistor P11 and the second PMOS transistor P12 may be different or the same in size. The sensing driving voltage LA is applied in response to a sensing enable signal (not shown). The sensing driving voltage LA may be either a supply voltage to be applied to the semiconductor memory device 200 or an internal voltage generated from a supply voltage in the semiconductor memory device 200.

The N type sense amplifier 222 includes the first NMOS transistor N11 and the second NMOS transistor N12 connected in series between the first node FN and the second node SN. A ground voltage VSS is applied to sources of the first and second NMOS transistors N11 and N12, the gate of the first NMOS transistor N11 is connected to the second node SN, and the gate of the second NMOS transistor N12 is connected to the first node FN. The first NMOS transistor N11 and the second NMOS transistor N12 may be different or the same in size.

The equalization unit 230 equalizes voltages of the first node FN and the second node SN of the sense amplifier 220 with the ground voltage VSS, in response to an equalizing signal PEQIJB. The equalization unit 230 includes a first NMOS transistor 231 connected between the ground voltage VSS source and the first node FN, a second NMOS transistor 232 connected between the ground voltage VSS source and the second node SN, and a third NMOS transistor 233 connected between the first node FN and the second node SN. The equalizing signal PEQIJB is supplied to gates of the first to third NMOS transistors 231 to 233.

During a precharge operation of the semiconductor memory device 200, the equalizing signal PEQIJB is logic high when supplied to the first to third NMOS transistors 231 to 233 so as to turn on the first to third NMOS transistors 231 to 233 and to precharge the first node FN and the second node SN to the ground voltage VSS. During active and sensing operations of the semiconductor memory device 200, the equalizing signal PEQIJB is logic low when supplied to the first to third NMOS transistors 231 to 233 so as to turn off the first to third NMOS transistors 231 to 233.

The first isolation control unit 240L connects the first bit line BL_L of the first memory cell array block 210 to the first node FN, in response to a first isolation control signal PIOSi, and the second isolation control unit 240R connects the second bit line BL_R of the second memory cell array block 210L to the second node SN, in response to a second isolation control signal PISOj. The first isolation control unit 240L includes a first NMOS transistor 241 connected between the first bit line BL_L and the first node FN and having a gate to which the first isolation control signal PISOi is supplied. The second isolation control unit 240R includes a second NMOS transistor 242 connected between the second bit line BL_R and the second node S and having a gate to which the second isolation control signal PISOj is supplied.

The first isolation control signal PISOi and the second isolation control signal PISOj are controlled in such a manner that a load on the first bit line BL_L to the first node FN is different from that on the second bit line BL_R to the second node SN. If the first isolation control signal PISOi supplied to the first NMOS transistor 241 is equal to a word line supply voltage VPP, then the first NMOS transistor 241 is completely turned on to deliver the entire load on the first bit line BL_L to the first node FN. If the first isolation control signal PISOi supplied to the first NMOS transistor 241 is equal to a voltage VPP/2, then the first NMOS transistor 241 is weakly turned on to reduce the load on the first bit line BL_L to be delivered to the first node FN. If the first isolation control signal PISOi supplied to the first NMOS transistor 241 is equal to a ground voltage VSS, then the first NMOS transistor 241 is turned off and does not deliver the load on the first bit line BL_L to the first node FN.

Similarly, a load on the second bit line BL_R that is to be delivered to the second node SN changes according to a voltage applied to the second isolation control signal PISOj. If the second isolation control signal PISOj supplied to the second NMOS transistor 242 is equal to the word line supply voltage VPP, then the second NMOS transistor 242 is completely turned on to deliver the entire load on the second bit line BL_R to the second node SN. If the second isolation control signal PISOj supplied to the second NMOS transistor 242 is equal to the voltage VPP/2, then the second NMOS transistor 242 is weakly turned on to reduce the load on the second bit line BL_R to be delivered to the second node SN. If the second isolation control signal PISOj supplied to the second NMOS transistor 242 is equal to the ground voltage VSS, then the second NMOS transistor 242 is turned off and does not deliver the load on the second bit line BL_R to the second node SN.

The voltage of the first isolation control signal PISOi and the voltage of the second isolation control signal PISOj may be controlled to be different from each other so that the sense amplifier 220 may perform sensing and amplifying operations while different loads are applied to the first node FN and the second node SN. Such controlling is performed so as to compensate for mismatch occurring between the first and second PMOS transistors P11 and P12 and the first and second NMOS transistors N11 and N12, which are expected to have symmetric characteristics with one another in the sense amplifier 220. For example, the first isolation control signal PISOi and the second isolation control signal PISOj supplied during an operation of the sense amplifier 220 may be set to have a voltage ranging from the voltage VPP/2 to the word line supply voltage VPP and a voltage ranging from a ground voltage VSS to the voltage VPP/2, respectively.

If the voltage of the second isolation control signal PISOj is lower than the voltage of the first isolation control signal PISOi, the load on the second node SN is lower than the load on the first node FN. Thus, the voltage of the second node SN may increase to a logic ‘high’ level by supplying a small amount of current thereto. Thus, the amount of current supplied to the second node SN needs to be controlled. That is, at the beginning of the sensing operation of the semiconductor memory device 200, current that is to be supplied to the second node SN is diverted to another path so as to maintain the voltage of the second node SN at a constant level. To this end, the current balancing control unit 250 is used.

The current balancing control unit 250 controls the amount of current to be supplied to the first node FN and the second node SN according to a first balancing signal BALi and a second balancing signal BALj. The current balancing control unit 250 includes a first NMOS transistor 251 connected between the ground voltage VSS source and the first node FN and having a gate to which the first balancing signal BALi is supplied, and a second NMOS transistor 252 connected between the ground voltage VSS source and the second node SN and having a gate to which the second balancing signal BALj is supplied.

The first and second balancing signals BALi and BALj are logic high during the precharge operation, and are controlled according to the voltages of the first and second isolation control signals PISOi and PSIOj during the active and sensing operations. If the voltage of the supplied second isolation control signal PISOj ranges from the ground voltage VSS to the voltage VPP/2 and the load on the second node SN is low, then the second balancing signal BALj is maintained at a logic ‘high’ level until the beginning of the sensing operation, thereby diverting current to a path of current I_{BAL} flowing through the second NMOS transistor 252, instead of to the second node SN when the sense amplifier 220 operates.

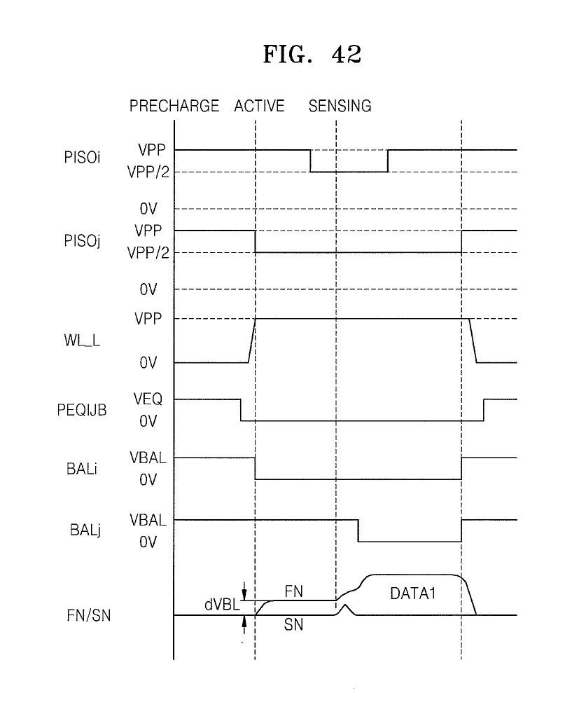

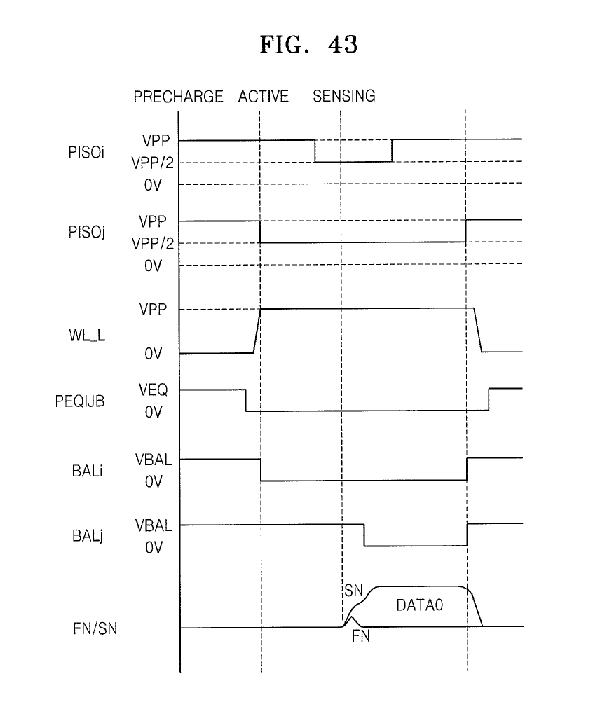

FIGS. 42 and 43 illustrate timing diagrams of operations of the semiconductor memory device 200 of FIG. 41 according to embodiments of the inventive concept. FIG. 42 illustrates a timing diagram of an operation of the semiconductor memory device 200 when data of the first memory cell MC_L is logic high, according to an embodiment of the inventive concept. FIG. 43 illustrates a timing diagram of an operation of the semiconductor memory device 200 when data of the first memory cell MC_L is logic low, according to another embodiment of the inventive concept.

Referring to FIG. 42, during a precharge operation of the semiconductor memory device 200, the first and second isolation control signals PISOi and PISOj are equal to the word line supply voltage VPP, the equalizing signal PEQIJB is equal to an equalizing voltage VEQ and is logic high, and the first and second balancing signals BALi and BALj are equal to a balancing control voltage VBAL and are logic high. The balancing control voltage VBAL ranges from the voltage VPP/2 to the word line supply voltage VPP. The first node FN and the second node SN are precharged to the ground voltage VSS. During an active operation of the semiconductor memory device 200, the first word line WL_L is enabled having the word line supply voltage VPP, the voltage of the second isolation control signal PISOj is lowered to the voltage VPP/2, the equalizing signal PEQIJB is logic low, and the first balancing signal BALi is logic low. If the data of the first memory cell MC_L is logic high, the first node SN and the second node SN in the sense amplifier 220 are charge-shared. During a sensing operation of the semiconductor memory device 200 in which a sensing enable signal (not shown) is activated and the sensing driving voltage LA is applied, the voltage of the first isolation control signal PISOi is equal to the voltage VPP/2, and the second balancing signal BALj is maintained at a logic ‘high’ level until the beginning of the sensing operation and is then lowered to a logic ‘low’ level. Thus, the difference between the voltages of the first node FN and the second node SN is sensed and amplified, and the first node FN and the second node SN approach the sensing driving voltage LA and the ground voltage VSS, respectively.

Referring to FIG. 43, the first and second isolation control signals PISOi and PISOj, the equalizing signal PEQIJB, and the first and second balancing signals BALi and BALj are supplied during the precharge, active, and sensing operations as described above with reference to FIG. 42. During the precharge operation, the first node FN and the second node SN are precharged to the ground voltage VSS. During the active operation, data of the first memory cell MC_L is logic low, and thus, the voltages of the first node FN and the second node SN are equal to the ground voltage VSS. That is, even if the first word line WL_L is enabled having the word line supply voltage VPP during the active operation, the first and second nodes FN and SN in the sense amplifier 220 are not charge-shared. During the sensing operation, the voltage of the second node SN is suppressed from increasing sharply due to the path of current I_{BAL} flowing through the second NMOS transistor 252 until the second balancing signal BALj changes from logic ‘high’ to logic ‘low’, the difference between the voltages of the first node FN and the second node SN is sensed and amplified, and then the first node FN and the second node SN approach the ground voltage VSS and the sensing driving voltage LA, respectively.

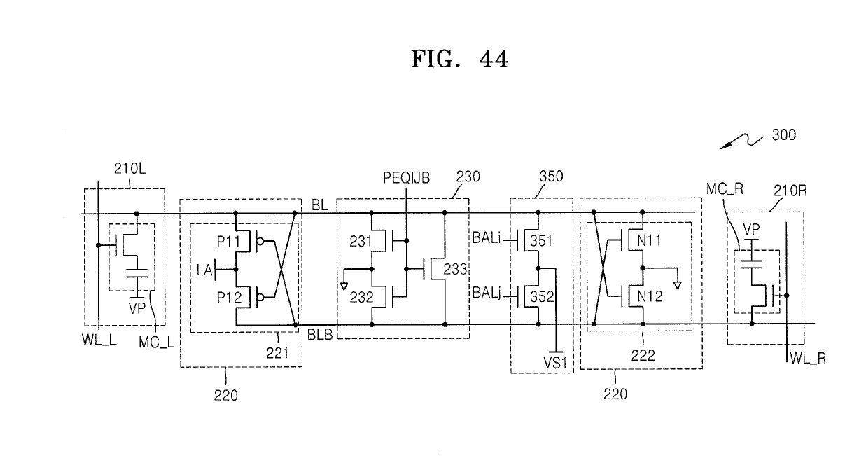

FIG. 44 illustrates a circuit diagram of a semiconductor memory device 300 according to another embodiment of the inventive concept. Compared to the semiconductor memory device 200 of FIG. 41, the semiconductor memory device 300 of FIG. 44 does not include the first and second isolation control units 240L and 240R illustrated in FIG. 41, and includes a voltage balancing control unit 350 instead of the current balancing control unit 250 illustrated in FIG. 41. A first memory cell array block 210L, a second memory cell array block 210R, a sense amplifier 220, and an equalization unit 230 are the same as those illustrated in FIG. 41 and will not be described in detail here.

The voltage balancing control unit 350 controls voltages of the bit line BL and the complementary bit line BLB according to the first balancing signal BALi and the second balancing signal BALj, respectively. The voltage balancing control unit 350 includes a first NMOS transistor 351 connected between a balancing voltage VS1 source and the bit line BL and having a gate to which the first balancing signal BALi is supplied, and a second NMOS transistor 352 connected between the balancing voltage VS1 source and the complementary bit line BLB and having a gate to which the second balancing signal BALj is supplied. The balancing voltage VS1 is half the difference dVBL between the bit line BL and the complementary bit line BLB.

The first or second balancing signal BALi or BALj is activated depending on which one of first and second memory cells MC_L and MC_R respectively included in the first and second memory cell array block 210L and 210R is selected. Specifically, the second balancing signal BALj is activated when the first memory cell MC_L is selected, and the first balancing signal BALi is activated when the second memory cell MC_R is selected. The first and second balancing signals BALi and BALj are activated to be logic high and have a balancing control voltage VBAL while the bit line BL and the complementary bit line BLB are charge-shared. A logic ‘high’ level of each of the first and second balancing signal BALi and BALj may be equal to a sum of a voltage for turning on the first or second NMOS transistor 351 or 352, i.e., the voltage that is half the difference dVBL, and a threshold voltage Vth of the first or second NMOS transistor 351 or 352. The complementary bit line BLB is set to be equal to the balancing voltage VS1 when the first balancing signal BALi is logic high, and the bit line BL is set to be equal to the balancing voltage VS1 when the second balancing signal BALj is logic high, so that during charge-sharing, the difference between the voltages of the first node FN and the second node SN may be equal to the voltage that is half the difference dVBL, i.e., a voltage dVBL/2.

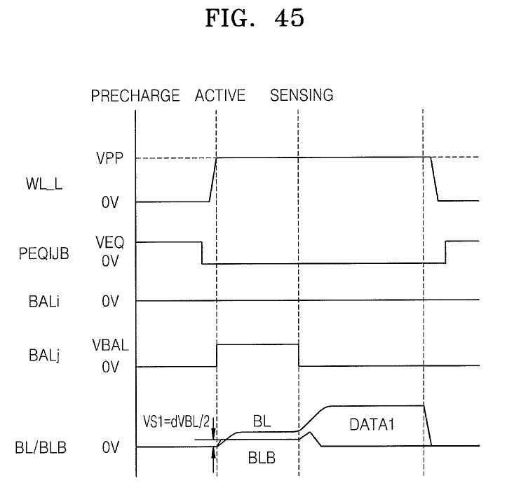

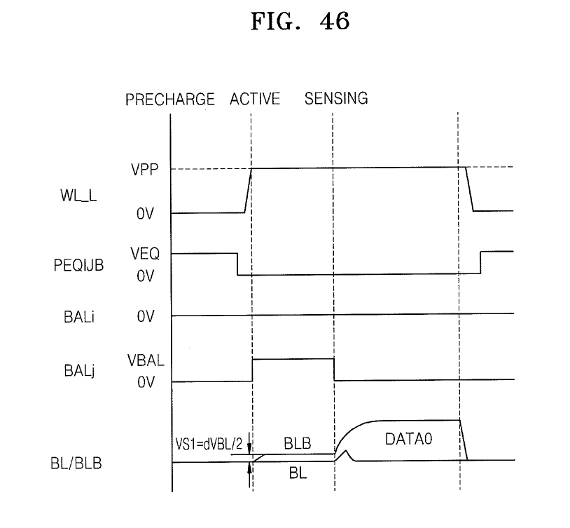

FIGS. 45 and 46 illustrate timing diagrams of operations of the semiconductor memory device 300 of FIG. 44 according to embodiments of the inventive concept. FIG. 45 illustrates a timing diagram of an operation of the semiconductor memory device 300 when data of the first memory cell MC_L is logic high, according to an embodiment of the inventive concept. FIG. 46 illustrates a timing diagram of an operation of the semiconductor memory device 300 when data of the first memory cell MC_L is logic low, according to another embodiment of the inventive concept.

Referring to FIG. 45, during a precharge operation, an equalizing signal PEQIJB is logic high and the first and second balancing signals BALi and BALj have a ground voltage VSS. During an active operation, the first word line WL_L is enabled having a word line supply voltage VPP, the equalizing signal PEQIJB is logic low, and the second balancing signal BALj is logic high. If the data of the first memory cell MC_L is logic high, the first node SN and the second node SN included in the sense amplifier 220 are charge-shared. In this case, a difference between the voltages of the first node FN and the second node SN is equal to the voltage dVBL/2, i.e., half the difference dVBL. During a sensing operation in which a sensing enable signal (not shown) is activated and the sensing driving voltage LA is applied, the second balancing signal BALj is logic low. Thus, the difference between the voltages of the first node FN and the second node SN is sensed and amplified, and the first node FN and the second node SN approach the sensing driving voltage LA and the ground voltage VSS, respectively.

Referring to FIG. 46, the equalizing signal PEQIJB and the first and second balancing signals BALi and BALj are supplied during the precharge, active, and sensing operations as described above with reference to FIG. 45. During the precharge operation, the first node FN and the second node SN are precharged to the ground voltage VSS. During the active operation, if the data of the first memory cell MC_L is logic low, then the first node FN has the ground voltage VSS, and the second node SN has the balancing voltage VS1 by the second NMOS transistor 352 turned on by the second balancing signal BALj, which is logic high. That is, during the active operation, the difference between the voltages of the first node FN and the second node SN is equal to the voltage dVBL/2, that is, half the difference dVBL. During the sensing operation, the difference between the voltages of the first node FN and the second node SN is sensed and amplified. Thus, the first node FN and the second node SN approach the ground voltage VSS and the sensing driving voltage LA, respectively.

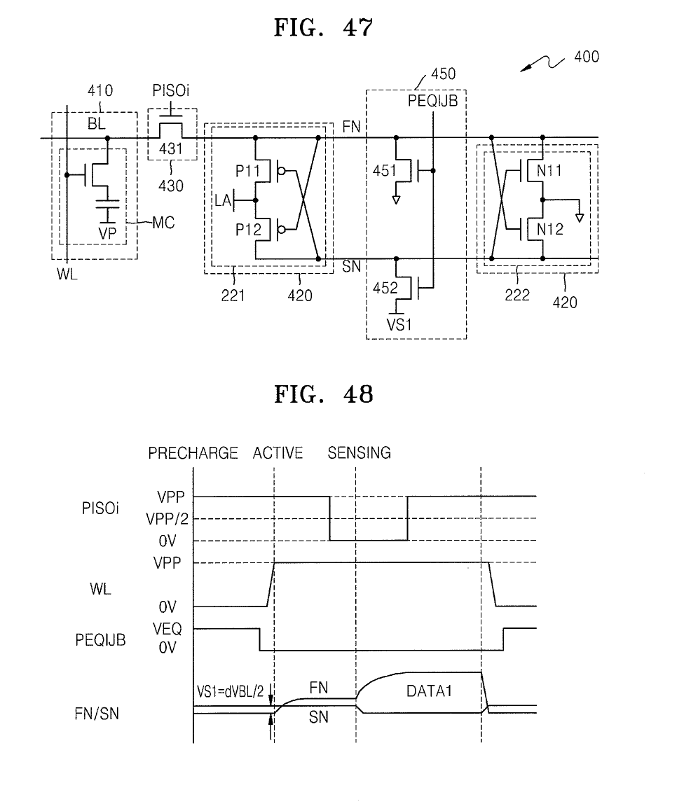

FIG. 47 illustrates a circuit diagram of a semiconductor memory device 400 according to another embodiment of the inventive concept. Referring to FIG. 47, the semiconductor memory device 400 includes a memory cell array block 410, a first sense amplifier 420, an isolation control unit 430, and a balancing control unit 450. The memory cell array block 410 is an outermost memory cell array from among memory cell arrays according to the open bit line configuration as described above with reference to FIG. 38, in which every alternate bit line is connected to one of sense amplifiers from among a half of bit lines and the other bit lines remain dummy bit lines. A memory cell MC of the memory cell array block 410 is connected to the dummy bit lines. The sense amplifier 420 includes the P type sense amplifier 221 and the N type sense amplifier 222 that sense and amplify a voltage between a first node FN and a second node SN, similar to the amplifier 220 of FIG. 41.

The isolation control unit 430 connects the bit line BL of the memory cell array block 410 to the first node FN according to the isolation control signal PIOSi. The isolation control unit 430 includes an NMOS transistor 431 connected between the bit line BL and the first node FN and having a gate to which the isolation control signal PISOi is supplied. The isolation control signal PISOi has a word line supply voltage VPP during the precharge and active operations and has a ground voltage VSS during the sensing operation.

The balancing control unit 450 controls voltages of the first node FN and the second node SN according to an equalizing signal PEQIJB. The balancing control unit 450 includes a first NMOS transistor 451 connected between a ground voltage VSS source and the first node FN and having a gate to which the equalizing signal PEQIJB is supplied, and a second NMOS transistor 452 connected between a balancing voltage VS1 source and the second node SN and having a gate to which the equalizing signal PEQIJB is supplied. The balancing voltage VS1 is half the difference dVBL between the first node FN and the second node SN. The equalizing signal PEQIJB is equal to an equalizing voltage VEQ and logic high during the precharge operation, and is logic low during the active and sensing operations. Accordingly, during the precharge operation, the first node FN is precharged to the ground voltage VSS and the second node SN is precharged to the balancing voltage VS1, so that the difference between the voltages of the first node FN and the second node SN may be equal to a voltage that is half the difference dVBL during the precharge operation and charge-sharing.

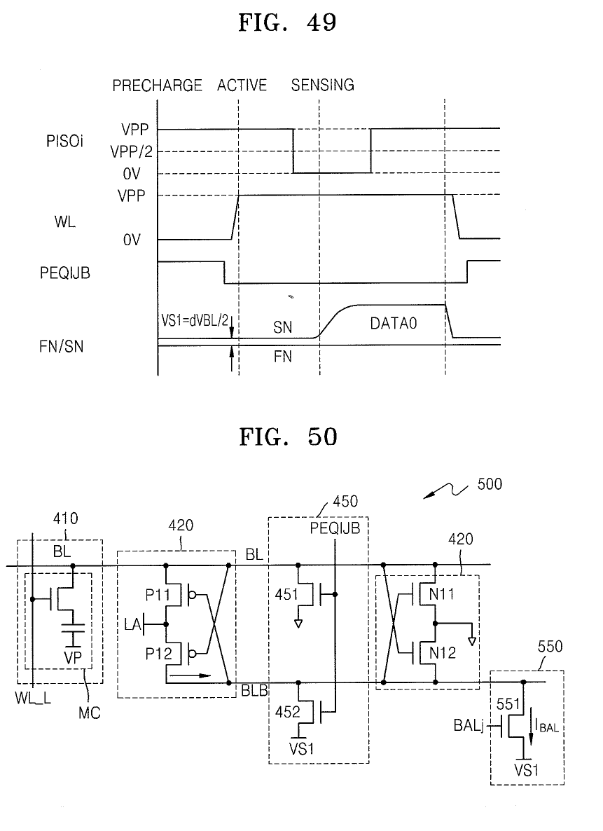

FIGS. 48 and 49 illustrate timing diagrams of operations of the semiconductor memory device 400 of FIG. 47 according to embodiments of the inventive concept. FIG. 48 illustrates a timing diagram of an operation of the semiconductor memory device 400 when data of the memory cell MC is logic high, according to an embodiment of the inventive concept. FIG. 49 illustrates a timing diagram of an operation of the semiconductor memory device 400 when the data of the memory cell MC is logic low, according to another embodiment of the inventive concept.

Referring to FIG. 48, during a precharge operation, the isolation control signal PISOi has the word line supply voltage VPP and the equalizing signal PEQIJB is logic high. In this case, the first node FN is precharged to the ground voltage VSS and the second node SN is precharged to the balancing voltage VS1. During an active operation, the word line WL is enabled having the word line supply voltage VPP and the equalizing signal PEQIJB is logic low. If data of the memory cell MC is logic high, then the first and second nodes FN and SN of the sense amplifier 220 are charge-shared and the difference between the voltages of the first node FN and the second node SN is equal to a voltage dVBL/2, that is, half the charge-sharing voltage dVBL. During a sensing operation in which a sensing enable signal (not shown) is activated and a sensing driving voltage LA is applied, the isolation control signal PISOi has the ground voltage VSS, the difference between the voltages of the first node FN and the second node SN is sensed and amplified. Thus, the first node FN and the second node SN approach the sensing driving voltage LA and the ground voltage VSS, respectively.

Referring to FIG. 49, the isolation control signal PISOi and the equalizing signal PEQIJB are supplied during precharge, active, and sensing operations as described above with reference to FIG. 48. During the precharge operation, the first node FN is precharged to the ground voltage VSS and the second node SN is precharged to the balancing voltage VS1. During the active operation, if data of the first memory cell MC_L is logic low, then the first node SN and the second node SN are charge-shared. In this case, the ground voltage VSS of the first node FN and the balancing voltage VS1 of the second node SN are maintained. That is, during the precharge and active operations, the first node FN and the second node SN has the voltage dVBL/2, that is, half the charge-sharing voltage dVBL. During the sensing operation, the difference between the voltages of the first node FN and the second node SN is sensed and amplified. Thus, the first node FN and the second node SN approach the ground voltage VSS and the sensing driving voltage LA, respectively.

FIG. 50 illustrates a circuit diagram of a semiconductor memory device 500 according to another embodiment of the inventive concept. Compared to the semiconductor memory device 400 of FIG. 47, the semiconductor memory device 500 of FIG. 50 does not include the isolation control unit 430 illustrated in FIG. 47, and includes a second balancing control unit 550 in addition to the balancing control unit 450 of FIG. 47. In FIG. 50, the memory cell array block 410 and the sense amplifier 420 are the same as those of FIG. 47 except that the bit line BL of the memory cell array block 410 is connected directly to the sense amplifier 420 and the sense amplifier 420 senses and amplifies a voltage between the bit line BL and a complementary bit line BLB, since the semiconductor memory device 500 does not include the isolation control unit 430 of FIG. 47.

The first balancing control unit 450 controls voltages of the bit line BL and the complementary bit line BLB according to an equalizing signal PEQIJB. During precharge and active operations, the first balancing control unit 450 precharges the bit line BL to a ground voltage VSS and precharges the complementary bit line BLB to a balancing voltage VS1. Thus, a difference between the voltages of the bit line BL and the complementary bit line BLB is equal to a voltage that is half the difference dVBL.

The second balancing control unit 550 controls the amount of current to be supplied to the complementary bit line BLB according to a balancing signal BALj. The second balancing control unit 550 includes an NMOS transistor 551 connected between a balancing voltage VS1 source and the complementary bit line BLB and having a gate to which the balancing signal BALj is supplied. Load on the complementary bit line BLB, which is not connected to any memory cell, is lower than that on the bit line BL, and the complementary bit line BLB is thus likely to go logic high with a small amount of current. To solve this problem, the balancing signal BALj is used to control the amount of current to be supplied to the complementary bit line BLB. A voltage of the balancing signal BALj may be equal to a balancing control voltage VBAL when the balancing control voltage VBAL is logic high. The balancing control voltage VBAL is equal to a sum of either a word line supply voltage VPP or a voltage for turning on the NMOS transistor 551, i.e., the voltage that is half the charge-sharing voltage dVBL, and a threshold voltage Vth of the NMOS transistor 551. The balancing signal BALj is maintained at a logic ‘high’ level until the beginning of the sensing operation starting from when the precharge operation begins, and current supplied to the complementary bit line BLB is diverted to a path of current I_{BAL} flowing through the NMOS transistor 551 when the sense amplifier 420 operates.

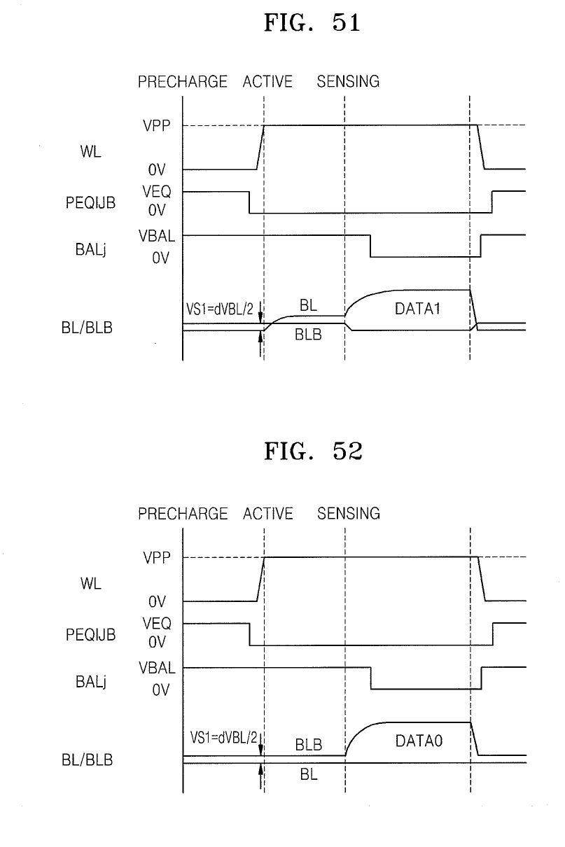

FIGS. 51 and 52 illustrate timing diagrams of operations of the semiconductor memory device 500 of FIG. 50 according to embodiments of the inventive concept. FIG. 51 illustrates a timing diagram of an operation of the semiconductor memory device 500 of FIG. 50 when data of a memory cell MC is logic high, according to an embodiment of the inventive concept. FIG. 52 illustrates a timing diagram of an operation of the semiconductor memory device 500 of FIG. 50 when data of the memory cell MC is logic low, according to another embodiment of the inventive concept.

Referring to FIG. 51, a voltage of an equalizing signal PEQIJB supplied during a precharge operation is equal to an equalizing voltage VEQ when the equalizing voltage VEQ logic high, and the balancing signal BALj supplied during the precharge operation is logic high. The bit line BL is precharged to the ground voltage VSS, and the complementary bit line BLB is precharged to the balancing voltage VS1. During an active operation, a word line WL is enabled having the word line supply voltage VPP, and the equalizing signal PEQIJB is logic low. If the data of the memory cell MC is logic high, then the bit line BL and the complementary bit line BLB included in the sense amplifier 220 are charge-shared. In this case, the difference between voltages of the bit line BL and the complementary bit line BLB is dVBL/2, that is, half the charge-sharing voltage dVBL. During a sensing operation in which a sensing enable signal (not shown) is activated and a sensing driving voltage LA is applied, the balancing signal BALj is logic high until the beginning of the sensing operation and then changes to logic low. Thus, the difference between voltages of the bit line BL and the complementary bit line BLB is sensed and amplified, and the bit line BL and the complementary bit line BLB approach the sensing driving voltage LA and the ground voltage VSS, respectively.

Referring to FIG. 52, the equalizing signal PEQIJB and the balancing signal BALj are supplied during precharge, active, and sensing operations as described above with reference to FIG. 51. During the precharge operation, the bit line BL is precharged to a ground voltage VSS and the complementary bit line BLB is precharged to the balancing voltage VS1. During the active operation, if the data of the memory cell MC is logic low, then the bit line BL and the complementary bit line BLB are charge-shared. In this case, a voltage of the bit line BL is equal to the ground voltage VSS and a voltage of the complementary bit line BLB is equal to the balancing voltage VS1. That is, during the precharge and active operations, the difference between the voltages of the bit line BL and the complementary bit line BLB is equal to the voltage dVBL/2, i.e., half the difference dVBL. During the sensing operation, the complementary bit line BLB is suppressed from increasing sharply due to a path of current I_{BAL} flowing through the NMOS transistor 551 until the balancing signal BALj changes from logic ‘high’ to logic ‘low’. Then, the difference between the voltages of the bit line BL and the complementary bit line BLB is sensed and amplified, and the bit line BL and the complementary bit line BLB approach the ground voltage VSS and the sensing driving voltage LA, respectively.

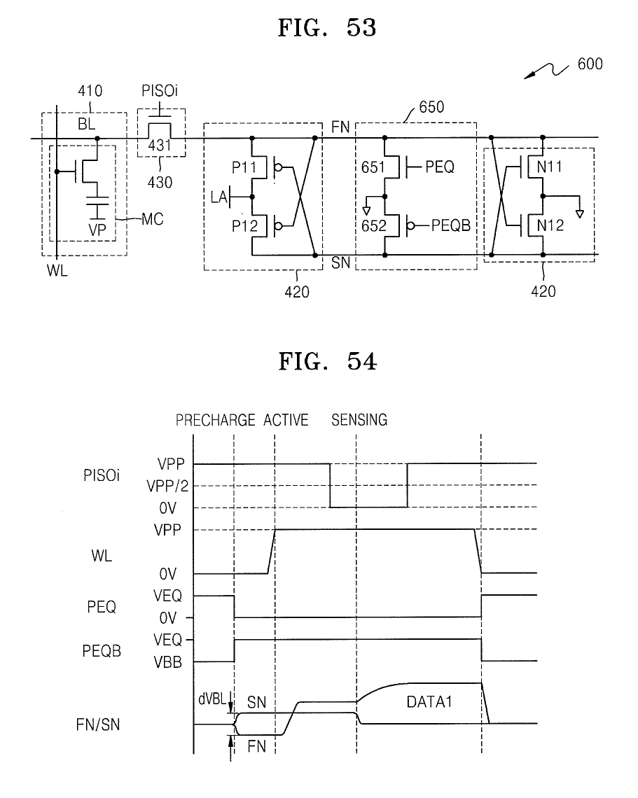

FIG. 53 illustrates a circuit diagram of a semiconductor memory device 600 according to another embodiment of the inventive concept. The semiconductor memory device 600 of FIG. 53 differs from the semiconductor memory device 400 of FIG. 47 in terms of constitutional elements of a balancing control unit 650. In FIG. 53, the memory cell array block 410, the sense amplifier 420, and the isolation control unit 430 are as described above with reference to FIG. 47, and are not described again here.

The balancing control unit 650 controls voltages of a first node FN and a second node SN according to first and second equalizing signals PEQ and PEQB, respectively. The balancing control unit 650 may secure in advance the difference dVBL between the voltages of the first node FN and the second node SN by performing coupling using the voltages of the first and second equalizing signals PEQ and PEQB supplied during a precharge operation.

The balancing control unit 650 includes an NMOS transistor 651 connected between a ground voltage VSS source and the first node FN and having a gate to which the first equalizing signal PEQ is supplied, and a PMOS transistor 652 connected between the ground voltage VSS source and the second node SN and having a gate to which the second equalizing signal PEQB is supplied. The first equalizing signal PEQ supplied before the precharge operation is performed has an equalizing voltage VEQ, and the first equalizing signal PEQ supplied during the precharge, active, and sensing operations has a ground voltage VSS. The second equalizing signal PEQB supplied before the precharge operation is performed has a back-bias voltage VBB, and the second equalizing signal PEQB supplied during the precharge, active, and sensing operations has the equalizing voltage VEQ. The back-bias voltage VBB is a negative voltage, more specifically, a voltage lower than the ground voltage VSS by a transistor threshold voltage Vth.

Before the precharge operation is performed, the NMOS transistor 651 and the PMOS transistor 652 are turned on according to the first and second equalizing signals PEQ and PEQB, and thus, the first node FN and the second node SN have the ground voltage VSS. During the precharge operation, the first node FN is coupled to the first equalizing signal PEQ having the ground voltage VSS and thus has a voltage lower than the ground voltage VSS. Also, during the precharge operation, the second node SN is coupled to the second equalizing signal PEQB having the equalizing voltage VEQ and, thus, has a voltage higher than the ground voltage VSS. Thus, the difference between the voltages of the first node FN and the second node SN is less than or equal to the difference dVBL.

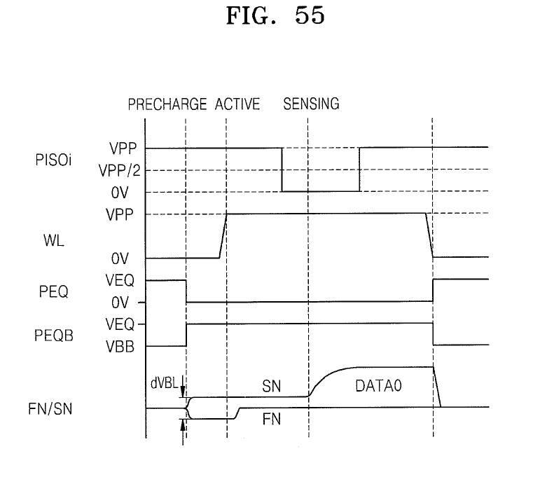

FIGS. 54 and 55 illustrate timing diagrams of operations of the semiconductor memory device 600 of FIG. 53 according to embodiments of the inventive concept. FIG. 54 illustrates a timing diagram of an operation of the semiconductor memory device 600 of FIG. 53 when data of a memory cell MC is logic high, according to an embodiment of the inventive concept. FIG. 55 illustrates a timing diagram of an operation of the semiconductor memory device 600 of FIG. 53 when the data of the memory cell MC is logic low, according to another embodiment of the inventive concept.

Referring to FIG. 54, before a precharge operation is performed, an isolation control signal PISOi has a word line supply voltage VPP, the first equalizing signal PEQ has the equalizing voltage VEQ, and the second equalizing signal PEQB has the back-bias voltage VBB. Thus, the first node FN and the second node SN have the ground voltage VSS. During the precharge operation, the first equalizing signal PEQ has the ground voltage VSS and the second equalizing signal PEQB has the equalizing voltage VEQ. Thus, the difference between the voltages of the first node FN and the second node SN is less than or equal to the difference dVBL. During an active operation, if a word line WL is enabled having the word line supply voltage VPP and the data of the memory cell MC is logic high, then the first node SN and second node SN included in the sense amplifier 420 are charge-shared. Accordingly, the voltages of the first node FN and the second node SN are switched with each other. During a sensing operation in which a sensing enable signal (not shown) is activated and a sensing driving voltage LA is applied, the isolation control signal PISOi has the ground voltage VSS, the difference between the voltages of the first node FN and the second node SN is sensed and amplified. Thus, the first node FN and the second node SN approach the sensing driving voltage LA and the ground voltage VSS, respectively.

Referring to FIG. 55, the isolation control signal PISOi and the first and second equalizing signals PEQ and PEQB are supplied before a precharge operation is performed and during the precharge operation and active and sensing operations, as described above with reference to FIG. 54. The first node FN and the second node SN have the ground voltage VSS before the precharge operation is performed, and the difference between the voltages of the first node FN and the second node SN is less than or equal to the difference dVBL. During the active operation, if the data of the memory cell MC is logic low, then the first node SN and the second node. SN are charge-shared, and the first node FN has the ground voltage VSS and the second node SN has a voltage higher than the ground voltage VSS during the precharge operation. That is, during the active operation, the difference between the voltages of the first node FN and the second node SN is a voltage dVBL/2, that is, half the charge-sharing voltage dVBL. During a sensing operation, the difference between the voltages of the first node FN and the second node SN is sensed and amplified, and thus, the first node FN and the second node SN approach the ground voltage VSS and the sensing driving voltage LA, respectively.

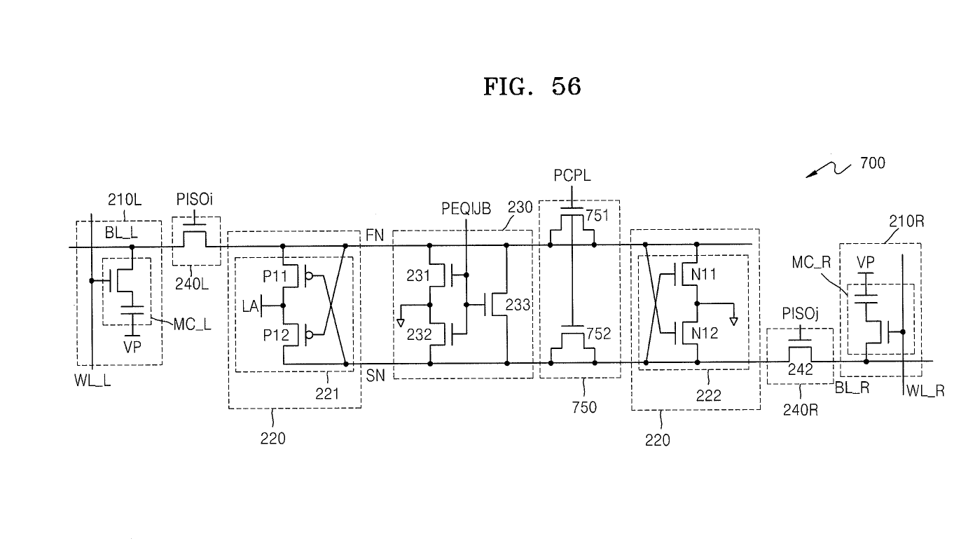

FIG. 56 illustrates a circuit diagram of a semiconductor memory device 700 according to another embodiment of the inventive concept. Referring to FIG. 56, the semiconductor memory device 700 differs from the semiconductor memory device 200 of FIG. 41 in that a coupling control unit 750 is included instead of the current balancing control unit 250 of FIG. 41. In FIG. 56, the first memory cell array block 210L, the second memory cell array block 210R, the sense amplifier 220, the equalization unit 230, the first isolation control unit 240L, and the second isolation control unit 240R are the same as those of FIG. 41, and will not be described again here.

The coupling control unit 750 controls voltages of the first node FN and the second node SN of the sense amplifier 220 according to a coupling signal PCPL. The coupling control unit 750 increases the voltages of the first node FN and the second node SN by performing coupling by applying a coupling voltage VCPL to the coupling signal PCPL during an active operation. If load on the first node FN is different from that on the second node SN and the first memory cell MC_L of the first memory cell array block 210L is selected, then the first node FN, on which a relatively high load is applied, is not greatly influenced by the coupling, but the second node SN, on which a relatively low load is applied, is influenced by the coupling. Thus, the voltage of the second node SN increases up to a voltage dVBL/2, i.e., half the difference dVBL.

The coupling control unit 750 includes a first NMOS transistor 751 having a gate to which the coupling signal PCPL is supplied and a source and drain connected to the first node FN, and a second NMOS transistor 752 having a gate to which the coupling signal PCPL is supplied and a source and drain connected to the second node SN. The first and second NMOS transistors 751 and 752 act as capacitors having a coupling capacitance C_{CPL}. The coupling control unit 750 is not part of the sense amplifier 220, but is located in an adjacent region, i.e., a common region of the semiconductor memory device 700, to be connected to the first and second nodes FN and SN of the bit line sense amplifiers.

The coupling voltage VCPL applied to the coupling signal PCPL is determined by:

$$\frac{1}{2} {V}_{{BL}_{D 1}} * ( {C}_{CPL} + {C}_{BLB} ) = {C}_{CPL} * {V}_{CPL} \qquad ( 4 )$$

wherein V_{BL}_{_{D1}} denotes a voltage when data of the first node FN is logic high, C_{CPL} denotes the coupling capacitance, C_{BLB} denotes a capacitance of the second node SN when a second isolation control signal PISOj has a ground voltage VSS, and V_{CPL} denotes the coupling voltage. That is, the coupling voltage V_{CPL} is determined in such a manner that the product of the sum of the coupling capacitance C_{CPL} and the capacitance C_{BLB} of the second node SN and a voltage that is half the voltage of V_{BL}_{_{D1}} of the first node FN may be equal to the product of the coupling capacitance C_{CPL} and the coupling voltage V_{CPL}.

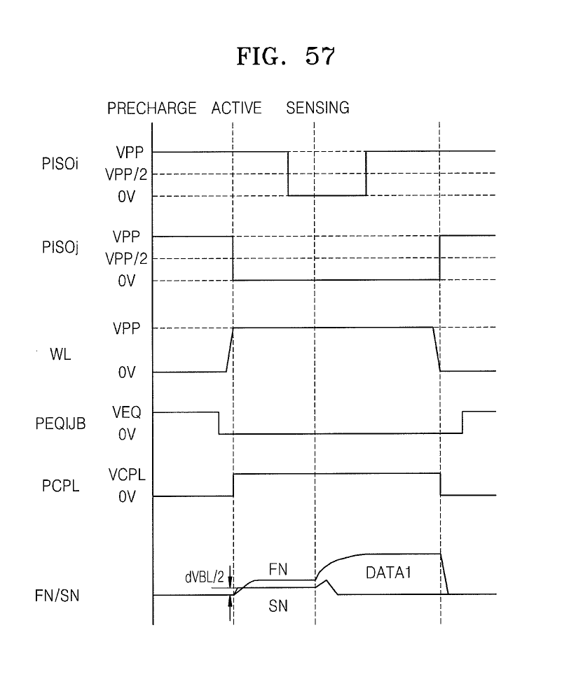

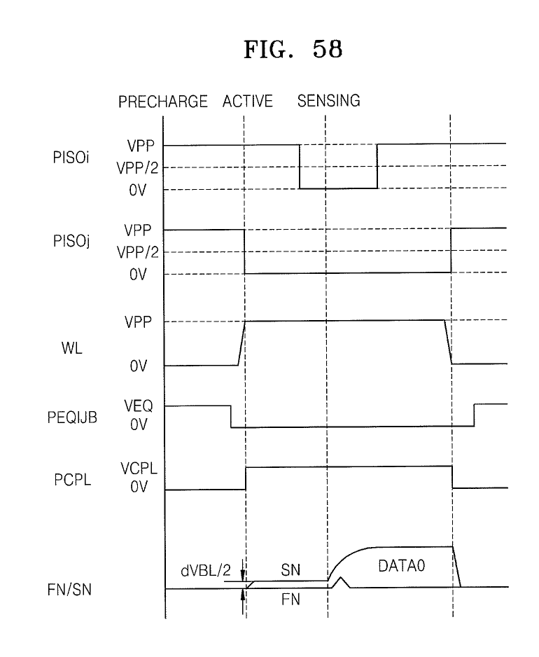

FIGS. 57 and 58 illustrate timing diagrams of operations of the semiconductor memory device 700 of FIG. 56 according to embodiments of the inventive concept. FIG. 57 illustrates a timing diagram of an operation of the semiconductor memory device 700 of FIG. 56 when the data of the first memory cell MC_L is logic high, according to an embodiment of the inventive concept. FIG. 58 illustrates a timing diagram of an operation of the semiconductor memory device 600 of FIG. 56 when the data of the first memory cell MC_L is logic low, according to another embodiment of the inventive concept.

Referring to FIG. 57, during a precharge operation, first and second isolation control signals PISOi and PISOj have a word line supply voltage VPP, an equalizing signal PEQIJB has an equalizing voltage VEQ that is logic high, and the coupling signal PCPL has the ground voltage VSS. In this case, the first node FN and the second node SN are precharged to the ground voltage VSS. During an active operation, a first word line WL_L is enabled having the word line supply voltage VPP, the voltage of the second isolation control signal PISOj is lowered to the ground voltage VSS, the equalizing signal PEQIJB is logic low, and the coupling signal PCPL has the coupling voltage VCPL that is logic high. While the voltage of the second node SN increases up to the voltage dVBL/2, i.e., half the difference dVBL, influenced by the coupling, the first node SN and the second node SN of the sense amplifier 220 are charge-shared when the data of the first memory cell MC_L is logic high. During a sensing operation in which a sensing enable signal (not shown) is activated and a sensing driving voltage LA is applied, the first isolation control signal PISOi has the ground voltage VSS, the difference between the voltages of the first node FN and the second node SN is sensed and amplified. Thus, the first node FN and the second node SN approach the sensing driving voltage LA and the ground voltage VSS, respectively.

Referring to FIG. 58, first and second isolation control signals PISOi and PISOj, the equalizing signal PEQIJB, and the coupling signal PCPL are supplied during precharge, active, and sensing operations, as described above with reference to FIG. 57. During the precharge operation, the first node FN and the second node SN are precharged to the ground voltage VSS. During the active operation, if the data of the first memory cell MC_L is logic low, then the first node FN has the ground voltage VSS, and the second node SN is influenced by the coupling and thus has the voltage dVBL/2, i.e., half the difference dVBL. During the sensing operation, the difference between the voltages of the first node FN and the second node SN is sensed and amplified, and the first node FN and the second node SN approach the ground voltage VSS and the sensing driving voltage LA, respectively.

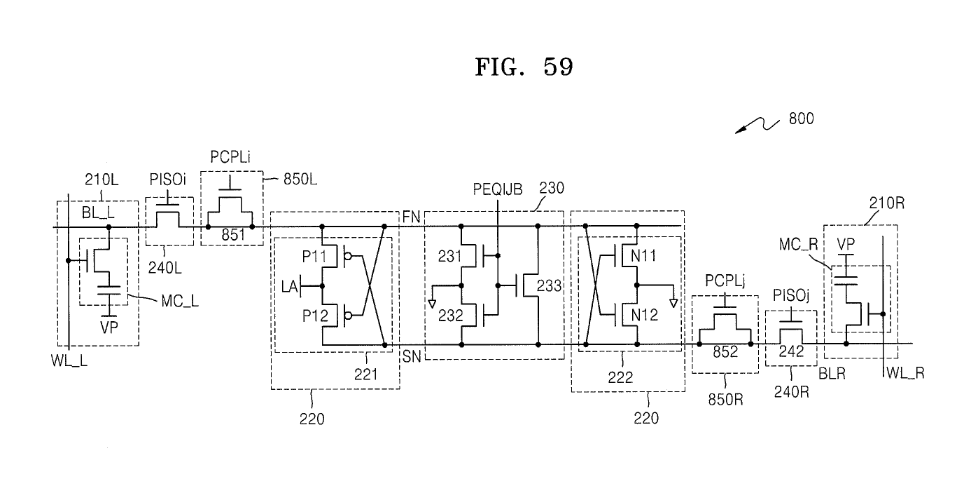

FIG. 59 illustrates a circuit diagram of a semiconductor memory device 800 according to another embodiment of the inventive concept. The semiconductor memory device 800 of FIG. 59 differs from the semiconductor memory device 700 of FIG. 56 in that a first coupling control unit 850L and a second coupling control unit 850R are included instead of the coupling control unit 750 of FIG. 56. In FIG. 59, the first memory cell array block 210L, the second memory cell array block 210R, the sense amplifier 220, the equalization unit 230, the first isolation control unit 240L, and the second isolation control unit 240R are the same as those of FIG. 41, and will not be described again here.

The first and second coupling control units 850L and 850R control voltages of the first node FN and the second node SN according to first and second coupling signals PCPLi and PCPLj, respectively. The first and second coupling control units 850L and 850R increase the voltages of the first node FN and the second node SN by performing coupling by applying a coupling voltage VCPL using the first and second coupling signals PCPLi and PCPLj during an active operation, respectively. The first coupling control unit 850L includes an NMOS transistor 851 having a gate to which the first coupling signal PCPLi is supplied and a source and drain connected to the first node FN. The second coupling control unit 850R includes an NMOS transistor 852 having a gate to which the second coupling signal PCPLj is supplied and a source and drain connected to the second node SN. The NMOS transistors 851 and 852 act as capacitors having a coupling capacitance CCPL. The first and second coupling control units 850L and 850R are not included in the sense amplifier 220, but are located in a an adjacent region, i.e., in a common region of the semiconductor memory device 800, to be connected to the first and second nodes FN and SN of the bit line sense amplifiers.

The first or second coupling signal PCPLi or PCPLj is activated depending on whether the first memory cell MC_L of the first memory cell array block 210L or the second memory cell MC_R of the second memory cell array block 210R is selected. That is, if the first memory cell MC_L is selected, then the second coupling signal PCPLj may be activated, and if the second memory cell MC_R is selected, then first coupling signal PCPLi may be activated. During an active operation, if the first memory cell MC_L is selected, the second node SN is influenced by the coupling and the voltage of the second node SN thus increases up to a voltage dVBL/2, i.e., half the difference dVBL.

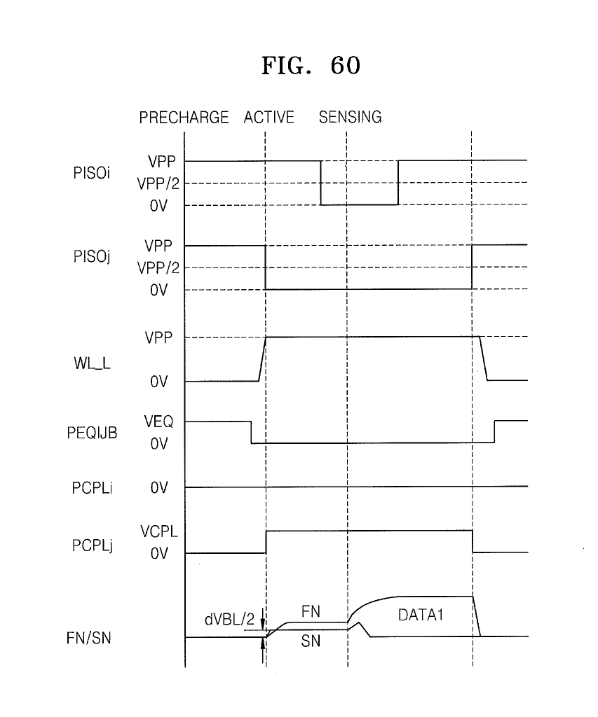

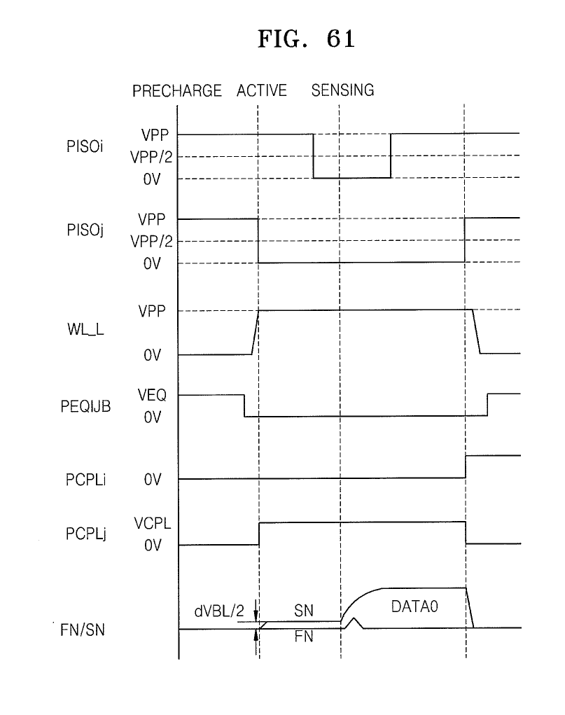

FIGS. 60 and 61 illustrate timing diagrams of operations of the semiconductor memory device 800 of FIG. 59 according to embodiments of the inventive concept. FIG. 60 illustrates a timing diagram of an operation of the semiconductor memory device 800 of FIG. 59 when data of the first memory cell MC_L is logic high, according to an embodiment of the inventive concept. FIG. 61 illustrates a timing diagram of an operation of the semiconductor memory device 800 of FIG. 59 when the data of the first memory cell MC_L is logic low, according to another embodiment of the inventive concept.

Referring to FIG. 60, during a precharge operation, first and second isolation control signals PISOi and PISOj have a word line supply voltage VPP, an equalizing signal PEQIJB is logic high, the first and second coupling signals PCPLi and PCPLj have a ground voltage VSS. In this case, the first node FN and the second node SN are precharged to the ground voltage VSS. During an active operation, the first word line WL_L is enabled having the word line supply voltage VPP, the voltage of the second isolation control signal PISOj is lowered to the ground voltage VSS, the equalizing signal PEQIJB is logic low, and the second coupling signal PCPLj has the coupling voltage VCPL that is logic high. While the voltage of the second node SN increases up to the voltage dVBL/2, i.e., half the difference dVBL, influenced by the coupling, the first node SN and the second node SN of the sense amplifier 220 are charge-shared when the data of the first memory cell MC_L is logic high. During a sensing operation in which a sensing enable signal (not shown) is activated and a sensing driving voltage LA is applied, the first isolation control signal PISOi has the ground voltage VSS, the difference between the voltages of the first node FN and the second node SN is sensed and amplified. Thus, the first node FN and the second node SN approach the sensing driving voltage LA and the ground voltage VSS, respectively.

Referring to FIG. 61, the first and second isolation control signals PISOi and PISOj, the equalizing signal PEQIJB, and the first and second coupling signals PCPLi and PCPLj are supplied during precharge, active, and sensing operations, as described above with reference to FIG. 60. During the precharge operation, the first node FN and the second node SN are precharged to the ground voltage VSS. During the active operation, if the data of the first memory cell MC_L is logic low, then the first node FN has the ground voltage VSS, and the second node SN has the voltage dVBL/2, i.e., half the difference dVBL, influenced by the coupling. During the sensing operation, the difference between the voltages of the first node FN and the second node SN is sensed and amplified. Thus, the first node FN and the second node SN approach the ground voltage VSS and the sensing driving voltage LA, respectively.

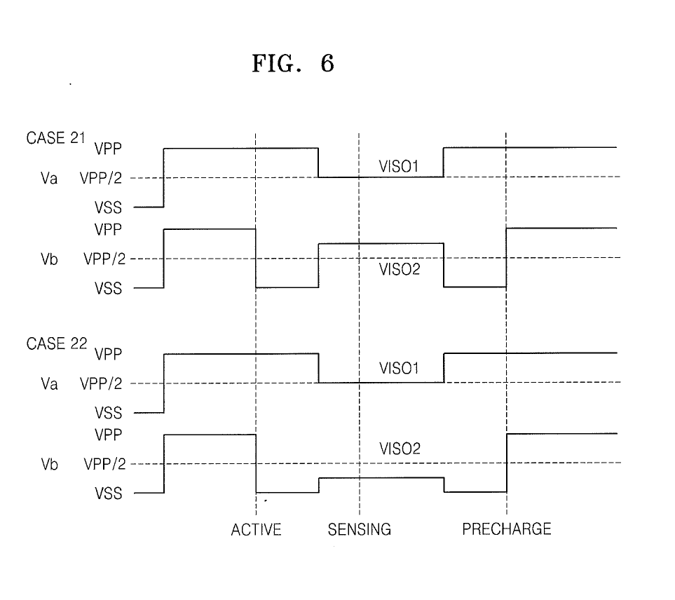

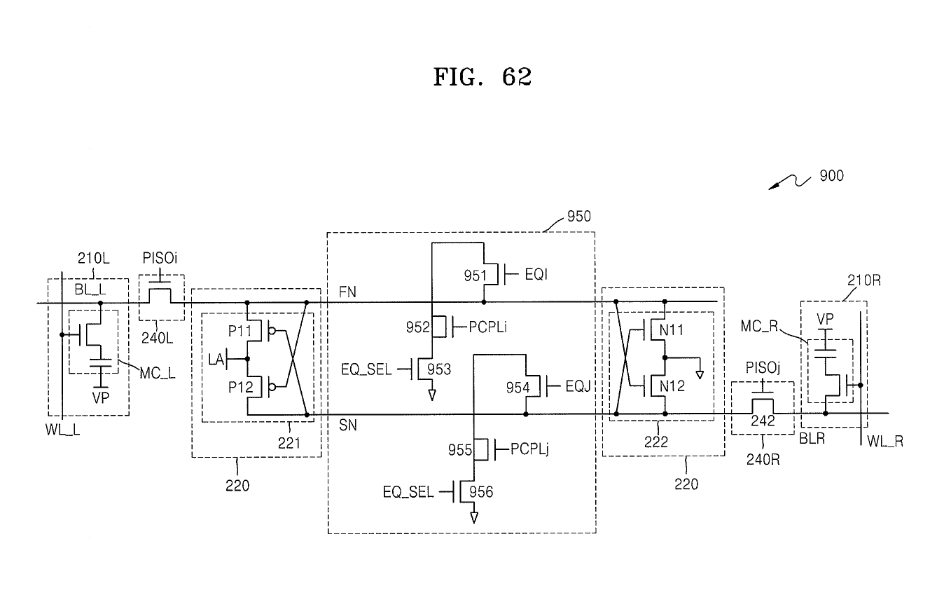

FIG. 62 illustrates a circuit diagram of a semiconductor memory device 900 according to another embodiment of the inventive concept. The semiconductor memory device 900 of FIG. 6 differs from the semiconductor memory device 700 of FIG. 56 in that an equalizing and coupling control unit 950 is included instead of the equalization unit 230 and the coupling control unit 750 illustrated in FIG. 56. In FIG. 62, the first memory cell array block 210L, the second memory cell array block 210R, the sense amplifier 220, the first isolation control unit 240L, and the second isolation control unit 240R are the same as those of FIG. 41, and will not be described again here.

The equalizing and coupling control unit 950 controls voltages of a first node FN and a second node SN according to an equalizing selection signal EQ_SEL, first and second equalizing signals EQI and EQJ, and first and second coupling signals PCPLi and PCPLj. The equalizing and coupling control unit 950 includes first to sixth NMOS transistors 951 to 956. The first NMOS transistor 951 has a gate to which the first equalizing signal EQI is supplied and a drain connected to the first node FN. The second NMOS transistor 952 has a gate to which the first coupling signal PCPLi is supplied, and a source and drain connected to a source of the first NMOS transistor 951. The third NMOS transistor 953 has a gate to which the equalizing selection signal EQ_SEL is supplied, a drain connected to the source of the first NMOS transistor 951, and a source to which a ground voltage VSS is applied. The fourth NMOS transistor 954 has a gate to which the second equalizing signal EQJ is supplied and a drain connected to the second node SN. The fifth NMOS transistor 955 has a gate to which the second coupling signal PCPLj is supplied, and a source and drain connected to a source of the fourth NMOS transistor 954. The sixth NMOS transistor 956 has a gate to which the equalizing selection signal EQ_SEL is supplied, a drain connected to the source of the fourth NMOS transistor 954, and a source to which the ground voltage VSS is applied. The second and fifth NMOS capacitors 952 and 955 act as capacitors having a coupling capacitance CCPL. The equalizing and coupling control unit 950 is not included in the sense amplifier 1120, but is located in an adjacent region, i.e., a common region of the semiconductor memory device 900, to be connected to first and second nodes FN and SN of the bit line sense amplifiers.

During a precharge operation, the equalizing selection signal EQ_SEL and the first and second equalizing signals EQI and EQJ have an equalizing voltage VEQ that is logic high, thereby equalizing and precharging the first and second nodes FN at the ground voltage VSS. During an active operation, the equalizing selection signal EQ_SEL is logic low, and the first or second equalizing signal EQI or EQJ and the first or second coupling signal PCPLi or PCPLj are activated depending on whether the first memory cell MC_L of the first memory cell array block 210R or the second memory cell MC_R of the second memory cell array block 210R is selected. That is, if the first memory cell MC_L is selected, then the second equalizing signal EQJ and the second coupling signal PCPLj may be activated, and if the second memory cell MC_R is selected, then the first equalizing signal EQI and the first coupling signal PCPLi may be activated. Thus, the voltage of the second node SN increases up to a voltage dVBL/2, i.e., half the difference dVBL, influenced by the coupling using the fourth and fifth NMOS transistors 954 and 955. During a sensing operation, the equalizing selection signal EQ_SEL and the first and second equalizing signals EQI and EQJ are logic low. Thus, the first and second modes FN and SN are not influenced by the coupling.

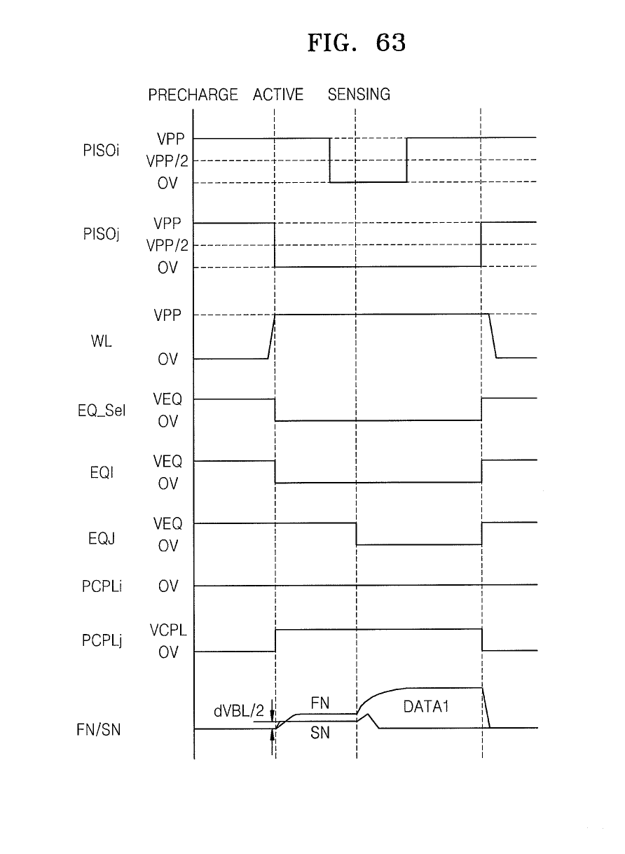

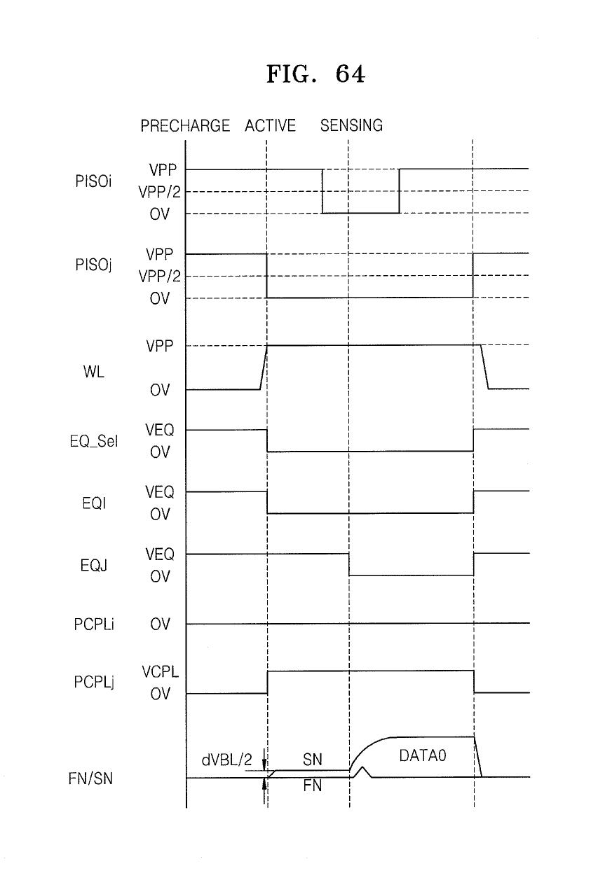

FIGS. 63 and 64 illustrate timing diagrams of operations of the semiconductor memory device 900 of FIG. 62 according to embodiments of the inventive concept. FIG. 63 illustrates a timing diagram of an operation of the semiconductor memory device 900 of FIG. 62 when the data of the first memory cell MC_L is logic high, according to an embodiment of the inventive concept. FIG. 64 illustrates a timing diagram of an operation of the semiconductor memory device 900 of FIG. 62 when the data of the first memory cell MC_L is logic low, according to another embodiment of the inventive concept.

Referring to FIG. 63, during a precharge operation, first and second isolation control signals PISOi and PISOj have a word line supply voltage VPP, the equalizing selection signal EQ_SEL and the first and second equalizing signals EQI and EQJ are logic high, and the first and second coupling signals PCPLi and PCPLj have the ground voltage VSS. The first node FN and the second node SN are precharged to the ground voltage VSS. During an active operation, the first word line WL_L is enabled having the word line supply voltage VPP, the voltage of the second isolation control signal PISOj is lowered to the ground voltage VSS, the equalizing selection signal EQ_SEL is logic low, the first equalizing signal EQI is logic low, the first coupling signal PCPLi is logic low, and the second coupling signal PCPLj has a coupling voltage VCPL that is logic high. When the voltage of the second node SN increases up to a voltage dVBL/2, i.e., half the difference, influenced by the coupling, the first and second nodes FN and SN of the sense amplifier 220 are charge-shared when the data of the first memory cell MC_L is logic high. During a sensing operation in which a sensing enable signal (not shown) is activated and a sensing driving voltage LA is applied, the first isolation control signal PISOi has the ground voltage VSS, the difference between the voltages of the first node FN and the second node SN is sensed and amplified. Thus, the first node FN and the second node SN approach the sensing driving voltage LA and the ground voltage VSS, respectively.

Referring to FIG. 64, the first and second isolation control signals PISOi and PISOj, the equalizing selection signal EQ_SEL, the first and second equalizing signals EQI and EQJ, and the first and second coupling signals PCPLi and PCPLj are supplied during precharge, active, and sensing operations, as described above with reference to FIG. 63. During the precharge operation, the first node FN and the second node SN are precharged to the ground voltage VSS. During the active operation, if the data of the first memory cell MC_L is logic low, then the first node FN has the ground voltage VSS, and the second node SN has the voltage dVBL/2, i.e., the difference dVBL, due to charge coupling. During the sensing operation, the difference between the voltages of the first node FN and the second node SN is sensed and amplified. Thus, the first node FN and the second node SN approach the ground voltage VSS and the sensing driving voltage LA, respectively.

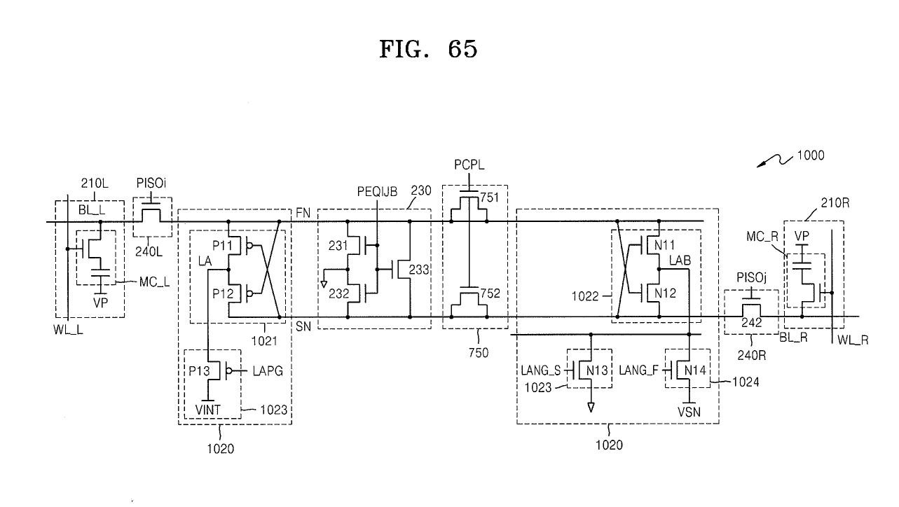

FIG. 65 illustrates a circuit diagram of a semiconductor memory device 1000 according to another embodiment of the inventive concept. The semiconductor memory device 1000 of FIG. 65 differs from the semiconductor memory device 700 of FIG. 56 in that a sense amplifier 1020 having a free sensing function is included instead of the sense amplifier 220 of FIG. 56. In FIG. 65, the first memory cell array block 210L, the second memory cell array block 210R, the equalization unit 230, the first isolation control unit 240L, and the second isolation control unit 240R are the same as those of FIG. 41, and the coupling control unit 750 is the same as that of FIG. 56, and thus will not be described again here.

The sense amplifier 1020 includes a P type sense amplifier 1021 and an N type sense amplifier 1022 that sense and amplify a voltage between the first node FN and the second node SN, a main sensing control unit 1023, and a free sensing control unit 1024. The P type sense amplifier 1021 includes the first PMOS transistor P11 and the second PMOS transistor P12 connected in series between the first node FN and the second node SN. The first sensing driving voltage LA is applied to sources of the first and second PMOS transistors P11 and P12, the gate of the first PMOS transistor P11 is connected to the second node SN, and the gate of the second PMOS transistor P12 is connected to the first node FN. The first PMOS transistor P11 and the second PMOS transistor P12 may be different or the same in size.

The N type sense amplifier 1022 includes the first NMOS transistor N11 and the second NMOS transistor N12 connected in series between the first node FN and the second node SN. A second sensing driving voltage LAB is applied to sources of the first and second NMOS transistors N11 and N12, a gate of the first NMOS transistor N11 is connected to the second node SN, and a gate of the second NMOS transistor N12 is connected to the first node FN. The first NMOS transistor N11 and the second NMOS transistor N12 may be different or the same in size.

The main sensing control unit 1023 includes a PMOS transistor P13 connected between the first sensing driving voltage LA source and a first internal supply voltage VINT source for supplying a first internal supply voltage VINT and having a gate to which a first sensing enable signal LAPG is supplied, and an NMOS transistor N13 connected between the second sensing driving voltage LAB source and a ground voltage VSS source and having a gate to which a second sensing enable signal LANG_S is supplied. During a main sensing operation, the first sensing enable signal LAPG is logic low and the second sensing enable signal LANG_S is logic high. The free sensing control unit 1024 includes an NMOS transistor N14 connected between the second sensing driving voltage LAB source and a second internal supply voltage VSN source for supplying a second internal supply voltage VSN and having a gate to which a free sensing enable signal LANG_F is supplied. The free sensing enable signal LANG_F is enabled during an active operation and is disabled before a sensing operation is performed. The first internal supply voltage VINT and the second internal supply voltage VSN may be supply voltages to be applied to the semiconductor memory device 1000 or may be internal voltages generated from an internal voltage in the semiconductor memory device 1000. The second internal supply voltage VSN ranges between the ground voltage VSS and a negative transistor threshold voltage Vthn.

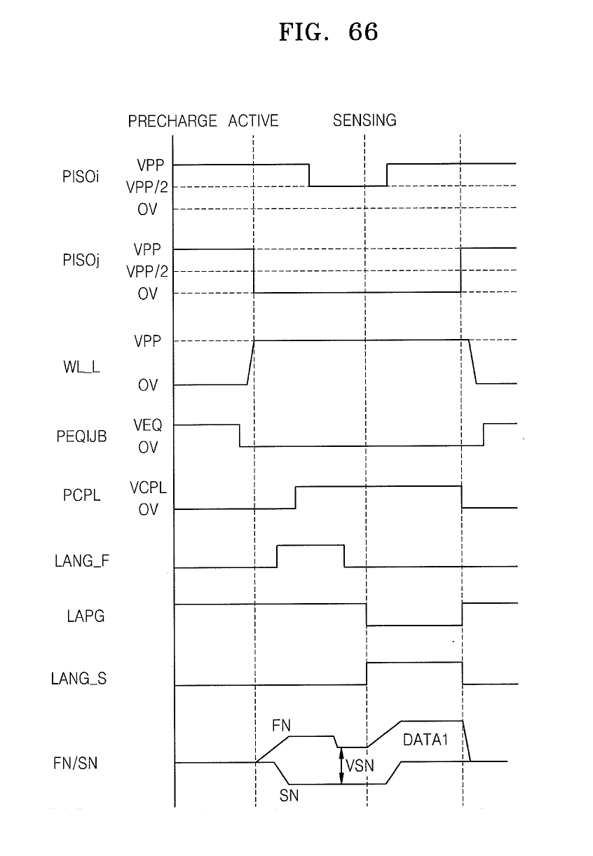

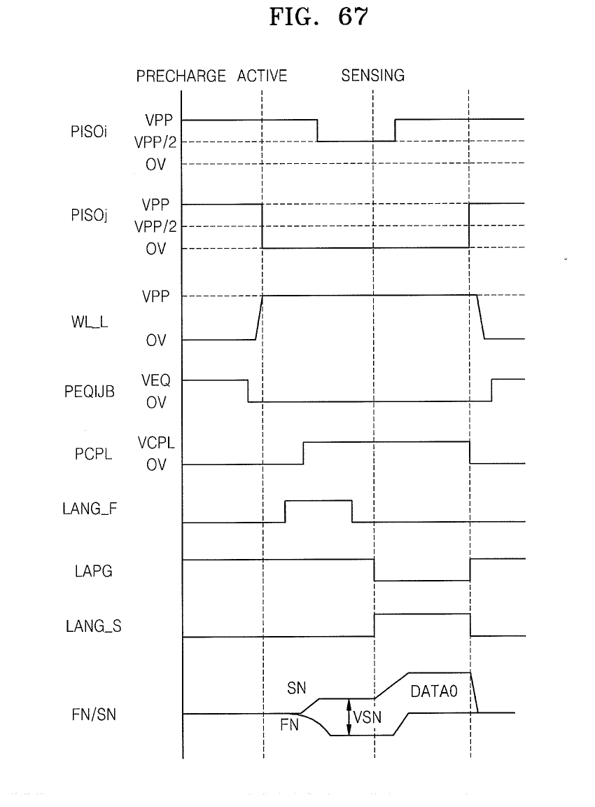

FIGS. 66 and 67 illustrate timing diagrams of operations of the semiconductor memory device 1000 of FIG. 65 according to embodiments of the inventive concept. FIG. 66 illustrates a timing diagram of an operation of the semiconductor memory device 1000 of FIG. 65 when data of a first memory cell MC_L is logic high, according to an embodiment of the inventive concept. FIG. 67 illustrates a timing diagram of an operation of the semiconductor memory device 1000 of FIG. 65 when the data of the first memory cell MC_L is logic LOW, according to another embodiment of the inventive concept.

Referring to FIG. 66, during a precharge operation, first and second isolation control signals PISOi and PISOj have a word line supply voltage VPP, an equalizing signal PEQIJB has an equalizing voltage VEQ that is logic high, a coupling signal PCPL has a ground voltage VSS, the free sensing enable signal LANG_F is logic low, the first sensing enable signal LAPG is logic high, and the second sensing enable signal LANG_S is logic low. The first node FN and the second node SN are precharged to the ground voltage VSS.

During an active operation, if the equalizing signal PEQIJB is logic low and a first word line WL_L is enabled having the word line supply voltage VPP, then the first and second nodes FN and SN in the sense amplifier 220 are charge-shared. If the free sensing enable signal LANG_F is logic high, the coupling signal PCPL has a coupling voltage VCPL that is logic high, and the first isolation control signal PISOi has a voltage VPP/2, that is, half the word line supply voltage VPP, then the voltage of the first node FN on which a relative high load is applied increases while not being influenced by the coupling, and the voltage of the second node SN on which a relative low load is applied is lowered to a negative voltage while not being influenced by the coupling by the second NMOS transistor N12 turned on by the voltage of the first node FN and the NMOS transistor N14 turned on by the free sensing enable signal LANG_F, when the data of the first memory cell MC_L is logic high. Then, the free sensing enable signal LANG_F changes to be logic low right before a sensing operation is performed, and thus, the load on the first node FN decreases, thereby slightly lowering the voltage of the first node FN, caused by the coupling. In this case, the difference between the voltages of the first node FN and the second node SN is less than or equal to the second internal supply voltage VSN.

During the sensing operation, the first sensing enable signal LAPG is logic low, and the second sensing enable signal LANG_S is logic high. Then, the difference VSN between the voltages of first node FN and the second node SN is sensed and amplified, and thus, the first node FN and the second node SN are developed to the first sensing driving voltage LA and the second sensing driving ground voltage LAB, respectively.

Referring to FIG. 67, the first and second isolation control signals PISOi and PISOj, the equalizing signal PEQIJB, the coupling signal PCPL, the free sensing enable signal LANG_F, and the first and second sensing enable signals LAPG and LANG_S are supplied during precharge, active, and sensing operations, as described above with reference to FIG. 66. During the precharge operation, the first node FN and the second node SN are precharged to the ground voltage VSS. During the active operation, the free sensing enable signal LANG_F is logic high, the coupling signal PCPL is logic high, and the data of the first memory cell MC_L is logic low. Thus, the voltage of the second node SN increases, influenced by the coupling but the voltage of the first node FN is lowered to a negative voltage by the first NMOS transistor N11 turned on due to an increase in the voltage of the second node SN and the NMOS transistor N14 turned on according to the free sensing enable signal LANG_F while hardly being influenced by the coupling. The difference between the voltages of the first node FN and the second node SN is less than or equal to the second internal supply voltage VSN. During the sensing operation, the difference between the voltages of the first node FN and the second node SN is sensed and amplified. Thus, the first node FN and the second node SN approach the second sensing driving voltage LAB and the first sensing driving voltage LA, respectively.

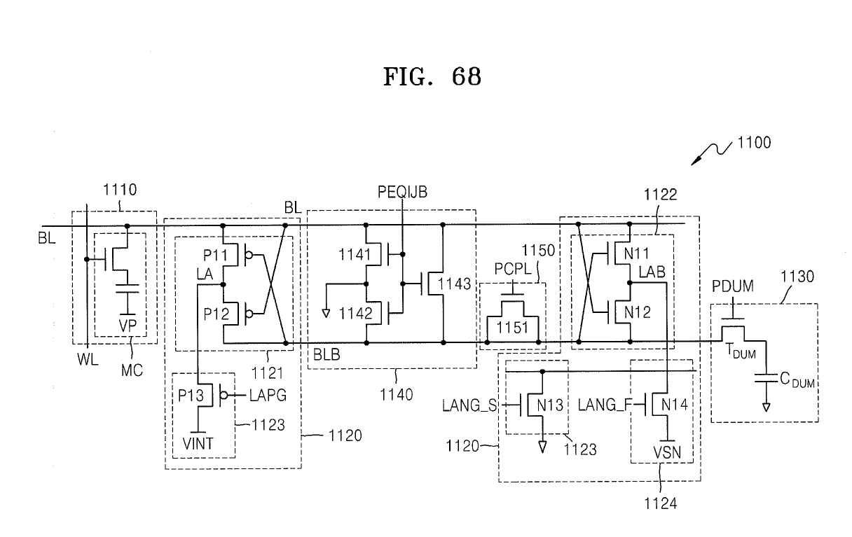

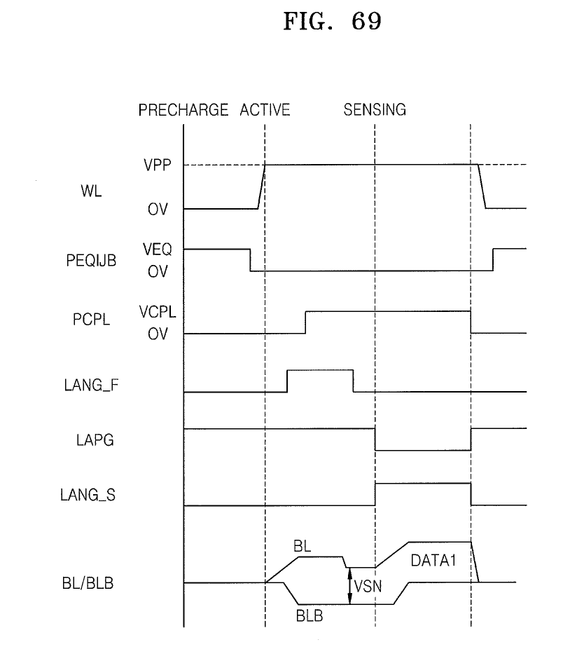

FIG. 68 illustrates a circuit diagram of a semiconductor memory device 1100 according to another embodiment of the inventive concept. Referring to FIG. 68, the semiconductor memory device 1100 includes a memory cell array block 1110, a sense amplifier 1120, a dummy block 1130, an equalization unit 1140, and a coupling control unit 1150. As described above with reference to FIG. 38, the memory cell array block 1110 is an outermost memory array from among a plurality of memory cell arrays according to the open bit line configuration, in which every alternate bit line is connected to a sense amplifier from among half of bit lines and the other bit lines remain dummy. In FIG. 68, a memory cell MC of the memory cell array block 1110 is connected to the dummy bit lines.

The sense amplifier 1120 is almost the same as the sense amplifier 1020 of FIG. 65 having free and main sensing function operations. However, the sense amplifier 1020 of FIG. 65 senses and amplifies a voltage between a first node FN and a second node SN, whereas the sense amplifier 1120 senses and amplifies a voltage between a bit line BL and a complementary bit line BLB. Here, the bit line BL is a line extending from the memory cell MC in the memory cell array block 1110, and the complementary bit line BLB is connected to the dummy block 1130. In the sense amplifier 1120, a P type sense amplifier 1121, an N type sense amplifier 1122, a main sensing control unit 1123, and a free sensing control unit 1124 are respectively the same as the P type sense amplifier 1021, the N type sense amplifier 1022, the main sensing control unit 1023, and the free sensing control unit 1024 of FIG. 65, and will not be described again here.

The dummy block 1130 is similar to the dummy block 130 of FIG. 38. However, the dummy block 130 of FIG. 38 is connected to the bit line BL of the sense amplifier 120, whereas the dummy block 1130 is connected to the complementary bit line BLB of the sense amplifier 1120. The dummy block 1130 includes a dummy transistor T_{DUM} that connects a dummy capacitor C_{DUM} to the complementary bit line BLB according to a dummy load signal PDUM. Load that is to be applied to the dummy block 1130 is determined by a dummy voltage VDUM applied to the dummy load signal PDUM and a capacitance of the dummy capacitor C_{DUM}. A load applied to the complimentary bit line BLB connected to the dummy block 130 is set to be lower than a load on the bit line BL of the memory cell array block 1110 when data of the memory cell MC is logic high, and is set to be higher than the load on the bit line BL of the memory cell array block 1110 when the data of the memory cell MC is logic low.

The equalization unit 1140 equalizes voltages of the bit line BL and the complementary bit line BLB with a ground voltage VSS according to an equalizing signal PEQIJB. The equalization unit 1140 includes a first NMOS transistor 1141 connected between a ground voltage VSS source and the bit line BL, a second NMOS transistor 1142 connected between the ground voltage VSS source and the complementary bit line BLB, and a third NMOS transistor 1143 connected between the bit line BL and the complementary bit line BLB. The equalizing signal PEQIJB is supplied to gates of the first to third NMOS transistors 1141 to 1143. During a precharge operation, the equalizing signal PEQIJB is logic high, and turns on the first to third NMOS transistors 1141 to 1143 and precharges the bit line BL and the complementary bit line BLB to the ground voltage VSS. During active and sensing operations, the equalizing signal PEQIJB is logic low and turns off the first to third NMOS transistors 1141 to 1143.

The coupling control unit 1150 controls the voltage of the complementary bit line BLB according to a coupling signal PCPL. The coupling control unit 1150 includes an NMOS transistor 1151 having a gate to which the coupling signal PCPL is supplied and a source and drain connected to the complementary bit line BLB. The NMOS transistor 1151 acts as a capacitor having a coupling capacitance CCPL. The coupling control unit 1150 is not present for the sense amplifier 1120 but is located in a conjunction region, that is, a common region of the semiconductor memory device 1100, to be connected to complementary bit lines BLB of the bit line sense amplifiers.

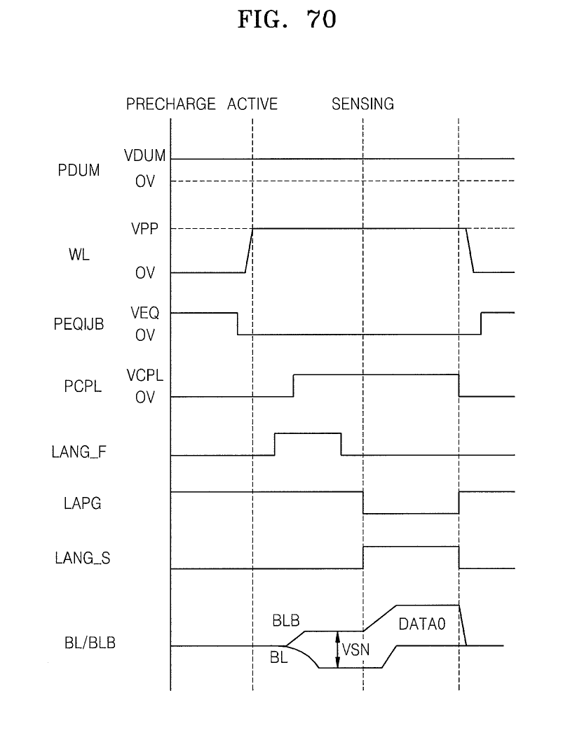

FIGS. 69 and 70 illustrate timing diagrams of operations of the semiconductor memory device 1100 of FIG. 68 according to embodiments of the inventive concept. FIG. 69 illustrates a timing diagram of an operation of the semiconductor memory device 1100 of FIG. 68 when data of the memory cell MC is logic high, according to an embodiment of the inventive concept. FIG. 70 illustrates a timing diagram of an operation of the semiconductor memory device 1100 of FIG. 68 when the data of the memory cell MC is logic low, according to another embodiment of the inventive concept.

Referring to FIG. 69, the dummy load signal PDUM has the dummy voltage VDUM during precharge, active, and sensing operations. During the precharge operation, the equalizing signal PEQIJB has an equalizing voltage VEQ that is logic high, the coupling signal PCPL has the ground voltage VSS, a free sensing enable signal LANG_F is logic low, a first sensing enable signal LAPG is logic high, and a second sensing enable signal LANG_S is logic low. The first node FN and the second node SN are precharged to the ground voltage VSS.

During the active operation, if the equalizing signal PEQIJB is logic low and a word line WL has a word line supply voltage VPP, then the first node FN and the second node SN in the sense amplifier 220 are charge-shared. If the free sensing enable signal LANG_F is logic high and the coupling signal PCPL has a coupling voltage VCPL that is logic high, then the data of the memory cell MC is logic high. Thus, a voltage of the first node FN, to which a relative high load is applied, increases, but a voltage of the second node SN, to which a relative low load is applied, is lowered to a negative voltage by a second NMOS transistor N12 turned on by the voltage of the first node FN and an NMOS transistor N14 turned on by the free sensing enable signal LANG_F while not being influenced by the coupling. Thereafter, the free sensing enable signal LANG_F changes to be logic low right before the sensing operation is performed, and the load on the first node FN thus decreases, thereby slightly lowering the voltage of first node FN, influenced by the coupling. In this case, the difference between the voltages of the first node FN and the second node SN is less than or equal to a second internal supply voltage VSN.

During the sensing operation, the first sensing enable signal LAPG is logic low and the second sensing enable signal LANG_S is logic high. The difference between the voltages of the bit line BL and the complementary bit line BLB is sensed and amplified, and thus, the bit line BL and the complementary bit line BLB are developed to a first sensing driving voltage LA and a second sensing driving ground voltage LAB, respectively.

Referring to FIG. 70, the dummy load signal PDUM, the equalizing signal PEQIJB, the coupling signal PCPL, the free sensing enable signal LANG_F, and the first and second sensing enable signals LAPG and LANG_S are supplied during precharge, active, and sensing operations, as described above with reference to FIG. 69. During the precharge operation, the bit line BL and the complementary bit line BLB are precharged to the ground voltage VSS. During the active operation, the free sensing enable signal LANG_F is logic high, the coupling signal PCPL is logic high, and the data of the memory cell MC is logic low. Thus, the voltage of the complementary bit line BLB increases influenced by the performing coupling but the voltage of the bit line BL is lowered to a negative voltage by a first NMOS transistor N11 turned on by an increase in the voltage of the complementary bit line BLB and the NMOS transistor N14 turned on by the free sensing enable signal LANG_F. The difference between the voltages of the bit line BL and the complementary bit line BLB is equal to the second internal supply voltage VSN. During the sensing operation, the difference between the voltages of the bit line BL and the complementary bit line BLB is sensed and amplified, and thus, the bit line BL and the complementary bit line BLB are developed to the second sensing driving voltage LAB and the first sensing driving voltage LA.

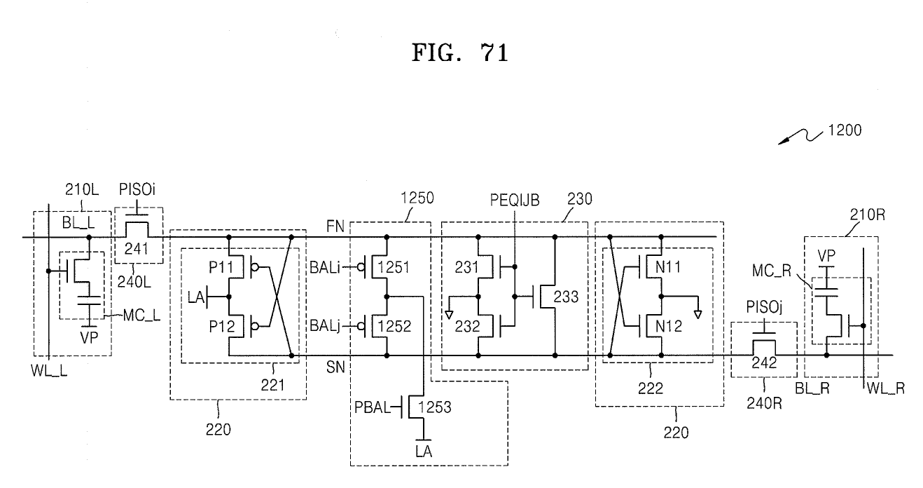

FIG. 71 illustrates a circuit diagram of a semiconductor memory device 1120 according to another embodiment of the inventive concept. The semiconductor memory device 1200 of FIG. 71 differs from the semiconductor memory device 200 of FIG. 41 in that a current balancing control unit 1250 that adds current is included instead of the current balancing control unit 250 of FIG. 41, which diverts current. In FIG. 71, the first memory cell array block 210L, the second memory cell array block 210R, the sense amplifier 220, the equalization unit 230, the first isolation control unit 240L, and the second isolation control unit 240R are the same as those of FIG. 41, and will not thus be described again here.

The current balancing control unit 1250 controls the amount of current to be supplied to a first node FN and a second node SN according to a balancing control signal PBAL, a first balancing signal BALi, and a second balancing signal BALj. The current balancing control unit 1250 includes an NMOS transistor 1253 having a source to which a sensing driving voltage LA is applied and a gate to which the balancing control signal PBAL is supplied, a first PMOS transistor 1251 connected between a drain of the NMOS transistor 1253 and the first node FN and having a gate to which the first balancing signal BALi is supplied, and a second PMOS transistor 1252 connected between the drain of the NMOS transistor 1253 and the second node SN and having a gate to which the second balancing signal BALj is supplied.

The balancing control signal PBAL is activated having an external voltage VEXT that is logic high during a sensing operation. The first or second balancing signals BALi or BALj is activated depending on whether the first memory cell MC_L of the first second memory cell array block 210L or the second memory cell MC_R of the second memory cell array block 210R is selected. That is, if the first memory cell MC_L is selected, then the second balancing signal BALj may be activated, and if the second memory cell MC_R is selected, then the first balancing signal BALi may be activated. The first and second balancing signals BALi and BALj have the balancing control voltage VBAL that is logic high during the precharge operation and have the ground voltage VSS that is logic low during the active and sensing operation. The current balancing control unit 1250 additionally supplies current to the first or second node FN or SN connected to a memory cell that is not selected during the sensing operation so that the difference between the amounts of currents supplied to the first node FN and the second node SN may be increased, thus improving sensing efficiency.

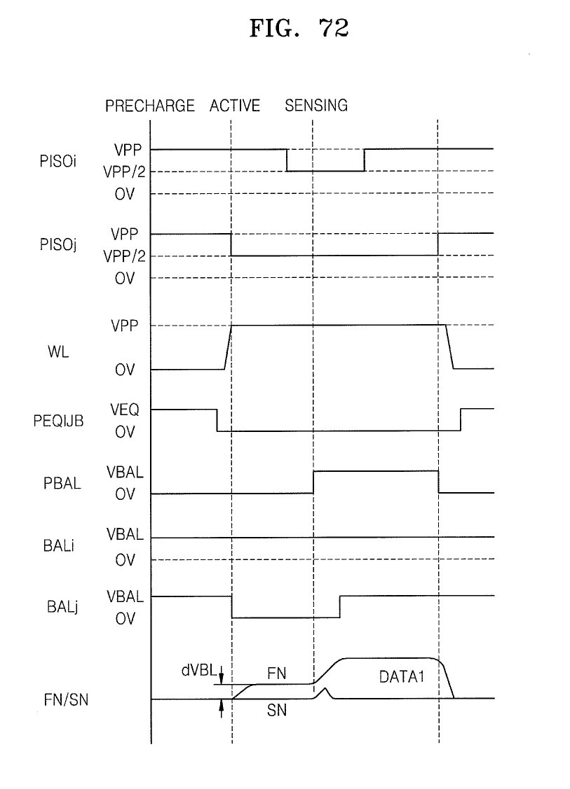

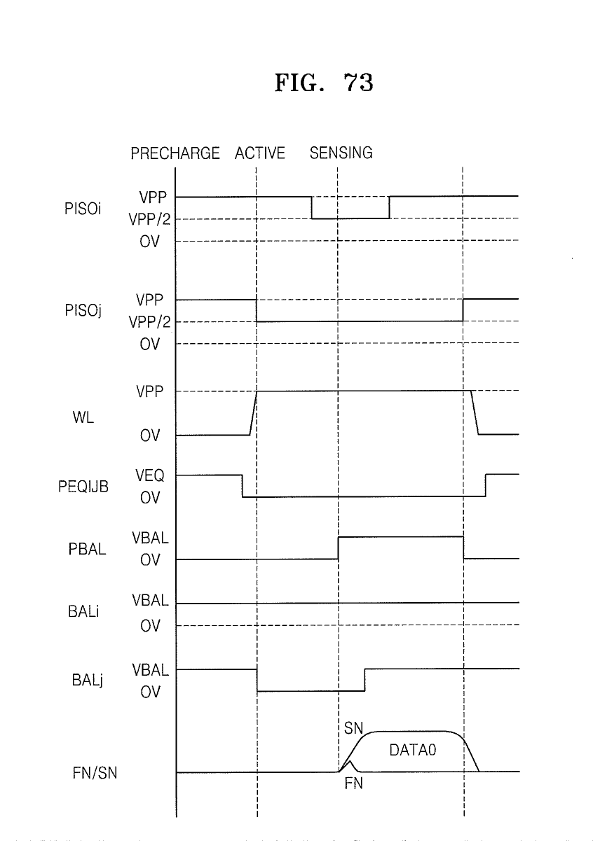

FIGS. 72 and 73 illustrate timing diagrams of operations of the semiconductor memory device 1200 of FIG. 71 according to embodiments of the inventive concept. FIG. 72 illustrates a timing diagram of an operation of the semiconductor memory device 1200 of FIG. 71 when data of the first memory cell MC_L is logic high, according to an embodiment of the inventive concept. FIG. 73 illustrates a timing diagram of an operation of the semiconductor memory device 1200 of FIG. 71 when the data of the first memory cell MC_L is logic low, according to another embodiment of the inventive concept.

Referring to FIG. 72, during a precharge operation, first and second isolation control signals PISOi and PISOj have a word line supply voltage VPP, an equalizing signal PEQIJB has an equalizing voltage VEQ that is logic high, the balancing control signal PBAL has the ground voltage VSS that is logic low, and the first and second balancing signals BALi and BALj have the balancing control voltage VBAL that is logic high. The first node FN and the second node SN are precharged to the ground voltage VSS.

During an active operation, a first word line WL_L for selecting the first memory cell MC_L is enabled having the word line supply voltage VPP, a voltage of the second isolation control signal PISOj is lowered to a voltage VPP/2, that is, half the word line supply voltage VPP, the equalizing signal PEQIJB is logic low, and the second balancing signal BALi is logic low. If the data of the first memory cell MC_L is logic high, then the first node SN and second node SN in the sense amplifier 220 are charge-shared. During a sensing operation in which a sensing enable signal (not shown) is activated and a sensing driving voltage LA is applied, the first isolation control signal PISOi has the voltage VPP/2, the balancing control signal PBAL is logic high, and the second balancing signal BALj is logic low until the beginning of the sensing operation and then changes to be logic high. The amount of current supplied to the first node FN via the first PMOS transistor P11 of the sense amplifier 220 is greater than that of current supplied to the second node SN via the NMOS transistor 1253 and the second PMOS transistor 1252 of the current balancing control unit 1250. Thus, the difference between the amounts of current supplied to the first node FN and the second node SN is sensed and amplified, and then, the first node FN and the second node SN are developed to the sensing driving voltage LA and the ground voltage VSS, respectively.

Referring to FIG. 73, the first and second isolation control signals PISOi and PISOj, the equalization signal PEQIJB, the balancing control signal PBAL, and the first and second balancing signals BALi and BALj are supplied during precharge, active, and sensing operations, as described above with reference to FIG. 72. During the precharge operations, the first node FN and the second node SN in the sense amplifier 220 are precharged to the ground voltage VSS. During the active operation, if the data of the first memory cell MC_L is logic low, then the first node FN and the second node SN have the ground voltage VSS. That is, even if the first word line WL_L is enabled having the word line supply voltage VPP during the active operation, the first node FN and the second node SN are not charge-shared.

During the sensing operation, the voltage of the second node SN is increased by current supplied via the NMOS transistor 1253 and the second PMOS transistor 252 and the first node FN has the ground voltage VSS until the balancing control signal PBAL is logic high and the second balancing signal BALj changes from logic high to logic low. The difference between the voltages of the first node FN and the second node SN is sensed and amplified, and thus, the first node FN and the second node SN are developed to the ground voltage VSS and the sensing driving voltage LA, respectively.

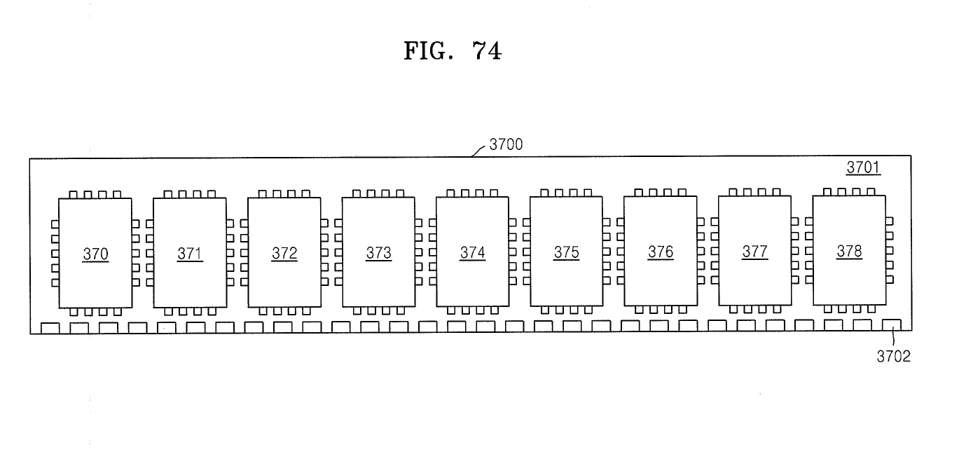

FIG. 74 illustrates a diagram of a memory module 3700 having a plurality of memory chips 370 to 378 each including a semiconductor memory device according to an embodiment of the inventive concept. Referring to FIG. 74, the memory module 3700 includes the memory chips 370 to 378 each having one of the semiconductor memory devices 100, 200, 300, 400, 500, 600, 700, 800, 900, 1000, 1100, and 1200 illustrated in FIGS. 38, 41, 44, 47, 50, 53, 56, 59, 62, 65, 68, and 71. The memory module 3700 is a single in-line memory module (SIMM) including the nine memory chips 370 to 378 disposed on a surface of a printed circuit board (PCB) 3701. In general, the total number of memory chips included in a SIMM is not limited and may range from, for example, 3 to 9. The PCB 3701 includes a plurality of edge connectors 3702 along one long edge thereon to be inserted into memory sockets on a computer mother board. Although not shown, a wiring pattern is formed on the PCB 3701, and terminals or leads that constitute the edge connectors 3702 are connected to the memory chips 370 to 378.

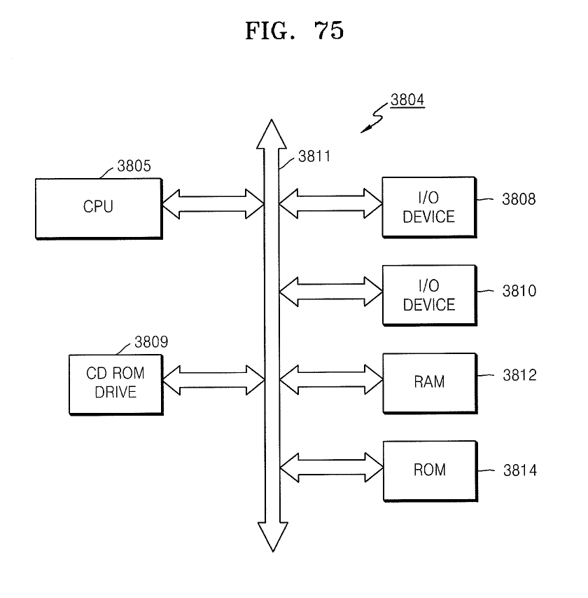

FIG. 75 illustrate a block diagram of a processor-based system 3804 employing a random access memory (RAM) device 3812 that is embodied as a semiconductor memory device according to an embodiment of the inventive concept. That is, the RAM device 3812 may improve sensing margin, speeds, and performance of a bit line sense amplifier as described above with reference to FIGS. 38 to 73. The processor-based system 3804 may be a computer system, a processor control system, or another system employing memory related to a processor. The processor-based system 3804 includes a central processing unit (CPU) 3805, e.g., a microprocessor that communicates with the RAM device 3812 and input/output (I/O) devices 3808 and 3810 via a bus 3811. The processor-based system 3804 may further include a read only memory (ROM) device 3814, and peripheral devices, such as a compact disc (CD) ROM device 3809 that communicate with the CPU 3805 via the bus 3811.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims

What is claimed is:

1. A semiconductor memory device, comprising:
a bit line connected to a plurality of memory cells included in a memory cell array block;
an isolation transistor having a first end connected to the bit line; and
a sense amplifier including a first node connected to a second end of the isolation transistor and a second node that is not connected to any bit line arranged on the memory cell array block,
wherein a word line supply voltage, a ground voltage, or an intermediate voltage between the word line supply voltage and the ground voltage is selectively applied to a gate of the isolation transistor, and
wherein the word line supply voltage is applied to a word line connected to at least one of the plurality of memory cells.

2. The semiconductor memory device as claimed in claim 1, further comprising an isolation control circuit for selectively applying the word line supply voltage, the ground voltage, or the intermediate voltage to the gate of the isolation transistor.

3. The semiconductor memory device as claimed in claim 2, wherein the isolation control circuit applies the word line supply voltage to the gate of the isolation transistor when the word line is activated, applies the intermediate voltage to the gate of the isolation transistor for a predetermined amount of time before and after a sensing operation of the sense amplifier begins, and applies the word line supply voltage again to the gate of the isolation transistor after the predetermined amount of time.

4. The semiconductor memory device as claimed in claim 2, wherein the isolation control circuit applies the word line supply voltage to the gate of the isolation transistor while the word line is deactivated.

5. A semiconductor memory device, comprising:
a first bit line connected to a plurality of memory cells in a first memory cell array block;
a second bit line connected to a plurality of memory cells in a second memory cell array block;
a sense amplifier including a first node and a second node;
a first isolation transistor connected between the first bit line and the first node of the sense amplifier; and
a second isolation transistor connected between the second bit line and the second node of the sense amplifier,
wherein a word line supply voltage, a ground voltage, or a first intermediate voltage between the word line supply voltage and the ground voltage is selectively applied to a gate of the first isolation transistor,
wherein the word line supply voltage is applied to a word line connected to at least one of the plurality of memory cells, and
wherein the word line supply voltage, the ground voltage, or a second intermediate voltage between the word line supply voltage and the ground voltage is selectively applied to a gate of the second isolation transistor.

6. The semiconductor memory device as claimed in claim 5, further comprising:
a first isolation control circuit for selectively applying the word line supply voltage, the ground voltage, or the first intermediate voltage to the gate of the first isolation transistor; and
a second isolation control circuit for selectively applying the word line supply voltage, the ground voltage, or the second intermediate voltage to the gate of the second isolation transistor.

7. The semiconductor memory device as claimed in claim 6, wherein the first isolation control circuit:
applies the word line supply voltage to the gate of the first isolation transistor when the word line is activated;
applies the first intermediate voltage to the gate of the first isolation transistor for a predetermined amount of time before and after a sensing operation of the sense amplifier begins; and
applies the word line supply voltage again to the gate of the first isolation transistor after the predetermined amount of time.

8. The semiconductor memory device as claimed in claim 7, wherein the second isolation control circuit:
applies the word line supply voltage to the gate of the second isolation transistor when the word line is activated;
applies the second intermediate voltage to the gate of the second isolation transistor for the predetermined amount of time before and after the sensing operation of the sense amplifier begins; and
applies the word line supply voltage again to the gate of the second isolation transistor after the predetermined amount of time.

9. The semiconductor memory device as claimed in claim 7, wherein the second isolation control circuit applies the ground voltage to the gate of the second isolation transistor from when the word line is activated to when the word line is deactivated.

10. The semiconductor memory device as claimed in claim 7, wherein the second isolation control circuit:
applies the ground voltage to the gate of the second isolation transistor when the word line is activated;
applies the second intermediate voltage to the gate of the second isolation transistor for the predetermined amount of time before and after the sensing operation of the sense amplifier begins; and
applies the ground voltage again to the gate of the second isolation transistor after the predetermined amount of time.

11. The semiconductor memory device as claimed in claim 7, wherein, while the word line is deactivated, the first isolation control circuit and the second isolation control circuit apply the word line supply voltage to the gate of the first isolation transistor and the gate of the second isolation transistor, respectively.

12. The semiconductor memory device as claimed in claim 6, further comprising:
a first intermediate voltage generator for generating the first intermediate voltage;
a second intermediate voltage generator for generating the second intermediate voltage;
a first multiplexer for selecting the first intermediate voltage and applying the first intermediate voltage to the first isolation control circuit when a block selection signal is at a first logic level, and selecting the second intermediate voltage and applying the second intermediate voltage to the first isolation control circuit when the block selection signal is at a second logic level; and
a second multiplexer for selecting the second intermediate voltage and applying the second intermediate voltage to the second isolation control circuit when the block selection signal is at the first logic level, and selecting the first intermediate voltage and applying the first intermediate voltage to the second isolation control circuit when the block selection signal is at the second logic level.

13. The semiconductor memory device as claimed in claim 5, wherein the second node of the sense amplifier is not connected to any bit line.

14. The semiconductor memory device as claimed in claim 13, further comprising:
a first isolation control circuit for selectively applying the word line supply voltage, the ground voltage, or the first intermediate voltage to the gate of the first isolation transistor; and
a second isolation control circuit for selectively applying the word line supply voltage, the ground voltage, or the second intermediate voltage to the gate of the second isolation transistor.

15. The semiconductor memory device as claimed in claim 14, wherein the first isolation control circuit:
applies the word line supply voltage to the gate of the first isolation transistor when the word line is activated;
applies the first intermediate voltage to the gate of the first isolation transistor for a predetermined amount of time before and after a sensing operation of the sense amplifier begins; and
applies the word line supply voltage again to the gate of the first isolation transistor after the predetermined amount of time.

16. The semiconductor memory device as claimed in claim 15, wherein the second isolation control circuit applies the ground voltage to the gate of the second isolation transistor from when the word line is activated to when the word line is deactivated.

17. The semiconductor memory device as claimed in claim 16, wherein, while the word line is deactivated, the first isolation control circuit and the second isolation control circuit apply the word line supply voltage to the gate of the first isolation transistor and the gate of the second isolation transistor, respectively.

18. The semiconductor memory device as claimed in claim 14, further comprising:
a first intermediate voltage generator for generating the first intermediate voltage;
a second intermediate voltage generator for generating the second intermediate voltage;
a first multiplexer for selecting the first intermediate voltage and applying the first intermediate voltage to the first isolation control circuit when a block selection signal is at a first logic level, and selecting the second intermediate voltage and applying the second intermediate voltage to the first isolation control circuit when the block selection signal is at a second logic level; and
a second multiplexer for selecting the second intermediate voltage and applying the second intermediate voltage to the second isolation control circuit when the block selection signal is at the first logic level, and selecting the first intermediate voltage and applying the first intermediate voltage to the second isolation control circuit when the block selection signal is at the second logic level.

19. A semiconductor memory device, comprising:
a plurality of unit blocks each including a bit line connected to a plurality of memory cells in a memory cell array block, a sense amplifier having a first node and a second node, and an isolation transistor connected between the bit line and the first node of the sense amplifier,
wherein the second nodes of the sense amplifiers are not connected to any bit line arranged on the same memory cell array block, and
wherein gates of the isolation transistors in the unit blocks are commonly connected to an isolation line, wherein one transistor is connected to the isolation line for each of the plurality of unit blocks.

20. The semiconductor memory device as claimed in claim 19, wherein the isolation line selectively applies a word line supply voltage, a ground voltage, or an intermediate voltage between the word line supply voltage and the ground voltage, and wherein the word line supply voltage is applied to a word line connected to at least one of the plurality of memory cells.

21. The semiconductor memory device as claimed in claim 20, further comprising an isolation control circuit for selectively applying the word line supply voltage, the ground voltage, or the intermediate voltage to the isolation line.

22. The semiconductor memory device as claimed in claim 21, wherein the isolation control circuit:
applies the word line supply voltage to the isolation line while the word line is activated;
applies the intermediate voltage to the isolation line for a predetermined amount of time before and after a sensing operation of the sense amplifier begins; and
applies the word line supply voltage again to the isolation line after the predetermined amount of time.

23. The semiconductor memory device as claimed in claim 21, wherein, while the word line is deactivated, the isolation control circuit applies the word line supply voltage to the isolation line.

24. A semiconductor memory device, comprising:
a memory cell array block including a plurality of memory cells each connected to one of a plurality of bit lines and one of a plurality of word lines;
a sense amplifier connected to a half of the plurality of bit lines, the sense amplifier for sensing and amplifying a voltage between each of the half of the bit lines and a corresponding complementary bit line; and
a dummy block connected to the half of the plurality of bit lines of the memory cell array block, the dummy block for controlling a load on the memory cell array block to be different from a load on the dummy block according to a dummy load signal.

25. The semiconductor memory device as claimed in claim 24, wherein the dummy block comprises:
a dummy capacitor; and
a dummy transistor for connecting the dummy capacitor to the half of the plurality of bit lines of the memory cell array according to the dummy load signal.

26. The semiconductor memory device as claimed in claim 24, wherein the dummy block is connected commonly to the half of the plurality of bit lines of the memory cell array.

27. A semiconductor memory device, comprising:
a first memory cell array block including at least one first memory cell connected to at least one first bit line and at least one first word line;
a second memory cell array block including at least one second memory cell connected to at least one second bit line and at least one second word line;
a first isolation control unit for connecting the at least one first bit line of the first memory cell array block to a first node according to a first isolation control signal;
a second isolation control unit for connecting the at least one second bit line of the second memory cell array block to a second node according to a second isolation control signal;
an equalization unit for equalizing voltages of the first node and the second node with a ground voltage according to an equalizing signal;
a sense amplifier for sensing and amplifying a voltage between the first node and the second node; and
a balancing control unit for controlling the voltages of the first node and the second node.

28. The semiconductor memory device as claimed in claim 27, wherein the first and second isolation control signals control a load on the at least one first bit line to be delivered to the first node to be different from a load on the at least one second bit line to be delivered to the second node.

29. The semiconductor memory device as claimed in claim 27, wherein the balancing control unit comprises a current balancing control unit for controlling the amount of current to be supplied to the first node and the second node according to a first balancing signal and a second balancing signal.

30. The semiconductor memory device as claimed in claim 29, wherein the current balancing control unit comprises:
a first NMOS transistor connected between a ground voltage source and the first node, and having a gate to which the first balancing signal is supplied; and
a second NMOS transistor connected between the ground voltage source and the second node and having a gate to which the second balancing signal is supplied.

31. The semiconductor memory device as claimed in claim 27, wherein the balancing control unit comprises a voltage balancing control unit for controlling the voltages of the first node and the second node according to a first balancing signal and a second balancing signal.

32. The semiconductor memory device as claimed in claim 31, wherein the voltage balancing control unit comprises:
a first NMOS transistor connected between a balancing voltage source and the first node and having a gate to which the first balancing signal is supplied; and
a second NMOS transistor connected between the balancing voltage source and the second node and having a gate to which the second balancing signal is supplied.

33. The semiconductor memory device as claimed in claim 27, wherein the balancing control unit comprises a current balancing control unit for controlling the amount of current to be supplied to the first node and the second node according to a balancing control signal, a first balancing signal, and a second balancing signal.

34. The semiconductor memory device as claimed in claim 33, wherein the current balancing control unit comprises:
an NMOS transistor having a source to which a sensing driving voltage is applied and a gate to which the balancing control signal is supplied;
a first NMOS transistor connected between a drain of the NMOS transistor and the first node and having a gate to which the first balancing signal is supplied; and
a second NMOS transistor connected between the drain of the NMOS transistor and the second node and having a gate to which the second balancing signal is supplied.

35. A semiconductor memory device, comprising:
a memory cell array block including a plurality of memory cells each connected to one of a plurality of bit lines and one of a plurality of word lines;
an isolation control unit for connecting a half of the plurality of bit lines to a first node according to an isolation control signal, respectively;
a sense amplifier for sensing and amplifying a voltage between the first node and a second node; and
a balancing control unit for controlling voltages of the first and second nodes.

36. The semiconductor memory device as claimed in claim 35, wherein the isolation control unit comprises an NMOS transistor connected between the plurality of bit lines and the first node and having a gate to which the isolation control signal is supplied.

37. The semiconductor memory device as claimed in claim 35, wherein the balancing control unit controls the voltages of the first node and the second node according to an equalizing signal.

38. The semiconductor memory device as claimed in claim 37, wherein the balancing control unit comprises:
a first NMOS transistor connected between a ground voltage source and the first node and having a gate to which the equalizing signal is supplied; and
a second NMOS transistor connected between a balancing voltage source and the second node and having a gate to which the equalizing signal is supplied.

39. The semiconductor memory device as claimed in claim 35, wherein the balancing control unit controls the voltages of the first node and the second node according to first and second equalizing signals.

40. The semiconductor memory device as claimed in claim 39, wherein the balancing control unit comprises:
an NMOS transistor connected between a ground voltage source and the first node and having a gate to which the first equalizing signal is supplied; and
a PMOS transistor connected between the ground voltage source and the second node and having a gate to which the second equalizing signal is supplied.

41. A semiconductor memory device, comprising:
a memory cell array block including a plurality of memory cells each connected to one of a plurality of bit lines and one of a plurality of word lines;
a sense amplifier for sensing and amplifying a voltage between each of a half of the plurality of bit lines and a corresponding complementary bit line;
a first balancing control unit for controlling the voltage between each of the half of the plurality of bit lines and the corresponding complementary bit line according to an equalizing signal; and
a second balancing control unit for controlling the amount of current to be supplied to the corresponding complementary bit lines according to a balancing signal.

42. The semiconductor memory device as claimed in claim 41, wherein the first balancing control unit comprises:
a first NMOS transistor connected between a ground voltage source and the half of the plurality of bit lines and having a gate to which the equalizing signal is supplied; and
a second NMOS transistor connected between a balancing voltage source and the corresponding complementary bit lines and having a gate to which the equalizing signal is supplied.

43. The semiconductor memory device as claimed in claim 42, wherein, during precharge and charge-sharing operations, the difference between voltages of the first and second node is half a charge-sharing voltage.

44. The semiconductor memory device as claimed in claim 41, wherein the second balancing control unit comprises an NMOS transistor connected between a balancing voltage source and the corresponding complementary bit lines and having a gate to which the balancing signal is supplied.

45. The semiconductor memory device as claimed in claim 44, wherein, until the beginning of a sensing operation starting from when a precharge operation begins, current that is to be supplied to the corresponding complementary bit line is diverted to a path of current flowing through the balancing voltage source when the sense amplifier operates.

46. A semiconductor memory device, comprising:
a first memory cell array block including at least one first memory cell connected to at least one first bit line and at least one first word line;
a second memory cell array block including at least one second memory cell connected to at least one second bit line and at least one second word line;
a first isolation control unit for connecting the at least one first bit line of the first memory cell array block to a first node according to a first isolation control signal;
a second isolation control unit for connecting the at least one second bit line of the second memory cell array block to a second node according to a second isolation control signal;
an equalization unit for equalizing voltages of the first node and the second node with a ground voltage according to an equalizing signal;
a sense amplifier for sensing and amplifying a voltage between the first node and the second node; and
a coupling control unit for controlling the voltages of the first node and the second node by performing coupling.

47. The semiconductor memory device as claimed in claim 46, wherein the coupling control unit controls the voltages of the first node and the second node according to a coupling signal.

48. The semiconductor memory device as claimed in claim 47, wherein the coupling control unit comprises:
a first NMOS transistor having a gate to which the coupling signal is supplied and a source and drain connected to the first node; and
a second NMOS transistor having a gate to which the coupling signal is supplied and a source and drain connected to the second node.

49. The semiconductor memory device as claimed in claim 46, wherein the coupling control unit comprises:
a first coupling control unit for controlling the voltage of the first node according to a first coupling signal; and
a second coupling control unit for controlling the voltage of the second node according to a second coupling signal.

50. The semiconductor memory device as claimed in claim 49, wherein the first coupling control unit comprises an NMOS transistor having a gate to which the first coupling signal is supplied and a source and drain connected to the first node.

51. The semiconductor memory device as claimed in claim 49, wherein the second coupling control unit comprises an NMOS transistor having a gate to which the second coupling signal is supplied and a source and drain connected to the second node.

52. The semiconductor memory device as claimed in claim 49, wherein the first or second coupling signal is activated depending on whether the at least one first memory cell of the first memory cell array block or the at least one second memory cell of the second memory cell array block is selected.

53. The semiconductor memory device as claimed in claim 49, wherein, if the at least one first memory cell is selected during an active operation, the voltage of the second node increases up to a voltage that is half a charge-sharing voltage, influenced by the coupling.

54. The semiconductor memory device as claimed in claim 46, wherein the coupling control unit comprises an equalizing and coupling control unit for controlling the voltages of the first node and the second node according to an equalizing selection signal, first and second equalizing signals, and first and second coupling signals.

55. The semiconductor memory device as claimed in claim 54, wherein the equalizing and coupling control unit comprises:
a first NMOS transistor having a gate to which the first equalizing signal is supplied and a drain connected to the first node;
a second NMOS transistor having a gate to which the first coupling signal is supplied and a source and drain connected to a source of the first NMOS transistor;
a third NMOS transistor having a gate to which the equalizing selection signal is supplied, a drain connected to the source of the first NMOS transistor, and a source to which a ground voltage is applied;
a fourth NMOS transistor having a gate to which the second equalizing signal is supplied and a drain connected to the second node;
a fifth NMOS transistor having a gate to which the second coupling signal is supplied and a source and drain connected to a source of the fifth NMOS transistor; and
a sixth NMOS transistor having a gate to which the equalizing selection signal is supplied, a drain connected to a source of the fourth NMOS transistor, and a source to which the ground voltage is applied.

56. A semiconductor memory device, comprising:
a first memory cell array block including at least one first memory cell connected to at least one first bit line and at least one first word line;
a second memory cell array block including at least one second memory cell connected to at least one second bit line and at least one second word line;
a first isolation control unit for connecting the at least one first bit line of the first memory cell array block to a first node according to a first isolation control signal;
a second isolation control unit for connecting the at least one second bit line of the second memory cell array block to a second node according to a second isolation control signal;
an equalization unit for equalizing voltages of the first node and the second node with a ground voltage according to an equalizing signal;
a sense amplifier for sensing and amplifying a voltage between the first node and the second node according to a free sensing enable signal and first and second sensing enable signals; and
a coupling control unit for controlling the voltages of the first node and the second node according to a coupling signal.

57. The semiconductor memory device as claimed in claim 56, wherein the sense amplifier comprises:
a first type sense amplifier being driven by a first sensing driving voltage, the first type sense amplifier for sensing and amplifying a voltage between the first node and the second node;
a second type sense amplifier being driven by a second sensing driving voltage, the second type sense amplifier for sensing and amplifying the voltage between the first node and the second node;
a main sensing control unit for applying the first sensing driving voltage as a first internal supply voltage according to the first sensing enable signal, and applying the second sensing driving voltage as a ground voltage according to the second sensing enable signal; and
a free sensing control unit for applying the second sensing driving voltage as a second internal supply voltage according to the free sensing enable signal.

58. The semiconductor memory device as claimed in claim 57, wherein the free sensing enable signal is activated during an active operation and is deactivated before a sensing operation is performed.

59. The semiconductor memory device as claimed in claim 57, wherein the main sensing control unit comprises:
a PMOS transistor connected between a first sensing driving voltage source and a first internal supply voltage source and having a gate to which the first sensing enable signal is supplied; and
an NMOS transistor connected between a second sensing driving voltage source and a ground voltage source and having a gate to which the second sensing enable signal is supplied.

60. The semiconductor memory device as claimed in claim 57, wherein the free sensing control unit comprises an NMOS transistor connected between a second sensing driving voltage source and a second internal supply voltage source and having a gate to which the free sensing enable signal is supplied.

61. A semiconductor memory device, comprising:
a memory cell array block including a plurality of memory cells each connected to one of a plurality of bit lines and one of a plurality of word lines;
a sense amplifier connected to a half of the plurality of bit lines, the sense amplifier for sensing and amplifying a voltage between each of the half of the plurality of bit lines and a corresponding complementary bit line according to a free sensing enable signal and first and second sensing enable signals;
a dummy block connected to the corresponding complementary bit lines, the dummy block for controlling a load on the memory cell array block to be different from a load on the dummy block according to a dummy load signal;
an equalization unit for equalizing voltages of the half of the plurality of bit lines and the corresponding complementary bit lines with a ground voltage according to an equalizing signal; and
a coupling control unit for controlling the voltages of the half of the plurality of bit lines according to a coupling signal.
